(19) United States
(12) Patent Application Publication
(10) Pub. No.: US 2023/0389317 A1
(43) Pub. Date: Nov. 30, 2023

(54) THREE-DIMENSIONAL MEMORY DEVICE INCLUDING A METAL OXIDE ETCH STOP LAYER AND METHODS FOR FORMING THE SAME

(71) Applicant: WESTERN DIGITAL TECHNOLOGIES, INC., San Jose, CA (US)

(72) Inventors: Mitsuhiro Togo, Yokkaichi (JP); Fumiaki Toyama, Cupertino, CA (US); Adarsh RAJASHEKHAR, Santa Clara, CA (US)

(21) Appl. No.: 18/233,697

(22) Filed: Aug. 14, 2023

Related U.S. Application Data
(63) Continuation-in-part of application No. 17/525,233, filed on Nov. 12, 2021.
(60) Provisional application No. 63/504,924, filed on May 30, 2023.

(51) Int. Cl. H10B 43/27; H10B 41/27; H10B 80/00; H01L 25/065; H01L 25/18; H01L 23/00; H01L 25/00

(52) U.S. Cl. CPC H10B 43/27; H10B 41/27; H10B 80/00; H01L 25/0657; H01L 25/18; H01L 24/08; H01L 24/80; H01L 25/50; H01L 2224/08145; H01L 2224/80006; H01L 2224/80895; H01L 2224/80896; H01L 2924/1431; H01L 2924/14511

(57) ABSTRACT

A semiconductor structure includes an alternating stack of first insulating layers and first electrically conductive layers, the first alternating stack having first stepped surfaces, at least one first metal oxide etch stop layer overlying and contacting the first stepped surfaces, a first stepped dielectric material portion overlying the at least one first metal oxide etch stop layer and the first stepped surfaces, a memory opening vertically extending through the first alternating stack, a memory opening fill structure located in the memory opening and containing a memory film and a vertical semiconductor channel, and an electrically conductive layer contact via structure vertically extending through the first stepped dielectric material portion and the at least one first metal oxide etch stop layer, and contacting a respective one of the first electrically conductive layers.

### FIELD

The present disclosure relates generally to the field of semiconductor devices, and particularly to a three-dimensional memory device including a metal oxide etch stop layer and methods for forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure includes a first alternating stack of first insulating layers and first electrically conductive layers, the first alternating stack having first stepped surfaces, at least one first metal oxide etch stop layer overlying and contacting the first stepped surfaces, a first stepped dielectric material portion overlying the at least one first metal oxide etch stop layer and the first stepped surfaces, a memory opening vertically extending through the first alternating stack, a memory opening fill structure located in the memory opening and containing a memory film and a vertical semiconductor channel, and an electrically conductive layer contact via structure vertically extending through the first stepped dielectric material portion and the at least one first metal oxide etch stop layer, and contacting a respective one of the first electrically conductive layers.

According to another aspect of the present disclosure, a method of forming a semiconductor structure includes forming an alternating stack of insulating layers and spacer material layers, wherein the spacer material layers are formed as or are subsequently replaced with electrically conductive layers; forming stepped surfaces in the alternating stack, wherein at least one transition-metal oxide etch stop layer is located over the stepped surfaces; forming a stepped dielectric material portion over the stepped surfaces; forming a memory opening through the alternating stack; forming a memory opening fill structure in the memory opening, wherein the memory opening fill structure comprises a memory film and a vertical semiconductor channel; forming a layer contact via cavity through the at least one transition-metal oxide etch stop layer and the stepped dielectric material portion to a top surface of one of the electrically conductive layers by performing a fluorine-based anisotropic etch through the stepped dielectric material portion and by performing a chlorine-based anisotropic etch through the at least one transition-metal oxide etch stop layer; and forming an electrically conductive layer contact via structure in the layer contact via cavity in contact with the top surface of one of the electrically conductive layers.

### BRIEF DESCRIPTION OF THE DRAWINGS

FIG. 1 is a schematic vertical cross-sectional view of a first exemplary structure for forming a memory die after formation of a stopper insulating layer, in-process source-level material layers, a first alternating stack of first insulating layers and first sacrificial material layers, and a first insulating cap layer over a carrier substrate according to a first embodiment of the present disclosure.

FIG. 2 is a schematic vertical cross-sectional view of the first exemplary structure after formation of first stepped surfaces, a first stepped dielectric material portion, and a first transition-metal oxide etch stop layer according to the first embodiment of the present disclosure.

FIG. 3A is a schematic vertical cross-sectional view of the first exemplary structure after forming first-tier memory openings and first-tier support openings according to the first embodiment of the present disclosure.

FIG. 3B is a top-down view of the first exemplary structure of FIG. 3A. The vertical plane A-A′ is the cut plane of the vertical cross-sectional view of FIG. 3A.

FIG. 4 is a schematic vertical cross-sectional view of the first exemplary structure after formation of first lower sacrificial opening fill material portions according to the first embodiment of the present disclosure.

FIG. 5 is a schematic vertical cross-sectional view of the first exemplary structure after optionally isotropically recessing the first insulating cap layer according to the first embodiment of the present disclosure.

FIG. 6 is a schematic vertical cross-sectional view of the first exemplary structure after formation of first upper sacrificial opening fill material portions according to the first embodiment of the present disclosure.

FIG. 7 is a schematic vertical cross-sectional view of the first exemplary structure after formation of a second alternating stack of second insulating layers and second sacrificial material layers, a second first insulating cap layer, and second stepped surfaces according to the first embodiment of the present disclosure.

FIG. 8 is a schematic vertical cross-sectional view of the first exemplary structure after formation of a second stepped dielectric material portion and a second transition-metal oxide etch stop layer according to the first embodiment of the present disclosure.

FIG. 9 is a schematic vertical cross-sectional view of the first exemplary structure after forming second-tier memory openings and second-tier support openings according to the first embodiment of the present disclosure.

FIG. 10 is a schematic vertical cross-sectional view of the first exemplary structure after formation of second lower sacrificial opening fill material portions according to the first embodiment of the present disclosure.

FIG. 11 is a schematic vertical cross-sectional view of the first exemplary structure after optionally isotropically recessing the second insulating cap layer according to the first embodiment of the present disclosure.

FIG. 12 is a schematic vertical cross-sectional view of the first exemplary structure after formation of second upper sacrificial opening fill material portions according to the first embodiment of the present disclosure.

FIG. 13 is a schematic vertical cross-sectional view of the first exemplary structure after formation of a third alternating stack of third insulating layers and third sacrificial material layers, a third insulating cap layer, third stepped surfaces, and a third stepped dielectric material portion according to the first embodiment of the present disclosure.

FIG. 14A is a schematic vertical cross-sectional view of the first exemplary structure after forming third-tier memory openings and third-tier support openings according to the first embodiment of the present disclosure.

FIG. 14B is a top-down view of the first exemplary structure of FIG. 14A. The vertical plane A-A′ is the cut plane of the vertical cross-sectional view of FIG. 14A.

FIG. 15 is a schematic vertical cross-sectional view of the first exemplary structure after formation of multi-tier memory openings and multi-tier support openings according to the first embodiment of the present disclosure.

FIG. 16 is a schematic vertical cross-sectional view of the first exemplary structure after formation of sacrificial multi-tier memory opening fill structures and sacrificial multi-tier support opening fill structures according to the first embodiment of the present disclosure.

FIG. 17 is a schematic vertical cross-sectional view of the first exemplary structure after replacement of the sacrificial multi-tier support opening fill structures with support pillar structures according to the first embodiment of the present disclosure.

FIG. 18A is a schematic vertical cross-sectional view of the first exemplary structure after removal of the sacrificial multi-tier memory opening fill structures according to the first embodiment of the present disclosure.

FIG. 18B is a top-down view of the first exemplary structure of FIG. 18A. The vertical plane A-A′ is the cut plane of the vertical cross-sectional view of FIG. 18A.

FIGS. 19A-19D are sequential vertical cross-sectional views of a region around an multi-tier memory opening during formation of a memory opening fill structure according to the first embodiment of the present disclosure.

FIG. 20 is a vertical cross-sectional view of the first exemplary structure after formation of memory opening fill structures according to the first embodiment of the present disclosure.

FIG. 21A is a vertical cross-sectional view of the first exemplary structure after formation of a contact-level dielectric layer and lateral isolation trenches according to the first embodiment of the present disclosure.

FIG. 21B is a top-down view of the first exemplary structure of FIG. 21A. The hinged vertical plane A-A′ is a cut plane of the vertical cross-sectional view of FIG. 21A.

FIG. 22 is a vertical cross-sectional view of the first exemplary structure after formation of a source cavity according to the first embodiment of the present disclosure.

FIG. 23A is a vertical cross-sectional view of the first exemplary structure after removal portions of the memory films that are exposed to the source cavity according to the first embodiment of the present disclosure.

FIG. 23B is a magnified view of a region of the first exemplary structure of FIG. 23A around a memory opening fill structure.

FIG. 24A is a vertical cross-sectional view of the first exemplary structure after formation of a source contact layer according to the first embodiment of the present disclosure.

FIG. 24B is a magnified view of a region of the first exemplary structure of FIG. 24A around a memory opening fill structure.

FIG. 25 is a vertical cross-sectional view of the first exemplary structure after formation of laterally-extending cavities according to the first embodiment of the present disclosure.

FIG. 26 is a vertical cross-sectional view of the first exemplary structure after formation of electrically conductive layers according to the first embodiment of the present disclosure.

FIG. 27A is a vertical cross-sectional view of the first exemplary structure after formation of an etch mask layer according to the first embodiment of the present disclosure.

FIG. 27B is a top-down view of the first exemplary structure of FIG. 27A.

FIG. 28 is a vertical cross-sectional view of the first exemplary structure after formation of a first patterned photoresist layer and after performing a first anisotropic etch process according to the first embodiment of the present disclosure.

FIG. 29 is a vertical cross-sectional view of the first exemplary structure after formation of a second patterned photoresist layer and after performing a second anisotropic etch process according to the first embodiment of the present disclosure.

FIG. 30 is a vertical cross-sectional view of the first exemplary structure after performing a third anisotropic etch process according to the first embodiment of the present disclosure.

FIG. 31A is a vertical cross-sectional view of the first exemplary structure after formation of drain contact via structures and layer contact via structures according to the first embodiment of the present disclosure.

FIG. 31B is a top-down view of the first exemplary structure of FIG. 31A. The hinged vertical plane A-A′ is a cut plane of the vertical cross-sectional view of FIG. 31A.

FIG. 32 is a vertical cross-sectional view of the first exemplary structure after formation of memory-side dielectric material layers and memory-side metal interconnect structures according to the first embodiment of the present disclosure.

FIG. 33 is a vertical cross-sectional view of the first exemplary structure after attaching a logic die to a memory die according to the first embodiment of the present disclosure.

FIG. 34 is a vertical cross-sectional view of the first exemplary structure after removal of a carrier substrate according to the first embodiment of the present disclosure.

FIG. 35 is a vertical cross-sectional view of an alternative configuration of the first exemplary structure after formation of a source layer according to an alternative aspect of the first embodiment of the present disclosure.

FIG. 36 is a schematic vertical cross-sectional view of a second exemplary structure for forming a memory die after formation of a stopper insulating layer, in-process source-level material layers, a first alternating stack of first insulating layers and first sacrificial material layers, and a first insulating cap layer over a carrier substrate, and after formation of first stepped surfaces and a first transition-metal oxide etch stop layer according to a second embodiment of the present disclosure.

FIG. 37A is a schematic vertical cross-sectional view of the second exemplary structure after formation of a first stepped dielectric material portion, first-tier memory openings, and first-tier support openings according to the second embodiment of the present disclosure.

FIG. 37B is a top-down view of the second exemplary structure of FIG. 37A. The vertical plane A-A′ is the cut plane of the vertical cross-sectional view of FIG. 37A.

FIG. 38 is a schematic vertical cross-sectional view of the second exemplary structure after formation of first lower sacrificial opening fill material portions according to the second embodiment of the present disclosure.

FIG. 39 is a schematic vertical cross-sectional view of the second exemplary structure after optionally isotropically recessing the first insulating cap layer according to the second embodiment of the present disclosure.

FIG. 40 is a schematic vertical cross-sectional view of the second exemplary structure after formation of first upper sacrificial opening fill material portions according to the second embodiment of the present disclosure.

FIG. 41 is a schematic vertical cross-sectional view of the second exemplary structure after formation of a second alternating stack of second insulating layers and second sacrificial material layers, a second first insulating cap layer, second stepped surfaces, a second transition-metal oxide etch stop layer, and a second stepped dielectric material portion according to the second embodiment of the present disclosure.

FIG. 42 is a schematic vertical cross-sectional view of the second exemplary structure after forming second-tier memory openings and second-tier support openings according to the second embodiment of the present disclosure.

FIG. 43 is a schematic vertical cross-sectional view of the second exemplary structure after formation of second lower sacrificial opening fill material portions according to the second embodiment of the present disclosure.

FIG. 44 is a schematic vertical cross-sectional view of the second exemplary structure after optionally isotropically recessing the second insulating cap layer according to the second embodiment of the present disclosure.

FIG. 45 is a schematic vertical cross-sectional view of the second exemplary structure after formation of second upper sacrificial opening fill material portions according to the second embodiment of the present disclosure.

FIG. 46 is a schematic vertical cross-sectional view of the second exemplary structure after formation of a third alternating stack of third insulating layers and third sacrificial material layers, a third insulating cap layer, third stepped surfaces, and a third stepped dielectric material portion according to the second embodiment of the present disclosure.

FIG. 47A is a schematic vertical cross-sectional view of the second exemplary structure after forming third-tier memory openings and third-tier support openings according to the second embodiment of the present disclosure.

FIG. 47B is a top-down view of the second exemplary structure of FIG. 47A. The vertical plane A-A′ is the cut plane of the vertical cross-sectional view of FIG. 47A.

FIG. 48 is a schematic vertical cross-sectional view of the second exemplary structure after formation of multi-tier memory openings and multi-tier support openings according to the second embodiment of the present disclosure.

FIG. 49 is a schematic vertical cross-sectional view of the second exemplary structure after formation of sacrificial multi-tier memory opening fill structures and sacrificial multi-tier support opening fill structures according to the second embodiment of the present disclosure.

FIG. 50 is a schematic vertical cross-sectional view of the second exemplary structure after replacement of the sacrificial multi-tier support opening fill structures with support pillar structures according to the second embodiment of the present disclosure.

FIG. 51A is a schematic vertical cross-sectional view of the second exemplary structure after removal of the sacrificial multi-tier memory opening fill structures according to the second embodiment of the present disclosure.

FIG. 51B is a top-down view of the second exemplary structure of FIG. 51A. The vertical plane A-A′ is the cut plane of the vertical cross-sectional view of FIG. 51A.

FIG. 52 is a vertical cross-sectional view of the second exemplary structure after formation of memory opening fill structures according to the second embodiment of the present disclosure.

FIG. 53A is a vertical cross-sectional view of the second exemplary structure after formation of a contact-level dielectric layer and lateral isolation trenches according to the second embodiment of the present disclosure.

FIG. 53B is a top-down view of the second exemplary structure of FIG. 53A. The hinged vertical plane A-A′ is a cut plane of the vertical cross-sectional view of FIG. 53A.

FIG. 54 is a vertical cross-sectional view of the second exemplary structure after formation of a source cavity according to the second embodiment of the present disclosure.

FIG. 55 is a vertical cross-sectional view of the second exemplary structure after removal portions of the memory films that are exposed to the source cavity according to the second embodiment of the present disclosure.

FIG. 56 is a vertical cross-sectional view of the second exemplary structure after formation of a source contact layer according to the second embodiment of the present disclosure.

FIG. 57 is a vertical cross-sectional view of the second exemplary structure after formation of laterally-extending cavities according to the second embodiment of the present disclosure.

FIG. 58 is a vertical cross-sectional view of the second exemplary structure after formation of electrically conductive layers according to the second embodiment of the present disclosure.

FIG. 59 is a vertical cross-sectional view of the second exemplary structure after formation of an etch mask layer and after performing an anisotropic etch process according to the second embodiment of the present disclosure.

FIG. 60A is a vertical cross-sectional view of the second exemplary structure after formation of drain contact via structures and layer contact via structures according to the second embodiment of the present disclosure.

FIG. 60B is a top-down view of the second exemplary structure of FIG. 60A. The hinged vertical plane A-A′ is a cut plane of the vertical cross-sectional view of FIG. 60A.

FIG. 61 is a vertical cross-sectional view of the second exemplary structure after formation of memory-side dielectric material layers and memory-side metal interconnect structures according to the second embodiment of the present disclosure.

FIG. 62 is a vertical cross-sectional view of the second exemplary structure after attaching a logic die to a memory die according to the second embodiment of the present disclosure.

FIG. 63 is a vertical cross-sectional view of the second exemplary structure after removal of a carrier substrate according to the second embodiment of the present disclosure.

FIG. 64 is a vertical cross-sectional view of the second exemplary structure after formation of a source contact structure according to the second embodiment of the present disclosure.

FIG. 65 is a schematic vertical cross-sectional view of a third exemplary structure after formation of a stopper insulating layer, in-process source-level material layers, and a vertical repetition of multiple instances of a unit layer stack including an insulating layer, a sacrificial material layer, and a transition-metal oxide etch stop layer over a carrier substrate according to a third embodiment of the present disclosure.

FIG. 66 is a schematic vertical cross-sectional view of the third exemplary structure after formation of stepped surfaces and a stepped dielectric material portion according to the third embodiment of the present disclosure.

FIG. 67A is a schematic vertical cross-sectional view of the third exemplary structure after formation of memory openings and support openings according to the third embodiment of the present disclosure.

FIG. 67B is a top-down view of the third exemplary structure of FIG. 67A. The hinged vertical plane A-A′ is a cut plane of the vertical cross-sectional view of FIG. 67A.

FIG. 68 is a vertical cross-sectional view of the third exemplary structure after formation of support pillar structures according to the third embodiment of the present disclosure.

FIGS. 69A-69D are sequential vertical cross-sectional views of a memory opening during formation of a memory opening fill structure in the third exemplary structure according to the third embodiment of the present disclosure.

FIG. 70 is a schematic vertical cross-sectional view of the third exemplary structure after formation of memory opening fill structures according to the third embodiment of the present disclosure.

FIG. 71A is a vertical cross-sectional view of the third exemplary structure after formation of a contact-level dielectric layer and lateral isolation trenches according to the third embodiment of the present disclosure.

FIG. 71B is a top-down view of the third exemplary structure of FIG. 71A. The vertical plane A-A is the cut plane of the vertical cross-sectional view of FIG. 71A.

FIG. 72 is a vertical cross-sectional view of the third exemplary structure after formation of a source cavity according to the third embodiment of the present disclosure.

FIG. 73 is a vertical cross-sectional view of the third exemplary structure after formation of a source contact layer according to the third embodiment of the present disclosure.

FIG. 74 is a vertical cross-sectional view of the third exemplary structure after formation of laterally-extending cavities according to the third embodiment of the present disclosure.

FIG. 75A is a schematic vertical cross-sectional view of the third exemplary structure after formation of electrically conductive layers according to the third embodiment of the present disclosure.

FIG. 75B is a magnified view of a region of a first configuration of the third exemplary structure of FIG. 75A.

FIG. 75C is a magnified view of a region of a second configuration of the third exemplary structure of FIG. 75A.

FIG. 76 is a vertical cross-sectional view of the third exemplary structure after formation of lateral isolation trench fill structures, layer contact via cavities, and drain contact via cavities according to the third embodiment of the present disclosure.

FIG. 77A is a vertical cross-sectional view of the third exemplary structure after formation of drain contact via structures and layer contact via structures according to the third embodiment of the present disclosure.

FIG. 77B is a top-down view of the third exemplary structure of FIG. 77A. The vertical plane A-A is the cut plane of the vertical cross-sectional view of FIG. 77A.

FIG. 78 is a vertical cross-sectional view of the third exemplary structure after formation of a memory die according to the third embodiment of the present disclosure.

FIG. 79 is a vertical cross-sectional view of the third exemplary structure after attaching the logic die to the memory die according to the third embodiment of the present disclosure.

FIG. 80 is a vertical cross-sectional view of the third exemplary structure after removal of the carrier substrate and the insulating material layer according to the third embodiment of the present disclosure.

FIG. 81 is a vertical cross-sectional view of the third exemplary structure after formation of a source contact structure according to the third embodiment of the present disclosure.

### DETAILED DESCRIPTION

As discussed above, the embodiments of the present disclosure are directed to methods for forming a three-dimensional memory device including a metal oxide etch stop layer and methods of forming the same, of which various aspects are now described in detail. Embodiments of the disclosure can be employed to form semiconductor devices, such as three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10 5 S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

Generally, silicon oxide and silicon nitride layers can be anisotropically etched using a fluorine-based etchant gas, such a CF₄ and/or CHF₃. However, fluorine-based etchant gases are typically much less effective in etching oxides of elements of Group 4 (also known as Group IVB) of the periodic table, such as hafnium, zirconium, and titanium, because fluoride molecules of hafnium, zirconium, and titanium have high melting points and high boiling points.

Chlorine-based etchant gases, such as BCl₃ and/or Cl₂ are more effective in etching oxides of elements of Group 4 (i.e., Group IVB) elements due to higher volatilities of chlorides of the elements of Group 4 relative to fluorides of the elements of Group 4. Thus, silicon oxide and silicon nitride layers can be selectively etched relative to oxides of elements of Group 4 in fluorine-based gases. Therefore, the oxides of elements of Group 4 can function as etch stop layers during a fluorine-based anisotropic etching of silicon oxide and silicon nitride. In contrast, oxides of elements of Group 4 can be selectively etched relative to silicon oxide and silicon nitride in chlorine-based gases. Therefore, silicon oxide and silicon nitride can function as etch stop layers during a chlorine-based anisotropic etching of layers comprising oxides of elements of Group 4, such as hafnium oxide, zirconium oxide and/or titanium oxide.

According to an aspect of the present disclosure, metal oxide etch stop liners, such as transition-metal oxide etch stop liners, are used as etch stop structures (i.e., etch stop layers) during an anisotropic etch process that forms via structures, such as contact via structures, in a three-dimensional memory device. In one embodiment, the transition metal-oxide etch stop liners comprise a dielectric metal oxide of a Group IVB element such as Ti, Zr, or Hf. For example, the transition-metal oxide etch stop liners comprise a dielectric metal oxide of a Group IVB element selected from Zr and/or Hf, such as hafnium oxide, zirconium oxide or hafnium zirconium oxide.

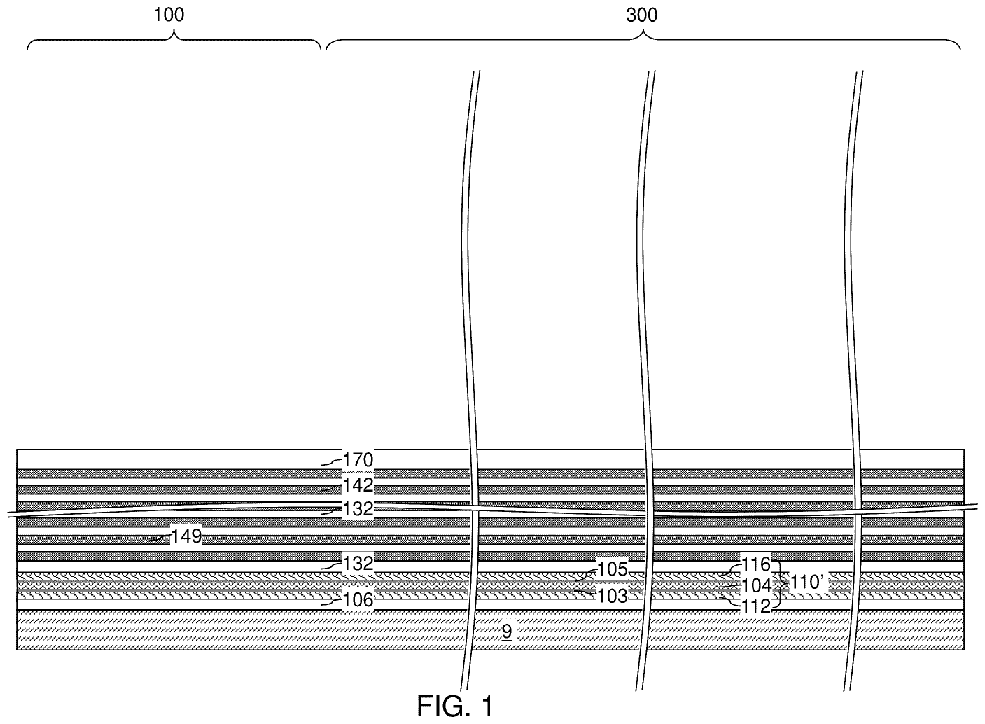

Referring to FIG. 1, a first exemplary structure according to an embodiment of the present disclosure is illustrated. The first exemplary structure comprises a carrier substrate 9, which may be a semiconductor substrate. For example, the carrier substrate 9 may comprise a commercially available silicon wafer. Alternatively, the carrier substrate 9 may comprise any material that may be removed selective the materials of overlying materials which are subsequently formed.

An optional insulating material layer can be formed on a top surface of the carrier substrate 9. The insulating material layer can be subsequently employed as a stopping material layer for an optional process that removes the carrier substrate 9, and is herein referred to as a stopper insulating layer 106. In one embodiment, the stopper insulating layer 106 comprises a dielectric material such as undoped silicate glass(i.e., silicon oxide), a doped silicate glass, or silicon nitride. The thickness of the stopper insulating layer 106 may be in a range from 50 nm to 600 nm, such as from 100 nm to 300 nm, although lesser and greater thicknesses may also be employed.

In-process source-level material layers 110′ can be formed over the stopper insulating layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner 103, a source-level sacrificial layer 104, an optional upper sacrificial liner 105, and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner 103 (or selective to the lower source-level semiconductor layer 112) and the upper sacrificial liner 105 (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner 103 (if present) and the upper sacrificial liner 105 (if present) include materials that may function as an etch stop material during removal of the source-level sacrificial layer 104. For example, the lower sacrificial liner 103 and the upper sacrificial liner 105 may include silicon oxide, silicon nitride, and/or a dielectric metal oxide. In one embodiment, each of the lower sacrificial liner 103 and the upper sacrificial liner 105 may include a silicon oxide layer having a thickness in a range from 2 nm to 30 nm, although lesser and greater thicknesses may also be used.

A first alternating stack of first insulating layers 132 and first spacer material layers can be formed over the in-process source-level material layer 110′. In one embodiment, the first spacer material layers may comprise first sacrificial material layers 142. In this case, a first alternating stack (132, 142) of first insulating layers 132 and first sacrificial material layers 142 can be formed over the in-process source-level material layer 110′. The first insulating layers 132 comprise an insulating material, such as undoped silicate glass (i.e., silicon oxide) or a doped silicate glass, and the first sacrificial material layers 142 comprise a sacrificial material, such as silicon nitride or silicon-germanium. In one embodiment, the first insulating layers 132 may comprise silicon oxide layers, and the first sacrificial material layers 142 may comprise silicon nitride layers. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from nm to 100 nm, such as from 30 nm to 60 nm, although lesser and greater thicknesses may also be employed.

A first insulating cap layer 170 can be formed over the first alternating stack (132, 142). In one embodiment, the first insulating cap layer 170 has a homogeneous material composition throughout. In one embodiment, the first insulating cap layer 170 comprises, and/or consists essentially of, a dielectric material selected from undoped silicate glass and a doped silicate glass. In one embodiment, the first insulating cap layer 170 may have a thickness in a range from 60 nm to 400 nm, such as from 100 nm to 300 nm, although lesser and greater thicknesses may also be employed.

The first insulating cap layer 170 may be formed by chemical vapor deposition. In one embodiment, the first insulating cap layer 170 comprises a silicon oxide material formed by decomposition of a precursor material (such as tetraethylorthosilicate (TEOS)) for silicon oxide deposition. In one embodiment, the first insulating cap layer 170 may include residual carbon atoms and/or residual hydrogen atoms. In one embodiment, the carbon concentration in the first insulating cap layer 170 may be in a range from 2 parts per million to 5,000 parts per million, such as from 10 parts per million to 1,000 parts per million. In one embodiment, the hydrogen concentration in the first insulating cap layer 170 may be in a range from 100 parts per million to parts per million, such as from 300 parts per million to 5,000 parts per million.

The first exemplary structure comprises a memory array region 100 in which a three-dimensional array of memory elements is to be subsequently formed, and a contact region 300 in which layer contact via structures contacting word lines are to be subsequently formed.

While an embodiment is described in which the first spacer material layers are formed as first sacrificial material layers 142, the first spacer material layers may be formed as first electrically conductive layers in an alternative embodiment. Generally, the spacer material layers formed in any alternating stack of insulating layers and spacer material layers of the present disclosure may be formed as, or may be subsequently replaced at least partly with, electrically conductive layers. Such variations of embodiments of the present disclosure are expressly contemplated herein.

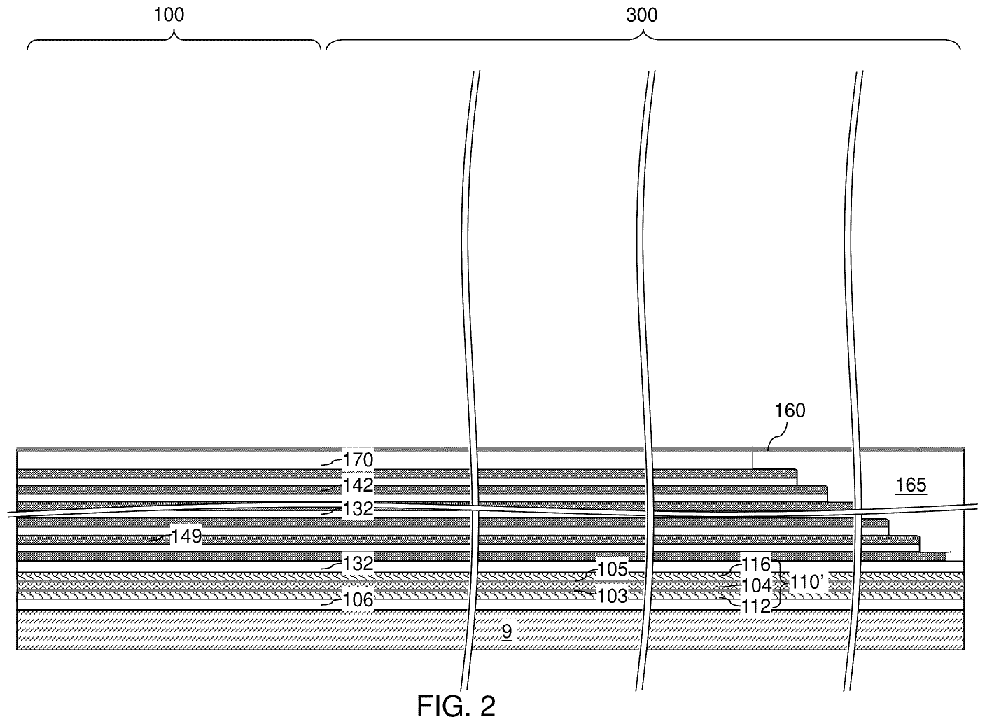

Referring to FIG. 2, first stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first alternating stack (132, 142) and the first insulating cap layer 170 are removed through formation of the first stepped surfaces. A “stepped cavity” refers to a cavity having stepped surfaces.

The first stepped cavity can have various first stepped surfaces such that the horizontal cross-sectional shape of the first stepped cavity changes in steps as a function of the vertical distance from the top surface of the in-process source-level material layer 110′. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the first alternating stack (132, 142) laterally extends farther than any overlying first sacrificial material layer 142 within the first alternating stack (132, 142) in the terrace region. The first stepped surfaces of the first alternating stack (132, 142) continuously extend from a bottommost layer within the first alternating stack (132, 142) to the first insulating cap layer 170. Generally, the first stepped surfaces continuously extend from a bottommost layer within the first alternating stack (132, 142) at least to a topmost layer within the first alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the first stepped cavity. Excess portions of the deposited dielectric material can be removed from above the top surface of the first insulating cap layer 170, for example, by chemical mechanical planarization (CMP). The remaining portion of the deposited dielectric material filling the first stepped cavity constitutes the first stepped dielectric material portion 165. As used herein, a “stepped” element refers to an element that has first stepped surfaces and a horizontal cross-sectional area that increases monotonically as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F. In one embodiment, the first stepped dielectric material portion 165 overlies and contacts the first stepped surfaces, and has a top surface that is coplanar with the top surface of the first insulating cap layer 170.

According to a first embodiment of the present disclosure, a first transition-metal oxide etch stop layer 160 including a dielectric metal oxide of a transition metal can be deposited over the top surface of first insulating cap layer 170 and the first stepped dielectric material portion 165. In general, the dielectric metal oxide of the transition metal, i.e., a transition-metal dielectric oxide, may be any dielectric oxide of a transition metal that provides a higher etch selectivity to fluorine-based anisotropic etch chemistry than silicon oxide or silicon nitride. In one embodiment, the dielectric metal oxide of the transition metal in the first transition-metal oxide etch stop layer 160 may comprise and/or may consist essentially of a dielectric metal oxide of a Group IVB element such as Ti, Zr, and/or Hf. For example, the dielectric metal oxide of the transition metal in the first transition-metal oxide etch stop layer 160 may comprise and/or may consist essentially of an oxide of a Group IVB element selected from Zr and/or Hf. The first transition-metal oxide etch stop layer 160 may be deposited by chemical vapor deposition, atomic layer deposition, sputtering, or other deposition processes known in the art. In one embodiment, the thickness of the first transition-metal oxide etch stop layer 160 may be in a range from 10 nm to 100 nm, such as from 20 nm to 50 nm, although lesser and greater thicknesses may also be employed. In the first embodiment, the first transition-metal oxide etch stop layer 160 overlies and contacts the top surface of the first stepped dielectric material portion 165 and on the top surface of the first insulating cap layer 170.

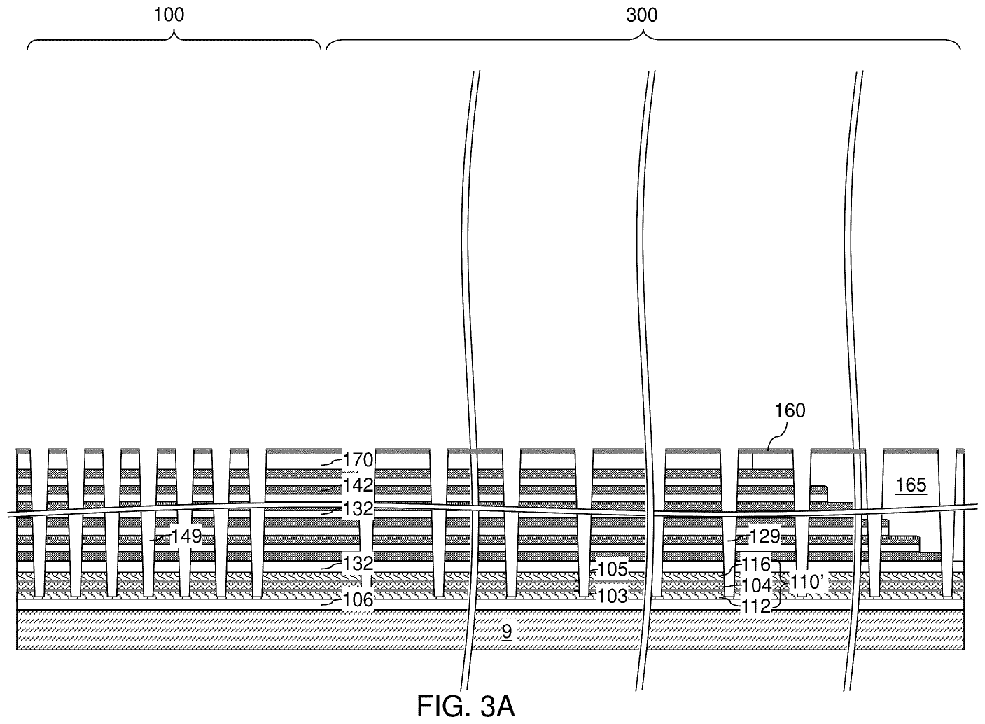

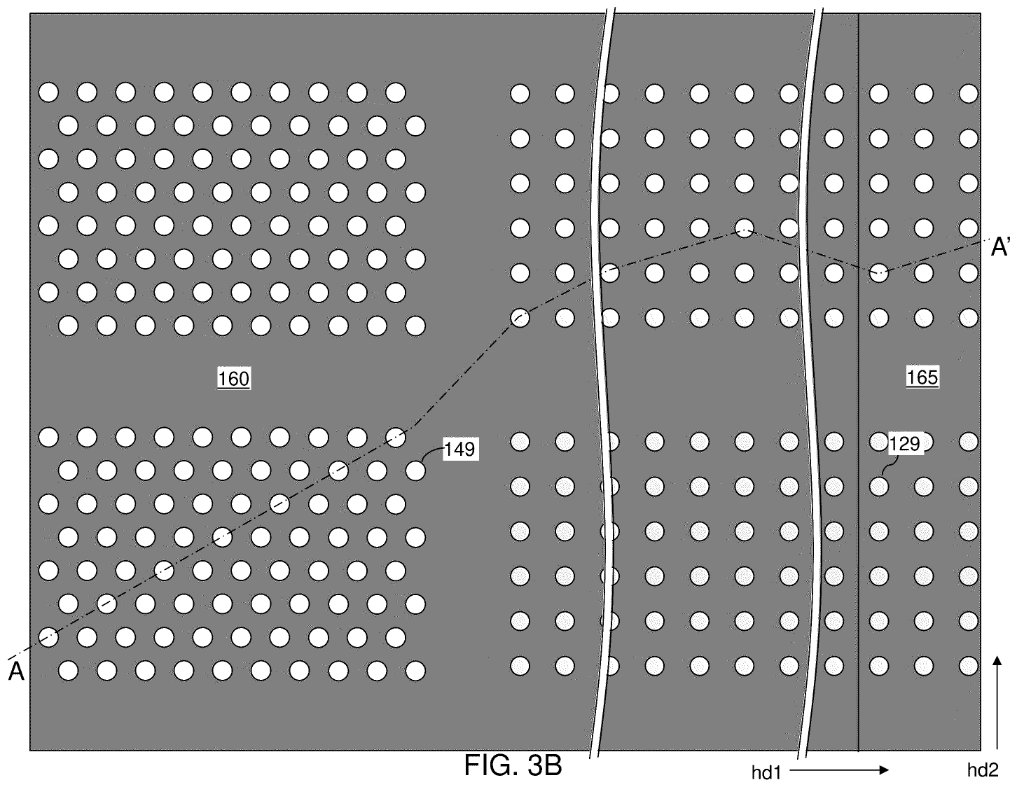

Referring to FIGS. 3A and 3B, a first etch mask layer (not shown) can be formed over the first transition-metal oxide etch stop layer 160, and can be lithographically patterned to form various openings therein. A first anisotropic etch process can be performed to transfer the pattern of the openings in the first etch mask layer through the first transition-metal oxide etch stop layer 160, the first alternating stack (132, 142), and the first stepped dielectric material portion 165. Various openings can be formed through first transition-metal oxide etch stop layer 160, the first alternating stack (132, 142), and the first stepped dielectric material portion 165. The various openings may comprise first-tier memory openings 149 that are formed in the memory array region 100 and first-tier support openings 129 that are formed in the contact region 300. Each of the first-tier memory openings 149 and the first-tier support openings 129 can vertically extend through the first alternating stack (132, 142) and into the in-process source-level material layers 110′. In one embodiment, bottom surfaces of the first-tier memory openings 149 and the first-tier support openings 129 may be formed within the lower source-level semiconductor layer 112 or at an interface between the lower source-level semiconductor layer and the stopper insulating layer 106.

The first-tier support openings 129 may have a maximum diameter in a range from 50 nm to 400 nm, such as from 70 nm to 300 nm, although lesser and greater maximum diameters may be employed. The first-tier memory openings 149 may have a maximum diameter in a range from 50 nm to 400 nm, such as from 70 nm to 300 nm, although lesser and greater maximum diameters may be employed.

In one embodiment, the memory array region 100 may be laterally spaced apart from the contact region 300 along a first horizontal direction hd1. The first-tier memory openings 149 may comprise rows of first-tier memory openings 149 that are arranged along the first horizontal direction hd1 and laterally spaced apart along a second horizontal direction hd2 that is perpendicular to the first horizontal direction hd2. Multiple clusters of first-tier memory openings 149, each containing a respective two-dimensional periodic array of first-tier memory openings 149, may be formed in the memory array region 100. The clusters of first-tier memory openings 149 may be laterally spaced apart along the second horizontal direction hd2.

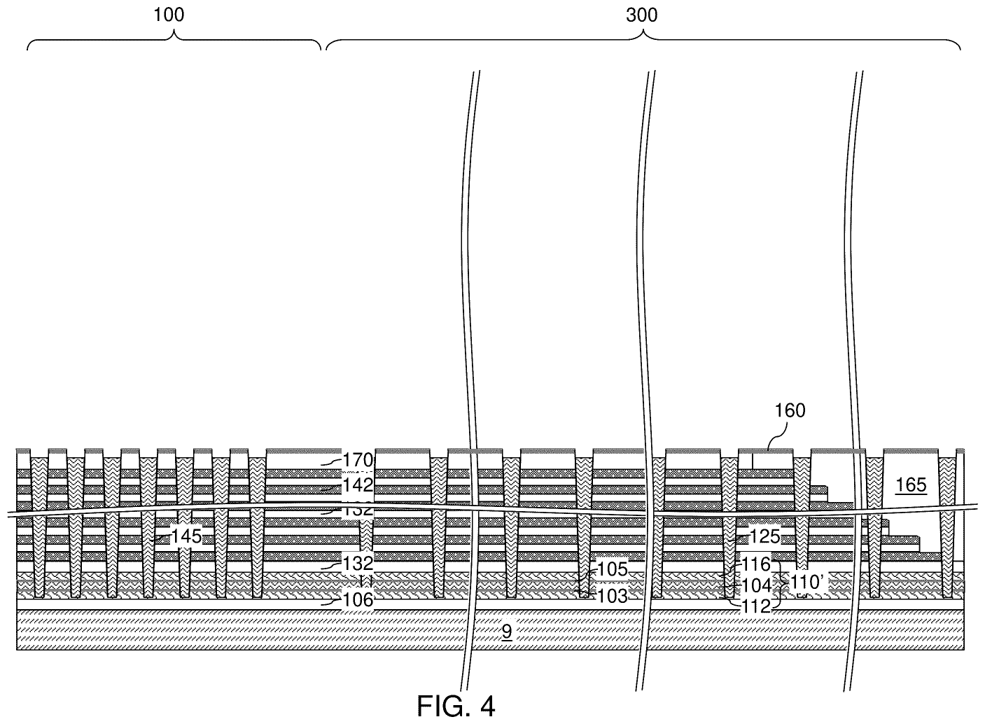

Referring to FIG. 4, an optional etch stop liner (not shown) and a first sacrificial fill material can be deposited in the first-tier memory openings 149 and the first-tier support openings 129. The optional etch stop liner (if present) comprises a thin silicon oxide layer having a thickness in a range from 1 nm to 6 nm. The first sacrificial fill material may comprise a carbon-based material, such as amorphous carbon or diamond-like carbon.

A recess etch process can be performed to remove portions of the first sacrificial fill material from above the horizontal plane including the top surface of the first insulating cap layer 170. The recess etch process can be continued such that each remaining portion of the first sacrificial fill material has a top surface between a horizontal plane including a top surface of the first insulating cap layer 170 and a horizontal plane including a bottom surface of the first insulating cap layer 170. Remaining portions of the first sacrificial fill material that fill the first-tier memory openings 149 and the first-tier support openings 129 constitute first lower sacrificial opening fill material portions (145, 125). The first lower sacrificial opening fill material portions (145, 125) comprise first lower sacrificial memory opening fill material portions 145 that are formed in the first-tier memory openings 149, and first lower sacrificial support opening fill material portions 125 that are formed in the first-tier support openings 129. A recess cavity 150 is formed above each first lower sacrificial opening fill material portions (145, 125). The depth of the recess cavities may be in a range from 10% to 60%, such as from 20% to 50%, of the thickness of the first insulating cap layer 170.

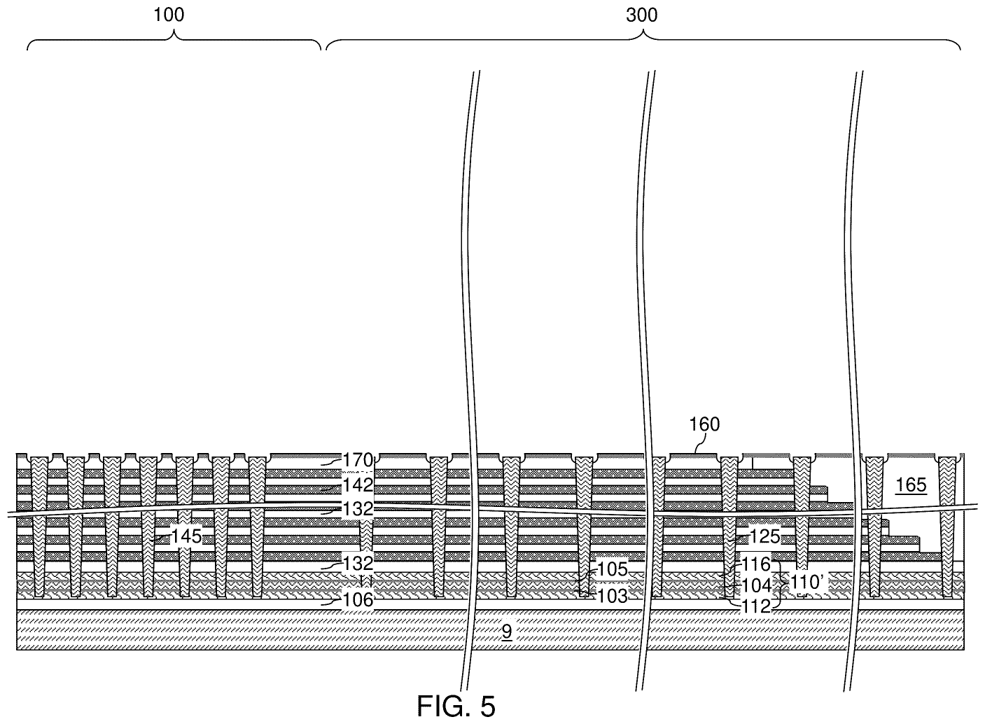

Referring to FIG. 5, an isotropic etch process can be performed to etch the material of the first insulating cap layer 170 selective to the material of the first transition-metal oxide etch stop layer 160 and selective to the material of the first lower sacrificial opening fill material portions (145, 125). Each recess cavity 150 overlying the first lower sacrificial opening fill material portions (145, 125) can be isotropically expanded as the surface portions of the first lower sacrificial opening fill material portions (145, 125) are isotropically recessed by during the isotropic etch process.

The etch distance of the isotropic etch process may be in a range from 10% to 40%, such as from 15% to 30%, of the thickness of the first insulating cap layer 170 as provided after the processing steps of FIG. 4 prior to the processing steps of FIG. 5. The etch distance may be in a range from 10 nm to 160 nm, such as from 20 nm to 100 nm, although lesser and greater etch distances may also be employed. The top surface of the first insulating cap layer 170 can be vertically recessed by the etch distance of the isotropic etch process. The thickness of the first insulating cap layer 170 after the isotropic etch process may be in a range from 50 nm to 360 nm, such as from 80 nm to 240 nm, although lesser and greater thicknesses may also be employed. Each recessed surface around a cavity 150 in an upper portion of a respective one of the first-tier memory openings 149 and the first-tier support openings 129 may comprise a cylindrical surface segment and an annular tapered concave surface segment that is adjoined to a bottom periphery of the cylindrical surface segment. The annular tapered concave surface segment may have a radius of curvature that is the same as the etch distance of the isotropic etch process.

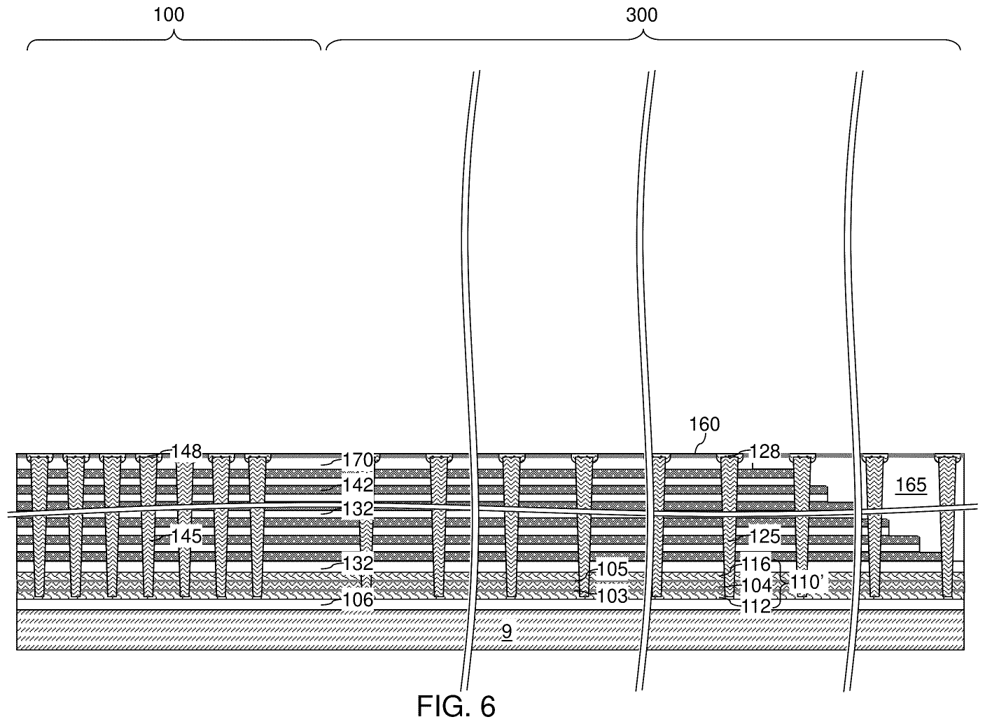

Referring to FIG. 6, a first sacrificial capping material can be deposited in the cavities 150 in the upper portions of the first-tier memory openings 149 and the first-tier support openings 129. The first sacrificial capping material may comprise a carbon-based material, such as amorphous carbon or diamond-like carbon. In one embodiment, the first sacrificial capping material may be the same as the first sacrificial fill material.

A planarization process can be performed to remove portions of the first sacrificial capping material from above the horizontal plane including the top surface of the first transition-metal oxide etch stop layer 160. For example, a chemical mechanical polishing process can be performed to remove the portions of the first sacrificial capping material the overlie the horizontal plane including the first transition-metal oxide etch stop layer 160. Remaining portions of the first sacrificial capping material that fill the first-tier memory openings 149 and the first-tier support openings 129 constitute first upper sacrificial capping material portions (148, 128). The first upper sacrificial capping material portions (148, 128) comprise first upper sacrificial memory capping material portions 148 that are formed in the first-tier memory openings 149, and first upper sacrificial support capping material portions 128 that are formed in the first-tier support openings 129.

Each contiguous combinations of first lower sacrificial capping material portions (145, 125) and respective first upper sacrificial capping material portions (148, 128) constitute first sacrificial opening fill structures {(145, 148), (125, 128)}. The first sacrificial opening fill structures {(145, 148), (125, 128)} comprise first sacrificial memory opening fill structures (145, 148) and first sacrificial support opening fill structures (125, 128). Each first sacrificial memory opening fill structure (145, 148) comprises a first lower sacrificial memory opening fill material portion 145 and a first upper sacrificial memory capping material portion 148. Each first sacrificial support opening fill structure (125, 128) comprises a first lower sacrificial support opening fill material portion 125 and a first upper sacrificial support capping material portion 128.

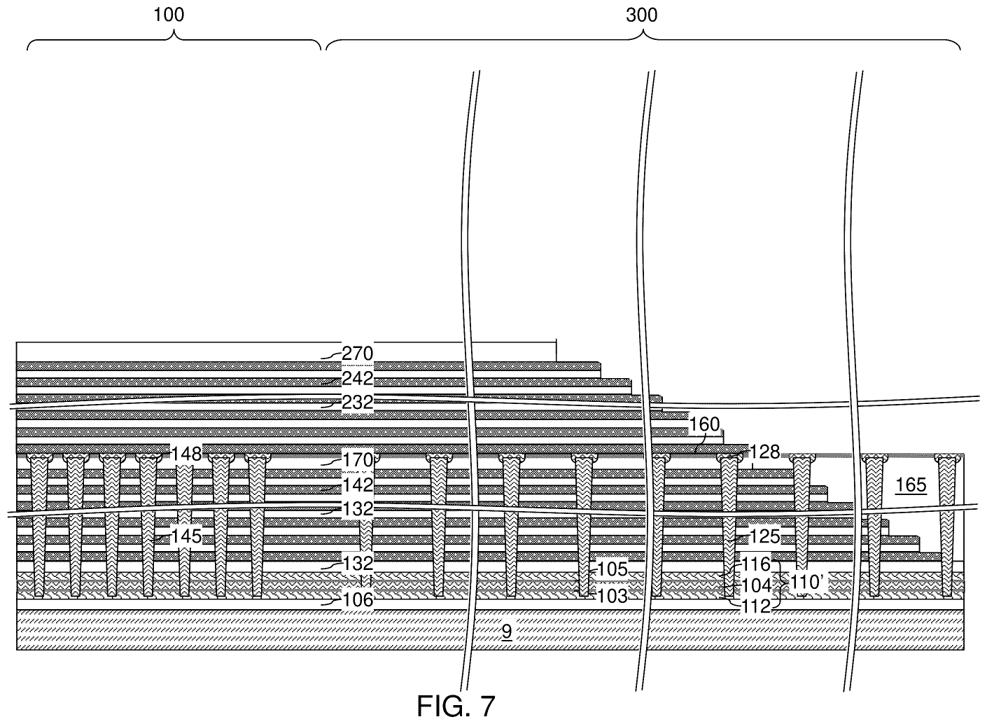

Referring to FIG. 7, a second alternating stack of second insulating layers 232 and second spacer material layers can be formed over the first transition-metal oxide etch stop layer 160. In one embodiment, the second spacer material layers may comprise second sacrificial material layers 242. In this case, a second alternating stack (232, 242) of second insulating layers 232 and second sacrificial material layers 242 can be formed over the first transition-metal oxide etch stop layer 160. In one embodiment, the second insulating layers 232 may comprise silicon oxide layers, and the second sacrificial material layers 242 may comprise silicon nitride layers. The second alternating stack (232, 242) may comprise multiple repetitions of a unit layer stack including a second insulating layer 232 and a second sacrificial material layer 242. The total number of repetitions of the unit layer stack within the second alternating stack (232, 242) may be, for example, in a range from 8 to 2,024, such as from 32 to 256, although lesser and greater number of repetitions may also be employed.

A second insulating cap layer 270 can be formed over the second alternating stack (232, 242). In one embodiment, the second insulating cap layer 270 has a homogeneous material composition throughout. In one embodiment, the second insulating cap layer 270 comprises, and/or consists essentially of silicon oxide. The second insulating cap layer 270 may have the same thickness and composition as the first insulating cap layer 270. Second stepped surfaces are formed in the contact region 300. A second stepped cavity is formed within the volume from which portions of the second alternating stack (232, 242) and the second insulating cap layer 270 are removed through formation of the second stepped surfaces.

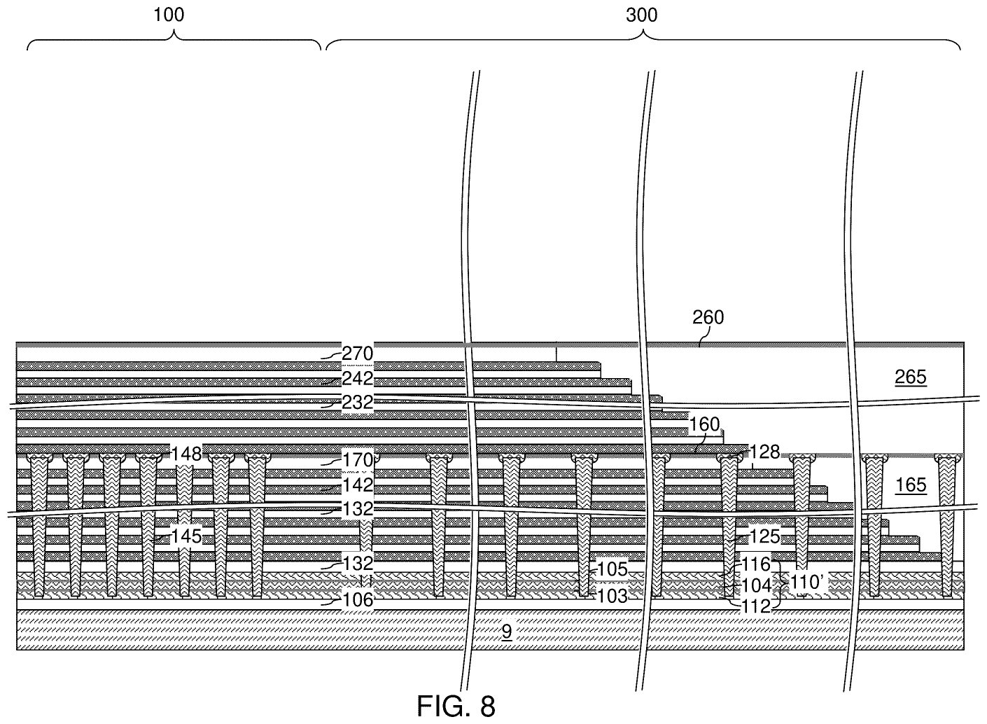

Referring to FIG. 8, a second stepped dielectric material portion 265 (i.e., an insulating fill material portion) can be formed in the second stepped cavity by deposition of a dielectric material followed by planarization. The second stepped dielectric material portion 265 may have the same composition and configuration as the first stepped dielectric material portion 165.

Optionally, a second transition-metal oxide etch stop layer 260 including a dielectric metal oxide of a transition metal can be deposited over the top surface of second insulating cap layer 270 and the second stepped dielectric material portion 265. In general, the dielectric metal oxide of the transition metal, i.e., a transition-metal dielectric oxide, may be any dielectric oxide of a transition metal that provides a higher etch selectivity to fluorine-based anisotropic etch chemistry than silicon oxide or silicon nitride. In one embodiment, the dielectric metal oxide of the transition metal in the second transition-metal oxide etch stop layer 260 may comprise and/or may consist essentially of a dielectric metal oxide of a Group IVB element such as Ti, Zr, and/or Hf. For example, the dielectric metal oxide of the transition metal in the second transition-metal oxide etch stop layer 260 may comprise and/or may consist essentially of an oxide of a Group IVB element selected from Zr and/or Hf. The second transition-metal oxide etch stop layer 260 may be deposited by chemical vapor deposition, atomic layer deposition, sputtering, or other deposition processes known in the art. In one embodiment, the thickness of the second transition-metal oxide etch stop layer 260 may be in a range from 10 nm to 100 nm, such as from 20 nm to 50 nm, although lesser and greater thicknesses may also be employed. The second transition-metal oxide etch stop layer 260 overlies and contacts the top surface of the second stepped dielectric material portion 265 and on the top surface of the second insulating cap layer 270.

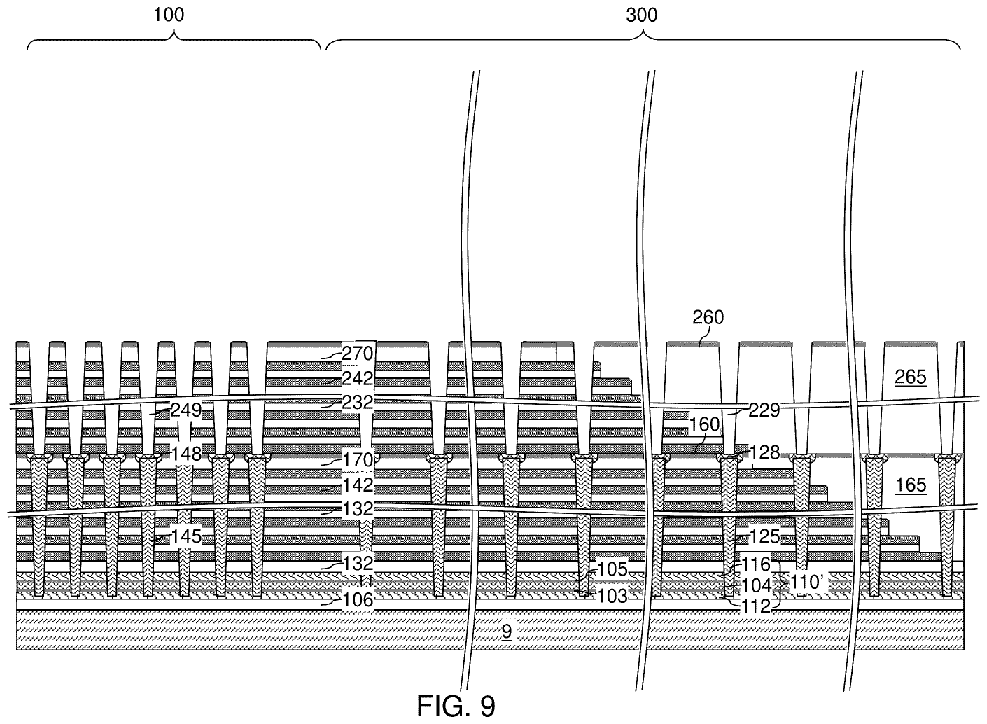

Referring to FIG. 9, a second etch mask layer (not shown) can be formed over the second transition-metal oxide etch stop layer 260, and can be lithographically patterned to form various openings therein. A second anisotropic etch process can be performed to transfer the pattern of the openings in the second etch mask layer through the second transition-metal oxide etch stop layer 260, the second alternating stack (232, 242), and the second stepped dielectric material portion 265. Various openings can be formed through the second alternating stack (232, 242) and the second stepped dielectric material portion 265. The various openings may comprise second-tier memory openings 249 that are formed in the memory array region 100 and second-tier support openings 229 that are formed in the contact region 300. Each of the second-tier memory openings 249 and the second-tier support openings 229 can vertically extend through the second alternating stack (232, 242) and on a top surface of a respective one of the first sacrificial opening fill structures {(145, 148), (125, 128)}. Specifically, a top surface of a first sacrificial memory capping portion 148 can be physically exposed underneath each second-tier memory opening 249, and a top surface of a first sacrificial support capping portion 128 can be physically exposed underneath each second-tier support opening 229. The diameter of the second-tier memory openings 249 and the second-tier support openings 229 may be the same as that of the respective first-tier memory openings 149 and the first-tier support openings 129.

In an illustrative example, the second insulating layers 232 may comprise silicon oxide and the second sacrificial material layers 242 may comprise silicon nitride, and the second anisotropic etch process may employ CF₄, CHF₃, C₄F₈, SF₆, and/or NF₃ as an etchant gas. Examples of etch chemistries that can etch silicon oxide and silicon nitride include a combination of CF₄ and CHF₃, a combination of C₄F₈ and Ar, a combination of SF₆ and O₂, or a combination of NF₃ and Ar.

As discussed above, the first sacrificial fill material of the first lower sacrificial opening fill material portions (145, 125) may comprise and/or may consist essentially of an undoped carbon-based material (such as amorphous carbon or diamond-like carbon) while the first sacrificial capping portions (148, 128) may comprise and/or may consist essentially of noble gas doped carbon.

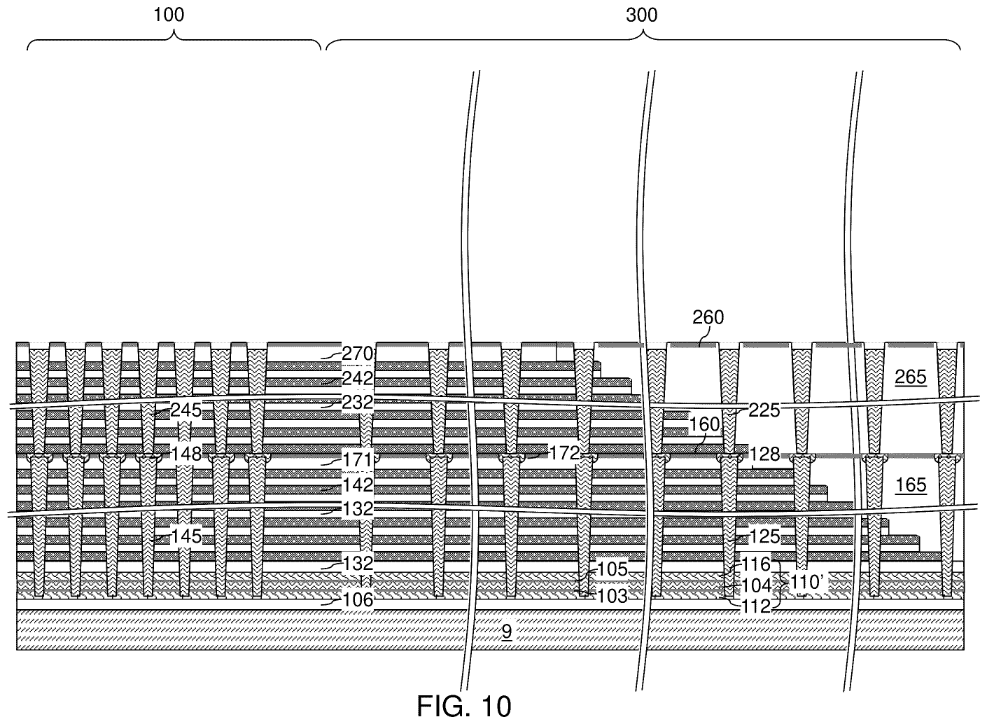

Referring to FIG. 10, an optional etch stop liner (not shown) and a second sacrificial fill material can be deposited in the second-tier memory openings 249 and the second-tier support openings 229. The optional etch stop liner (if present) comprises a thin silicon oxide layer having a thickness in a range from 2 nm to 6 nm. The second sacrificial fill material may comprise a carbon-based material such as amorphous carbon or diamond-like carbon.

A recess etch process can be performed to remove portions of the second sacrificial fill material from above the horizontal plane including the top surface of the second transition-metal oxide etch stop layer 260. The recess etch process can be continued such that each remaining portion of the second sacrificial fill material has a top surface between a horizontal plane including a top surface of the second insulating cap layer 270 and a horizontal plane including a bottom surface of the second insulating cap layer 270. Remaining portions of the second sacrificial fill material that fill the second-tier memory openings 249 and the second-tier support openings 229 constitute second lower sacrificial opening fill material portions (245, 225). The second lower sacrificial opening fill material portions (245, 225) comprise second lower sacrificial memory opening fill material portions 245 that are formed in the second-tier memory openings 249, and second lower sacrificial support opening fill material portions 225 that are formed in the second-tier support openings 229. A recess cavity is formed above each second lower sacrificial opening fill material portions (245, 225).

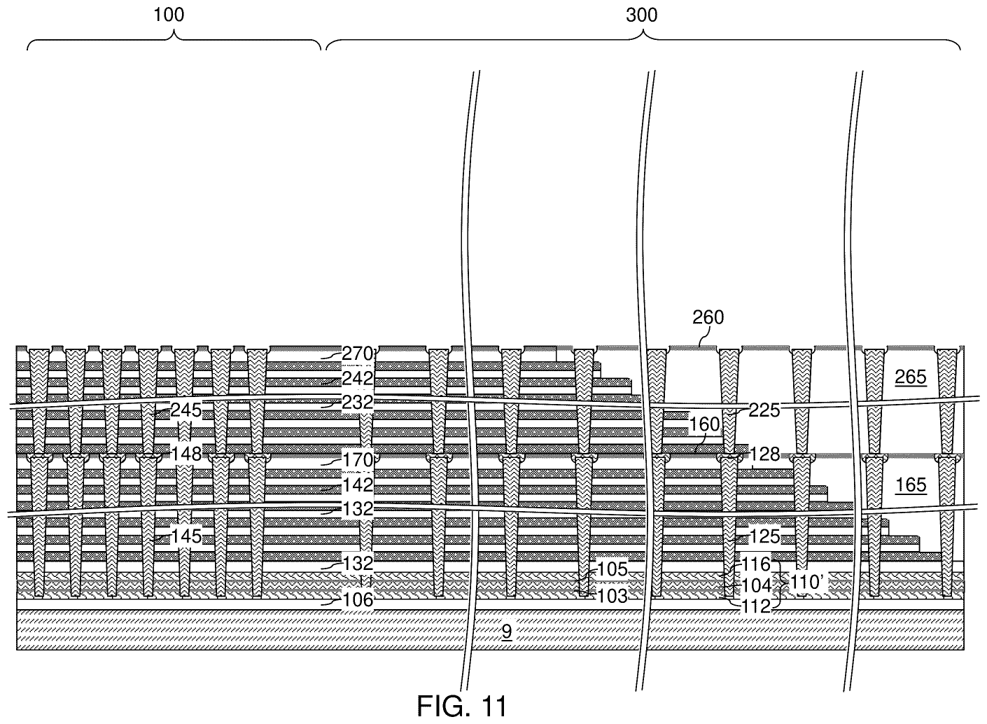

Referring to FIG. 11, an isotropic etch process can be performed to etch the material of the second insulating cap layer 270 selective to the material of the second transition-metal oxide etch stop layer 260 and selective to the material of the second lower sacrificial opening fill material portions (245, 225). Each recessed surface around the recess cavity in an upper portion of a respective one of the second-tier memory openings 249 and the second-tier support openings 229 may comprise a cylindrical surface segment and an annular tapered concave surface segment that is adjoined to a bottom periphery of the cylindrical surface segment. The annular tapered concave surface segment may have a radius of curvature that is the same as the etch distance of the isotropic etch process.

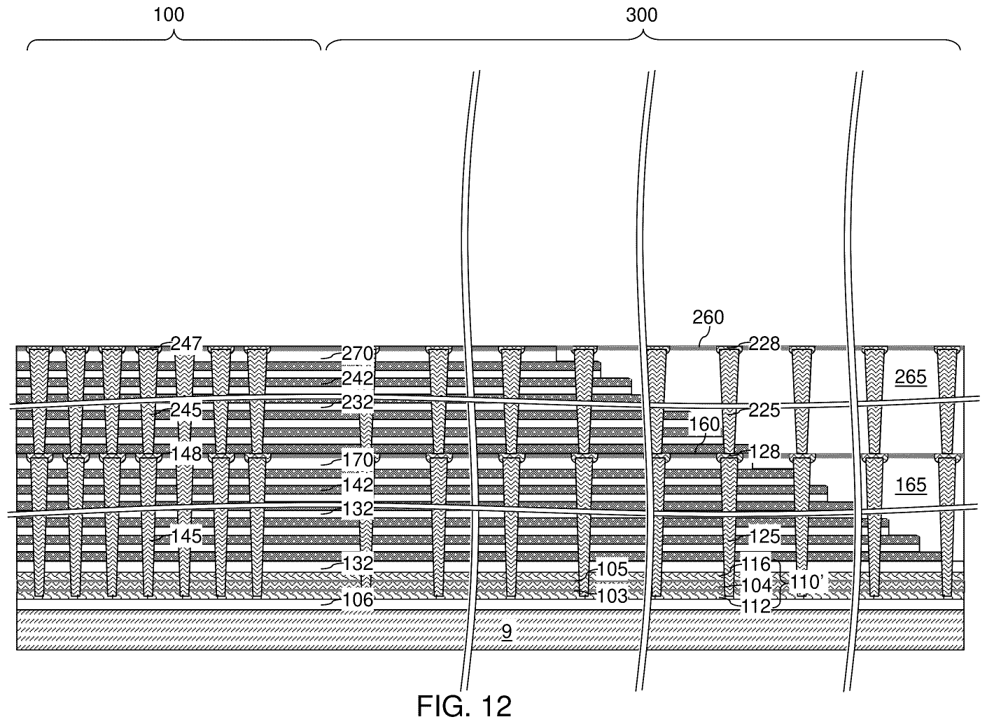

Referring to FIG. 12, a second sacrificial capping material can be deposited in the cavities in the upper portions of the second-tier memory openings 249 and the second-tier support openings 229. The second sacrificial capping material may comprise a carbon-based material such as amorphous carbon or diamond-like carbon. In one embodiment, the second sacrificial capping material may be the same as the second sacrificial fill material.

A planarization process can be performed to remove portions of the second sacrificial capping material from above the horizontal plane including the top surface of the second transition-metal oxide etch stop layer 260. Remaining portions of the second sacrificial capping material that fill the second-tier memory openings 249 and the second-tier support openings 229 constitute second upper sacrificial capping material portions (248, 228). The second upper sacrificial capping material portions (248, 228) comprise second upper sacrificial memory capping material portions 248 that are formed in the second-tier memory openings 249, and second upper sacrificial support capping material portions 228 that are formed in the second-tier support openings 229.

Each contiguous combination of second lower sacrificial capping material portions (245, 225) and second upper sacrificial capping material portions (248, 228) constitute second sacrificial opening fill structures {(245, 248), (225, 228)} which comprise second sacrificial memory opening fill structures (245, 248) and second sacrificial support opening fill structures (225, 228). Each second sacrificial memory opening fill structure (245, 248) comprises a second lower sacrificial memory opening fill material portion 245 and a second upper sacrificial memory capping material portion 248. Each second sacrificial support opening fill structure (225, 228) comprises a second lower sacrificial support opening fill material portion 225 and a second upper sacrificial support capping material portion 228.

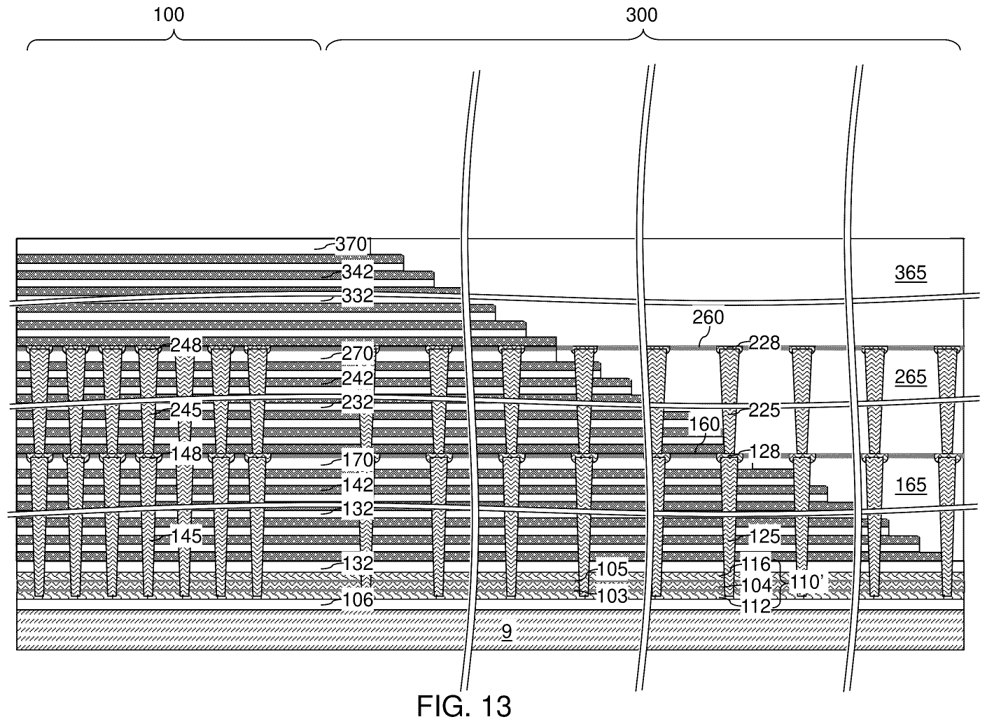

Referring to FIG. 13, a third alternating stack of third insulating layers 332 and third spacer material layers can be formed over the second transition-metal oxide etch stop layer 260. In one embodiment, the third spacer material layers may comprise third sacrificial material layers 342. In this case, a third alternating stack (332, 342) of third insulating layers 332 and third sacrificial material layers 342 can be formed over the second transition-metal oxide etch stop layer 260. In one embodiment, the third insulating layers 332 may comprise silicon oxide layers, and the third sacrificial material layers 342 may comprise silicon nitride layers. The third alternating stack (332, 342) may comprise multiple repetitions of a unit layer stack including a third insulating layer 332 and a third sacrificial material layer 342. The total number of repetitions of the unit layer stack within the third alternating stack (332, 342) may be, for example, in a range from 8 to 1,024, such as from 32 to 256, although lesser and greater number of repetitions may also be employed. An insulating cap layer 370, such as a silicon oxide layer, can be formed over the third alternating stack (332, 342). While an embodiment is described in which the third spacer material layers are formed as third sacrificial material layers 342, the third spacer material layers may be formed as third electrically conductive layers in an alternative embodiment.

Third stepped surfaces are formed in the contact region 300. A third stepped cavity is formed within the volume from which portions of the third alternating stack (332, 342) and the insulating cap layer 370 are removed through formation of the third stepped surfaces. A third stepped dielectric material portion 365 (i.e., an insulating fill material portion) can be formed in the third stepped cavity by deposition of a dielectric material therein followed by planarization. The remaining portion of the deposited dielectric material filling the third stepped cavity constitutes the third stepped dielectric material portion 365.

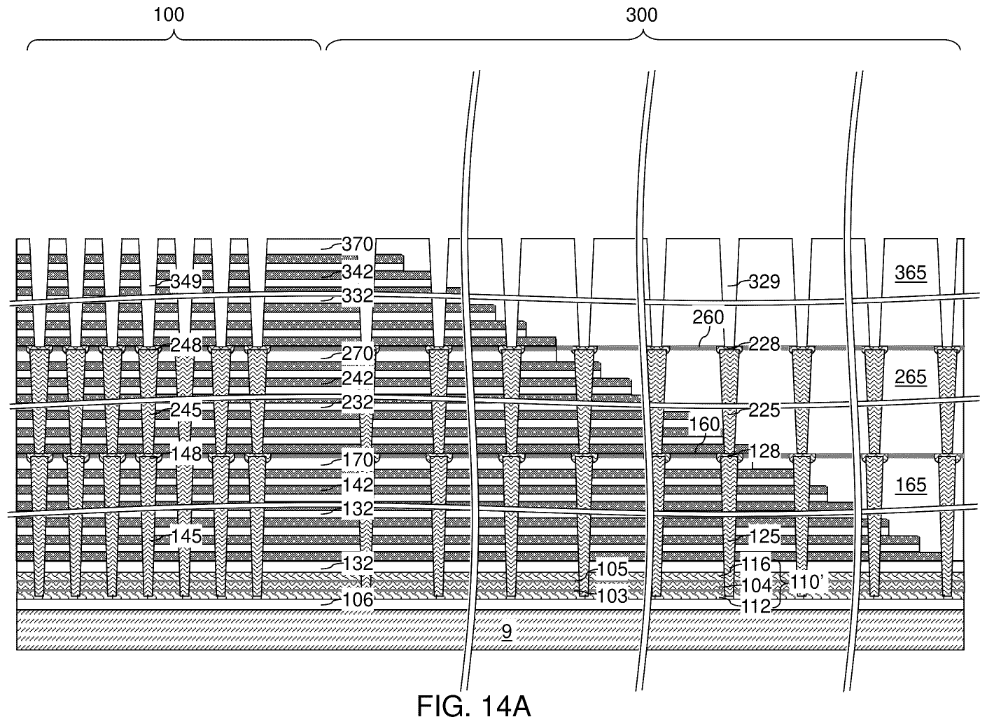

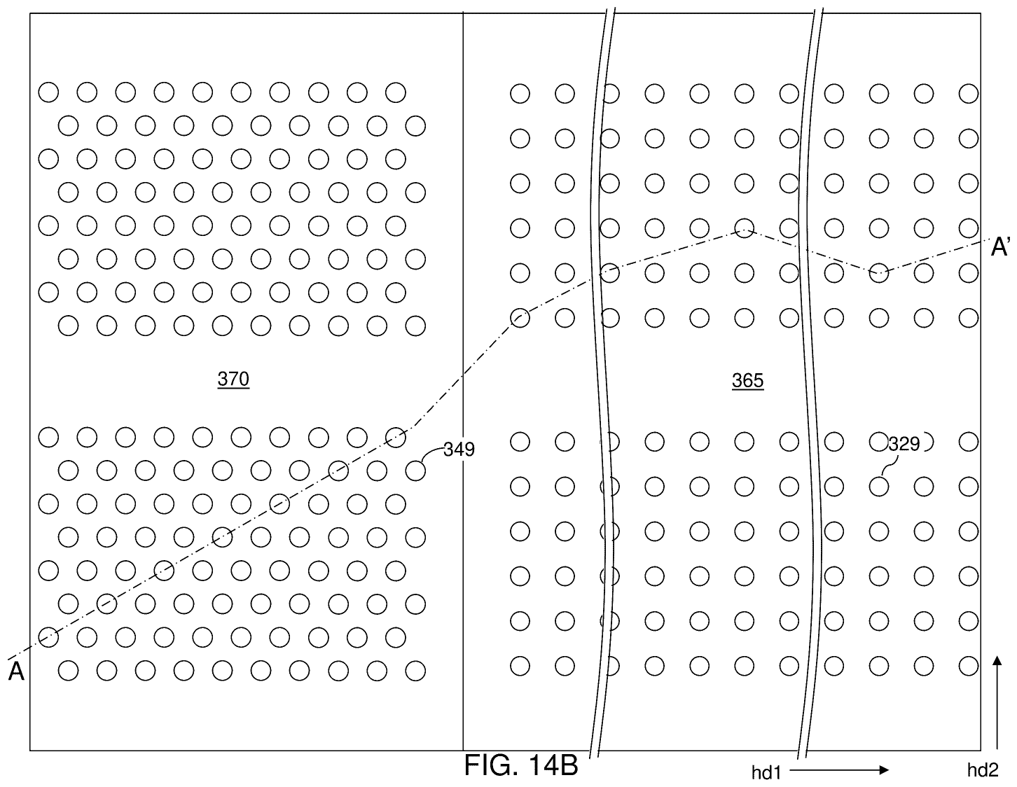

Referring to FIGS. 14A and 14B, a third etch mask layer (not shown) can be formed over the insulating cap layer 370, and can be lithographically patterned to form various openings therein. A third anisotropic etch process can be performed to transfer the pattern of the openings in the third etch mask layer through the third alternating stack (332, 342) and the third stepped dielectric material portion 365. Various openings can be formed through the third alternating stack (332, 342) and the third stepped dielectric material portion 365. The various openings may comprise third-tier memory openings 349 that are formed in the memory array region 100 and third-tier support openings 329 that are formed in the contact region 300. Each of the third-tier memory openings 349 and the third-tier support openings 329 can vertically extend through the third alternating stack (332, 342) and on a top surface of a respective one of the second sacrificial opening fill structures {(245, 248), (225, 228)}. Specifically, a top surface of a second sacrificial memory capping portion 248 can be physically exposed underneath each third-tier memory opening 349, and a top surface of a second sacrificial support capping portion 228 can be physically exposed underneath each third-tier support opening 329.

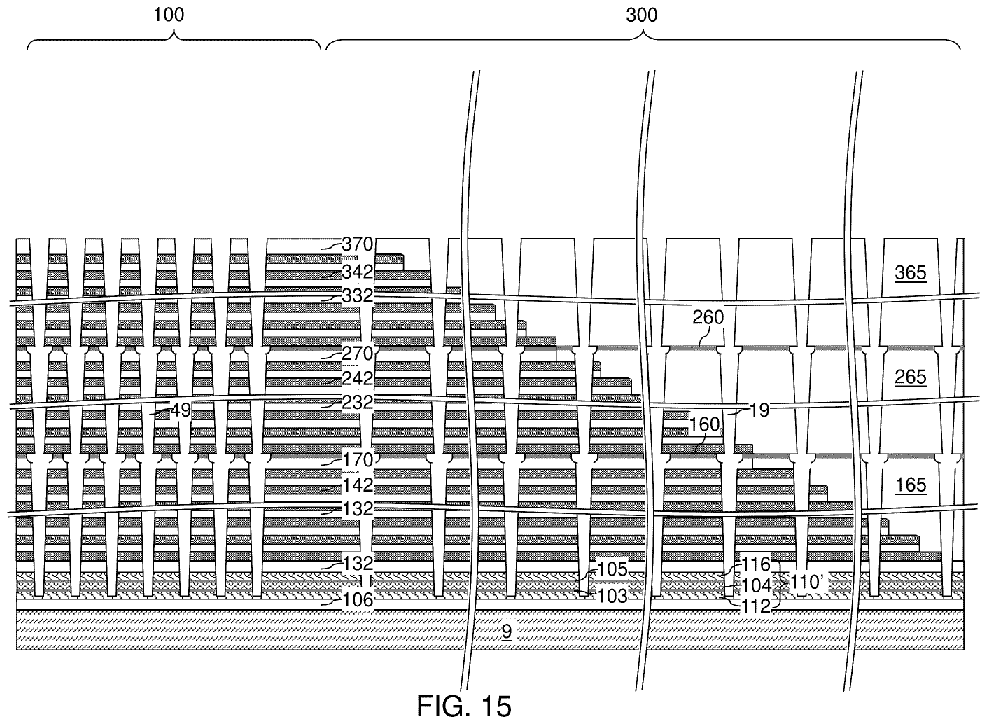

Referring to FIG. 15, the sacrificial fill materials of the second sacrificial opening fill structures {(245, 248), (125, 128)} and the first sacrificial opening fill structure {(145, 148), (125, 128)} can be removed without significant removal of the materials of the alternating stacks {(132, 142), (232, 242), (332, 342)}, the insulating cap layers (170, 270, 370), the transition-metal oxide etch stop layers (160, 260), or the stepped dielectric material portions (165, 265, 365). In case etch stop liners are present around the sacrificial fill materials of the second sacrificial opening fill structures {(245, 248), (125, 128)} and the first sacrificial opening fill structure {(145, 148), (125, 128)}, the sacrificial fill materials of the second sacrificial opening fill structures {(245, 248), (125, 128)} and the first sacrificial opening fill structure {(145, 148), (125, 128)} can be removed selective to the materials of the etch stop liners, and the etch stop liners can be subsequently removed, for example, by performing an isotropic etch process. In case the etch stop liners are not present, the sacrificial fill materials of the second sacrificial opening fill structures {(245, 248), (125, 128)} and the first sacrificial opening fill structure {(145, 148), (125, 128)} can be removed selective to the materials of the alternating stacks {(132, 142), (232, 242), (332, 342)}, the insulating cap layers (170, 270, 370), the transition-metal oxide etch stop layers (160, 260), or the stepped dielectric material portions (165, 265, 365).

The carbon sacrificial fill materials of the second sacrificial opening fill structures {(245, 248), (125, 128)} and the first sacrificial opening fill structure {(145, 148 or 148), (125, 128 or 148)} may be removed by ashing. Multi-tier memory openings 49 are formed in the volumes of the third-tier memory openings 349 and the volumes from which the second sacrificial memory opening fill structures {(245, 248), (125, 128)} are removed. The multi-tier memory openings 49 may also be referred to as memory openings 49. Multi-tier support openings 19 can be formed in the volumes of the third-tier support openings 329 and the volumes from which the first sacrificial support opening fill structures {(145, 148), (125, 128)} are removed. The multi-tier support openings 19 may also be referred to as support openings 19.

Each memory opening 49 comprises a volume of a third-tier memory opening 349, a second-tier memory opening 249, and a first-tier memory opening 149. In one embodiment, a memory opening 49 may have a first lateral extent at a horizontal plane including a bottom surface of a bottommost layer of the second alternating stack (232, 242). The first lateral extent may be less than a second lateral extent of the memory opening 49 at a horizontal plane including a top surface of the first insulating cap layer 170. In one embodiment, the memory opening 49 may have a third lateral extent at a horizontal plane including a bottom surface of a bottommost layer of the third alternating stack (332, 342). The third lateral extent may be less than a fourth lateral extent of the memory opening 49 at a horizontal plane including a top surface of the second insulating cap layer 270. In other words, the memory opening 49 may optionally have widened portions between device tiers, such as at the levels of the first and second insulating cap layers (170, 270) that were previously filled with the first and second upper sacrificial capping material portions (148, 248).

In an alternative embodiment, the memory opening widening steps shown in FIGS. 5 and 11 may be omitted. In this alternative embodiment, the formation of the first and second upper sacrificial capping material portions (148, 248) in FIGS. 6 and 12 may also be omitted. Therefore, in this alternative embodiment, the memory opening 49 does not have widened portions between device tiers at the levels of the first and second insulating cap layers (170, 270).

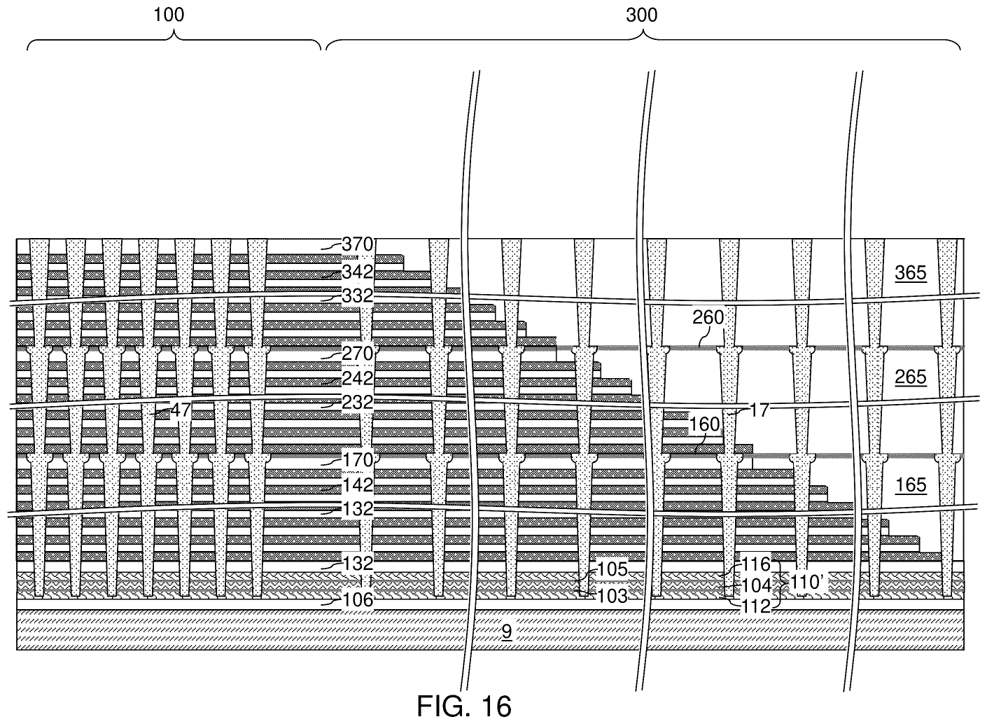

Referring to FIG. 16, in an optional embodiment where memory opening fill structures and the support pillar structures comprise different materials, an optional sacrificial fill material can be deposited in the memory openings 49 and the support openings 19. The sacrificial fill material may be formed by a non-conformal deposition or a conformal deposition method. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material may be removed from above the horizontal plane including the top surfaces of the insulating cap layer 370 and the third stepped dielectric material portion 365 by a planarization process such as a recess etch process. Sacrificial multi-tier memory opening fill structures 47 can be formed in the multi-tier memory openings 49, and sacrificial multi-tier support opening fill structures 17 can be formed in the multi-tier support openings 19.

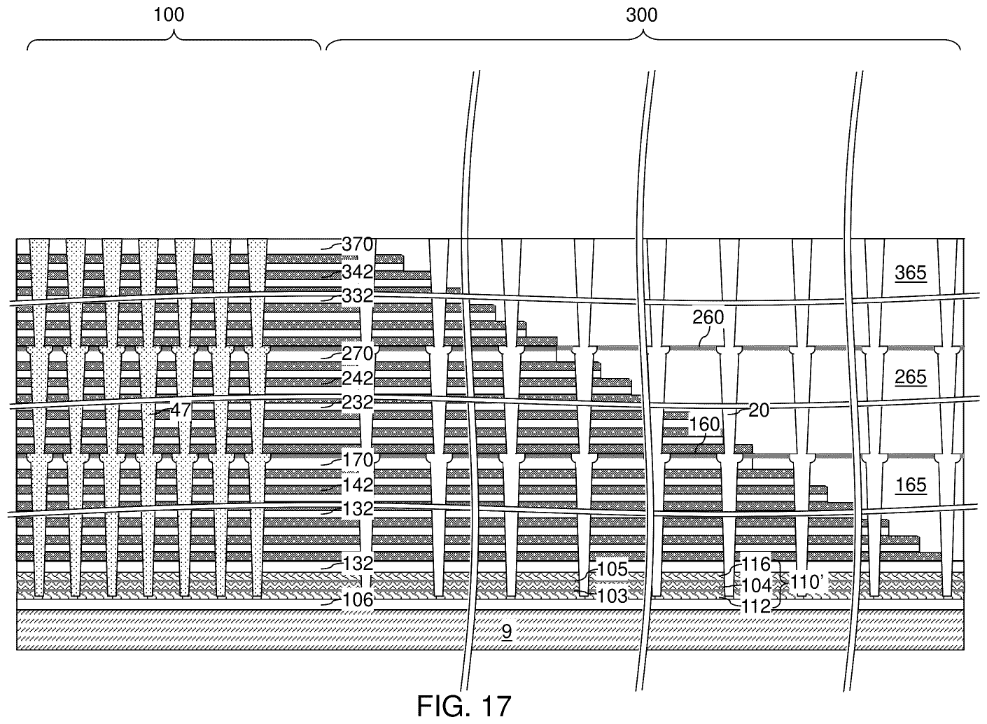

Referring to FIG. 17, a photoresist layer (not shown) can be applied over the insulating cap layer 370 and the third stepped dielectric material portion 365, and can be lithographically patterned to cover the memory array region 100 without covering the contact region 300. The sacrificial multi-tier support opening fill structures 17 in the contact region 300 can be removed selective to the materials of the alternating stacks {(132, 142), (232, 242), (332, 342)}, the insulating cap layers (170, 270, 370), the transition-metal oxide etch stop layers (160, 260), and the stepped dielectric material portions (165, 265, 365). For example, an etch process or an ashing process may be employed to remove the sacrificial multi-tier support opening fill structures 17 in the contact region 300. The photoresist layer can be subsequently removed.

A dielectric fill material, such as silicon oxide, can be deposited in the cavities in the multi-tier support openings 19 by a conformal deposition process. Excess portions of the dielectric fill material can be removed from above the top surface of the insulating cap layer 370, for example, by a recess etch process. Each portion of the dielectric fill material that fills a respective multi-tier support opening 19 constitutes a support pillar structure 20, which can be employed to provide structural support to the insulating layers (132, 232, 332) and the stepped dielectric material portions (165, 265, 365) during subsequent replacement of the sacrificial material layers (142, 242, 342) with electrically conductive layers.

Each support pillar structure 20 vertically extends at least from a horizontal plane including the bottom surface of the first alternating stack (132, 142), and at least to a horizontal plane including the top surface of the third alternating stack (332, 342). In one embodiment, each support pillar structure 20 consists essentially of at least one dielectric fill material. In one embodiment, each support pillar structure 20 comprises a first dielectric sidewall that vertically extends through the first alternating stack (132, 142) and the lower first insulating cap layer 170; a second dielectric sidewall that vertically extends through the second alternating stack (232, 242); and a third dielectric sidewall that vertically extends through the third alternating stack (332, 342). In one embodiment, each support pillar structure 20 further comprises a first contoured dielectric surface that connects the first dielectric sidewall and the second dielectric sidewall. The first contoured dielectric surface comprises a first planar annular top dielectric surface segment located within a horizontal plane including a top surface of the first transition-metal oxide etch stop layer 160 and further comprises a first convex annular dielectric sidewall segment that contacts a concave surface segment of the first transition-metal oxide etch stop layer 160. Further, each support pillar structure 20 further comprises a second contoured dielectric surface that connects the second dielectric sidewall and the third dielectric sidewall. The second contoured dielectric surface comprises a second planar annular top dielectric surface segment located within a horizontal plane including a top surface of the second transition-metal oxide etch stop layer 260 and further comprises a second convex annular dielectric sidewall segment that contacts a concave surface segment of the second transition-metal oxide etch stop layer 260.

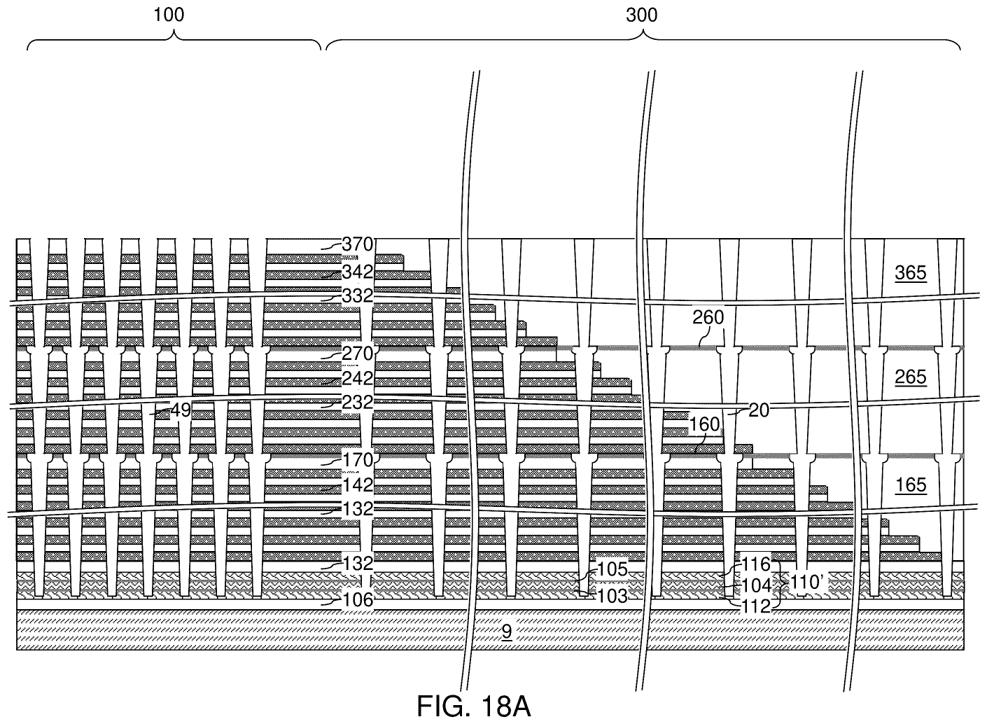

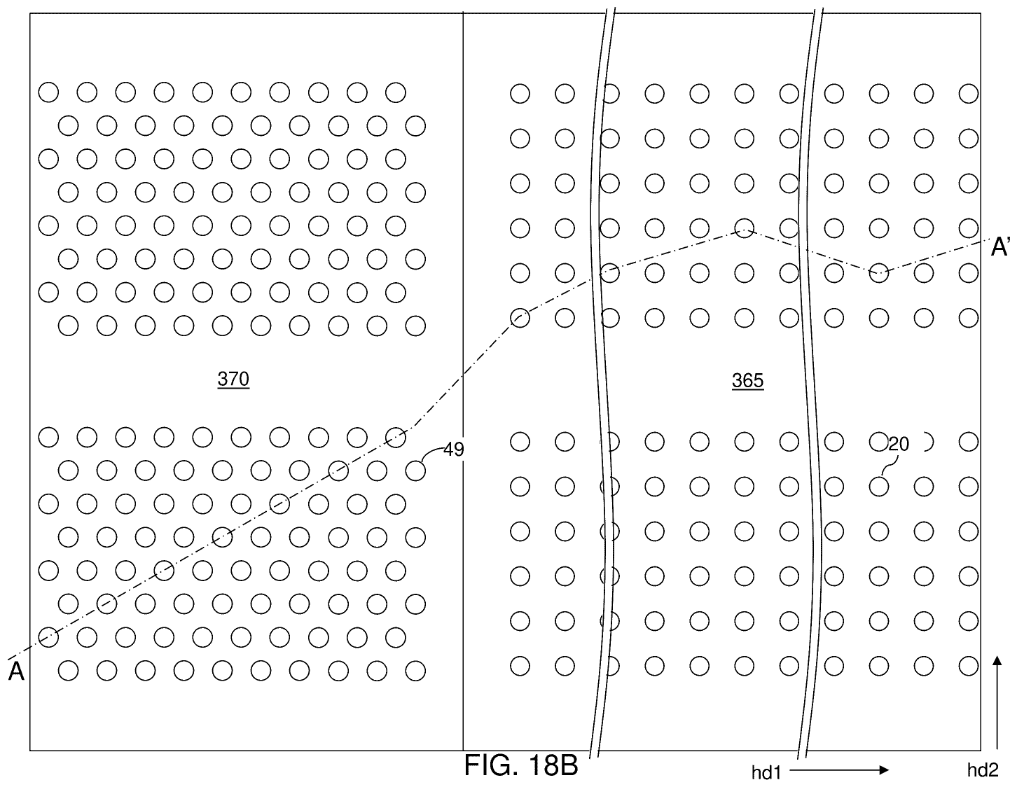

Referring to FIGS. 18A and 18B, the sacrificial multi-tier memory opening fill structures 47 in the memory array region 100 can be removed selective to the materials of the alternating stacks {(132, 142), (232, 242), (332, 342)}, the insulating cap layers (170, 270, 370), the transition-metal oxide etch stop layers (160, 260), and the stepped dielectric material portions (165, 265, 365). For example, a selective etch process or an ashing process may be employed to remove the sacrificial multi-tier memory opening fill structures 47 in the memory array region 100. Cavities are formed in the volumes of the multi-tier memory openings 49.

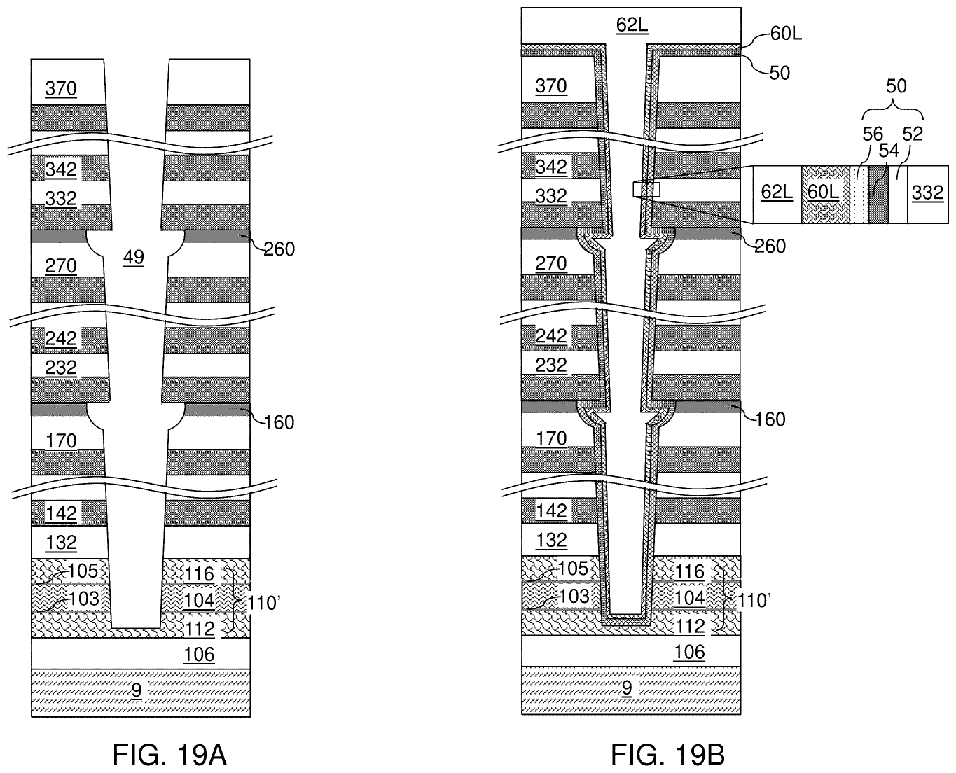

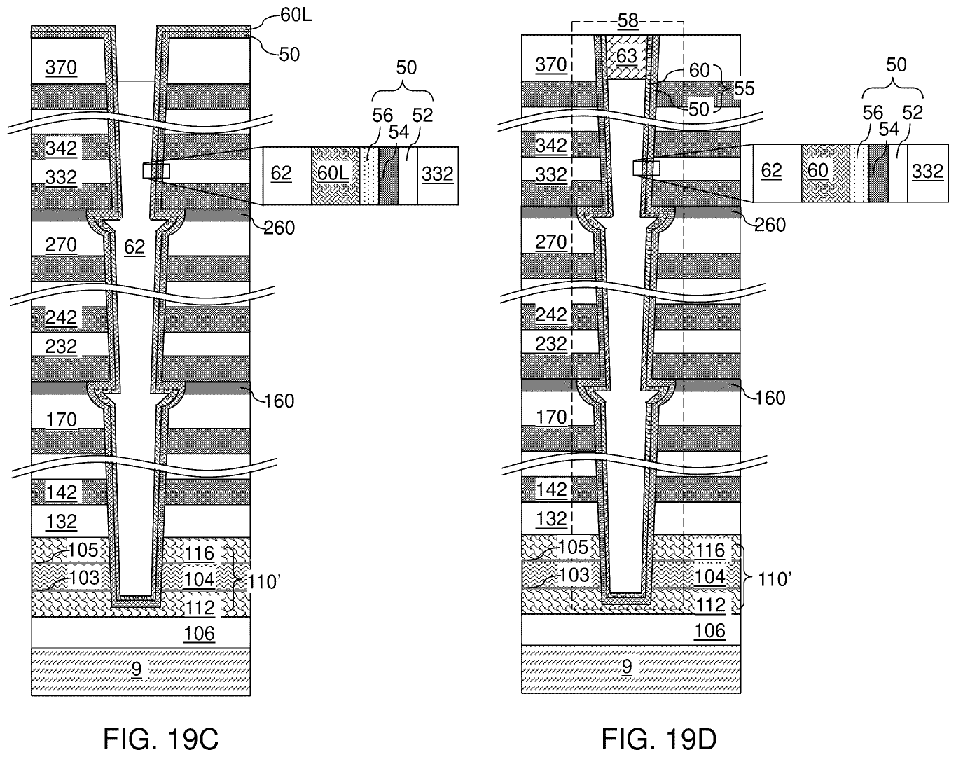

FIGS. 19A-19D are sequential vertical cross-sectional views of a multi-tier memory opening 49 (i.e., a memory opening 49) during formation of a memory opening fill structure 58 according to an embodiments of the present disclosure.

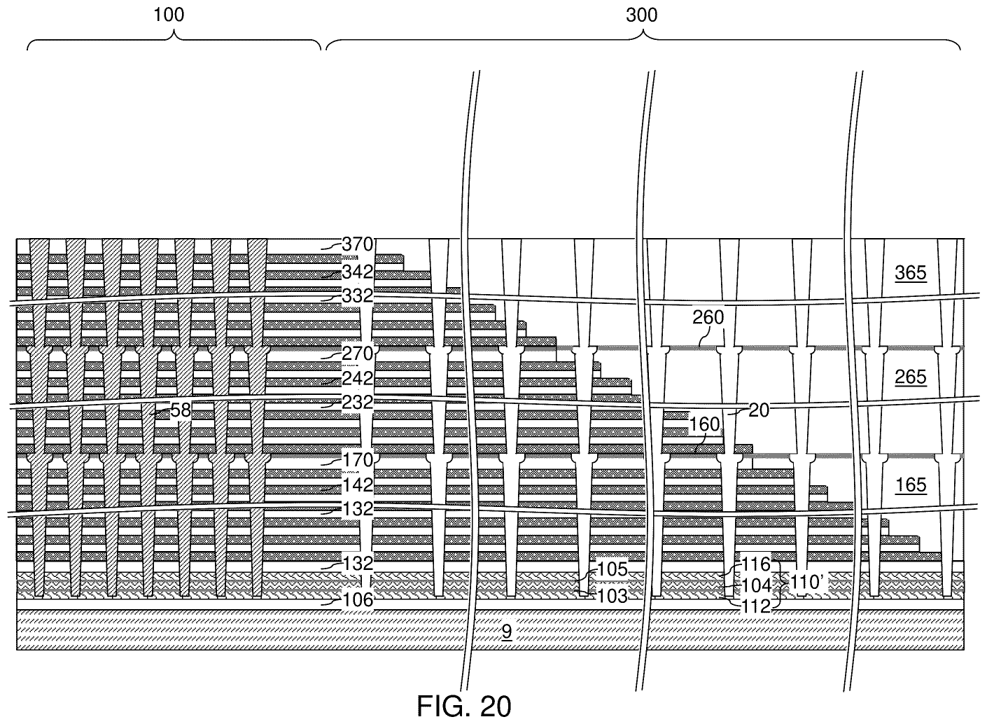

Referring to FIG. 19A, a memory opening 49 is illustrated after the processing steps of FIGS. 20A and 20B.

Referring to FIG. 19B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material (e.g., silicon oxide) can be deposited in remaining volumes of the memory openings 49 and over the alternating stack (32, 42).

Referring to FIG. 19C, the dielectric core layer 62L can be vertically recessed such that each remaining portion of the dielectric core layer 62L has a top surface at, or about, the horizontal plane including the bottom surface of the insulating cap layer 370. Each remaining portion of the dielectric core layer 62L constitutes a dielectric core 62.

Referring to FIGS. 19D and 20, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the insulating cap layer 370, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

In an alternative embodiment in which the memory opening fill structures 58 and the support pillar structures 20 comprise a same set of materials, the processing steps shown in FIGS. 16-18B may be omitted. In this alternative embodiment, the support pillar structures 20 are formed in the support openings 19 at the same time as the memory opening fill structures 58 are formed in the memory opening 49.

While an embodiment is described in which three alternating stacks and two transition-metal oxide etch stop layers (160, 260) are formed, other embodiments may include two alternating stacks and a single transition-metal oxide etch stop layer 160, or N alternating stacks with (N-1) transition-metal oxide etch stop layers (160, 260) in which N is an integer greater than 3.

In summary, each memory opening 49 vertically extends at least through the second alternating stack (232, 242), the first transition-metal oxide etch stop layer 160, the first insulating cap layer 170, and the first alternating stack (132, 146). A memory opening fill structure 58 comprising a memory film 50 and a vertical semiconductor channel 60 can be formed in each memory opening 49. In one embodiment in which the memory opening 49 widening steps shown in FIGS. 5 and 11 are included, the memory opening fill structure 58 has an annular horizontal surface within a horizontal plane including a top surface of the first transition-metal oxide etch stop layer 160, as shown in FIG. 19D. The annular horizontal surface is in contact with an annular segment of a bottom surface of a bottommost layer within the second alternating stack (232, 242). In an alternative embodiment in which the memory opening 49 widening steps shown in FIGS. 5 and 11 are not included, the memory opening fill structure 58 does not have an annular horizontal surface within a horizontal plane including a top surface of the first transition-metal oxide etch stop layer 160. In one embodiment, the memory film 50 is in contact with a sidewall of an opening through the first transition-metal oxide etch stop layer 160.

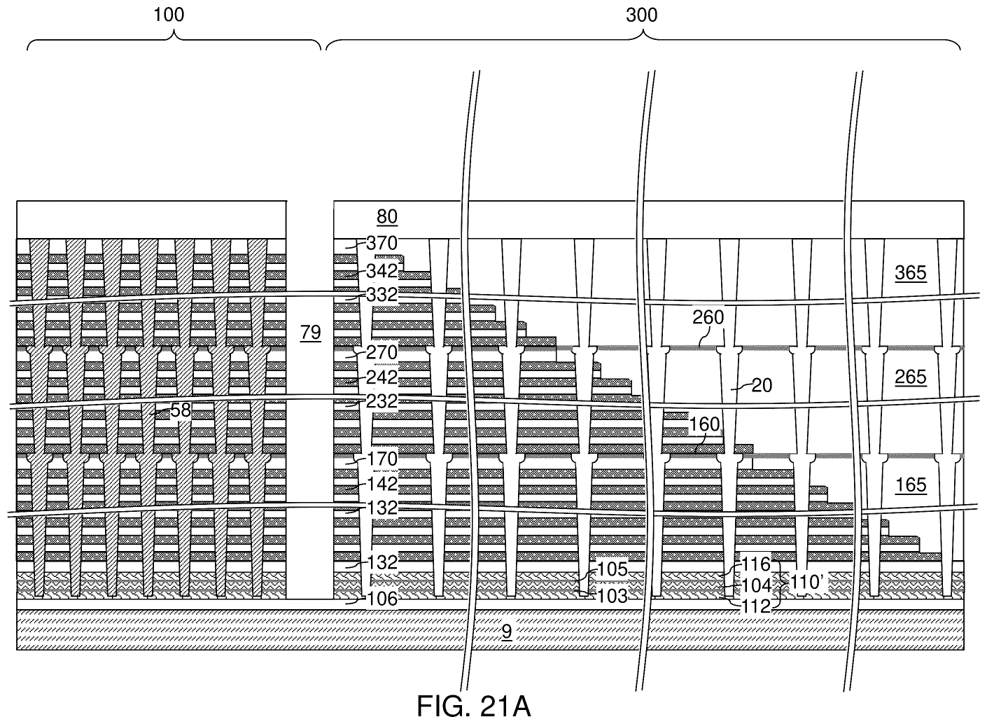

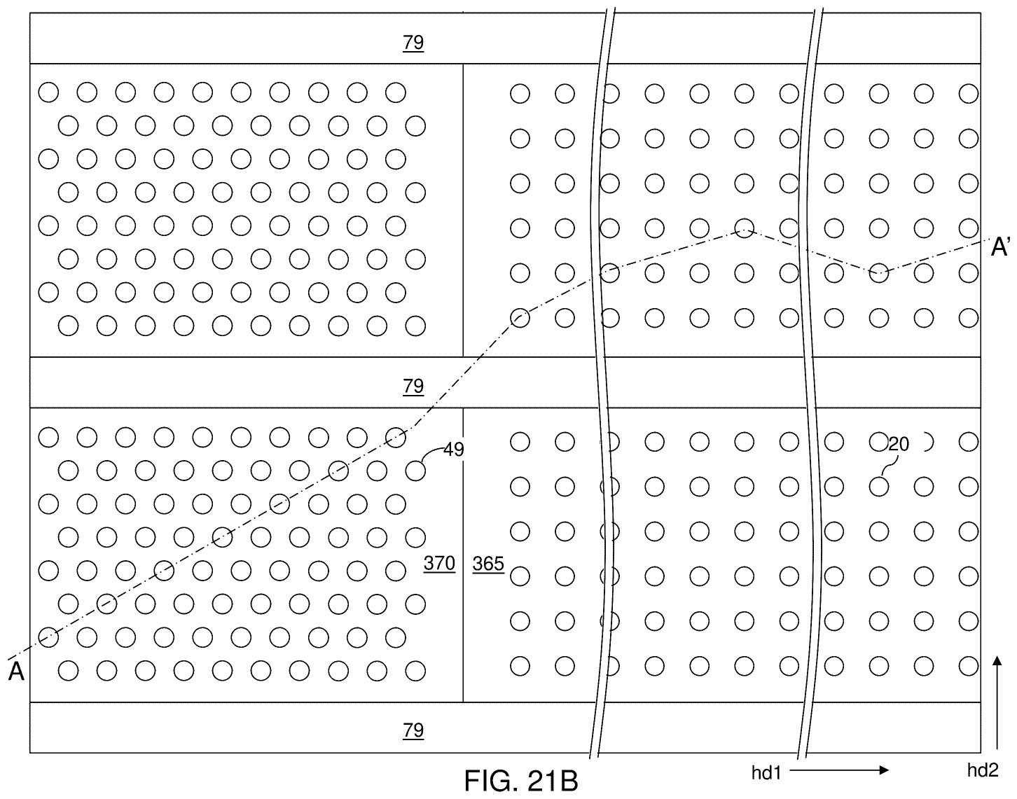

Referring to FIGS. 21A and 21B, a dielectric material, such as undoped silicate glass or a doped silicate glass, can be deposited over the alternating stacks {(132, 142), (232, 242), (332, 342)} to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the insulating cap layers (170, 270, 370), the transition-metal oxide etch stop layers (160, 260), the alternating stacks {(132, 142), (232, 242), (332, 342)}, the stepped dielectric material portions (165, 265, 365), and the in-process source-level material layers 110′. Lateral isolation trenches 79 laterally extending along the first horizontal direction (i.e., word line direction) hd1 can be formed through the alternating stacks {(132, 142), (232, 242), (332, 342)}, the stepped dielectric material portions (165, 265, 365), the contact-level dielectric layer 80, and the in-process source-level material layers 110′. Each of the lateral isolation trenches 79 may comprise a respective pair of lengthwise sidewalls that are parallel to the first horizontal direction hd1 and vertically extend from the stopper insulating layer 106 to the top surface of the contact-level dielectric layer 80. A top surface of the stopper insulating layer 106 can be physically exposed underneath each lateral isolation trench 79. The photoresist layer can be subsequently removed, for example, by ashing.

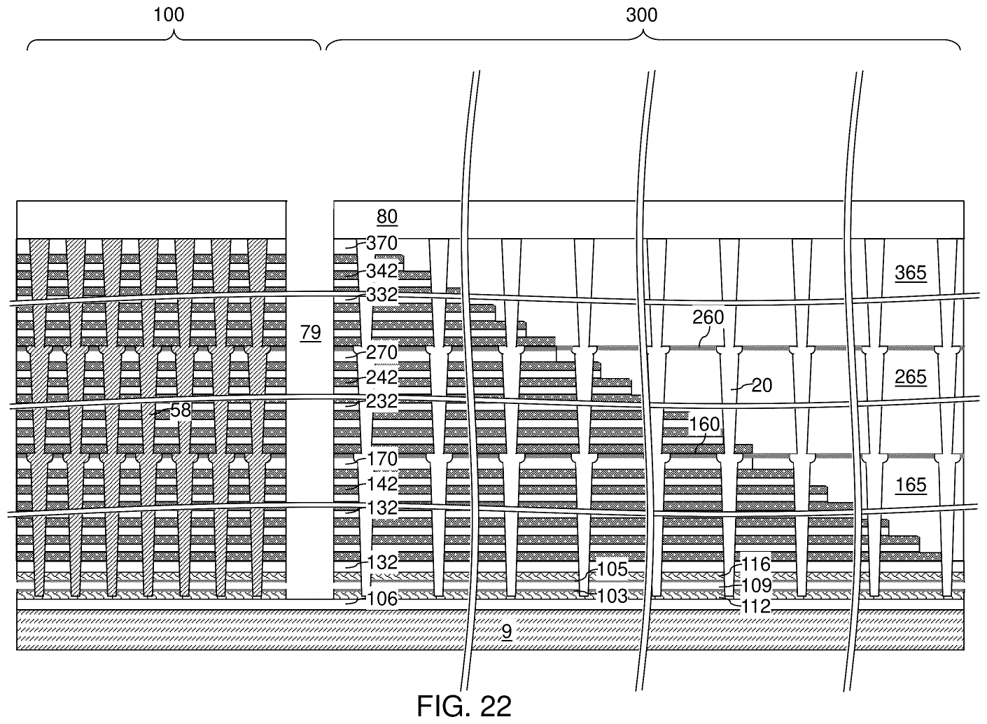

Referring to FIG. 22, an etchant that etches the material of the source-level sacrificial layer 104 selective to the materials of the alternating stacks {(132, 142), (232, 242), (332, 342)}, the contact level dielectric layer 80, the stepped dielectric material portions (165, 265, 365), the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stacks {(132, 142), (232, 242), (332, 342)}, the contact level dielectric layer 80, the stepped dielectric material portion 65, the lower source-level semiconductor layer 112, and the upper source-level semiconductor layer 116. A source cavity 109 is formed in the volume from which the source-level sacrificial layer 104 is removed. Each of the memory opening fill structures 58 is physically exposed to the source cavity 109. Specifically, each of the memory opening fill structures 58 includes a sidewall that is physically exposed to the source cavity 109.

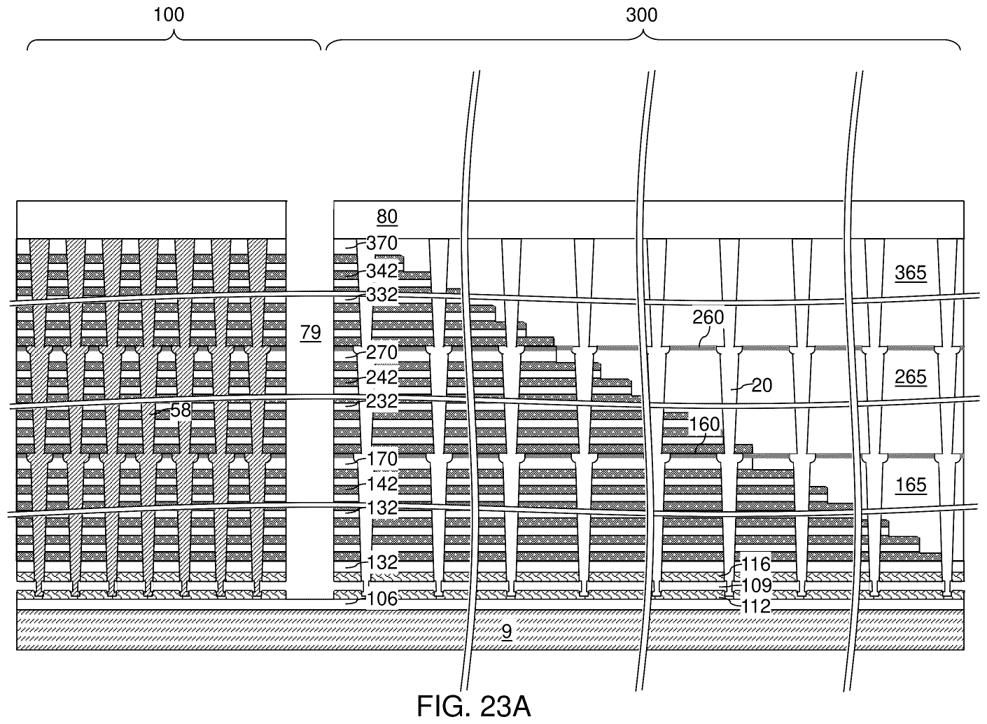

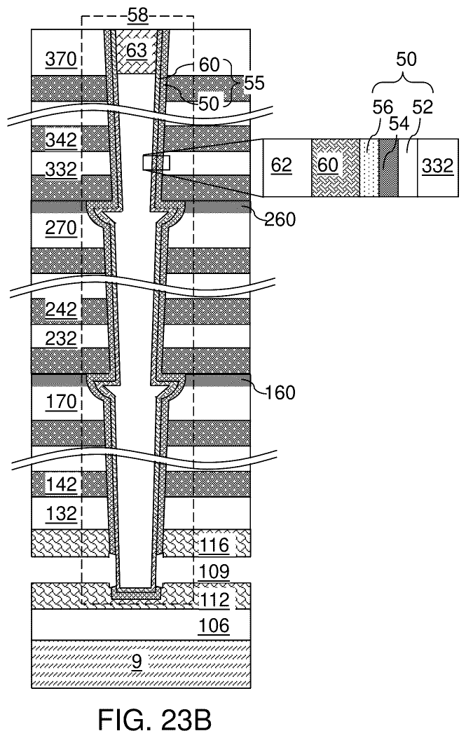

Referring to FIGS. 23A and 23B, a sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

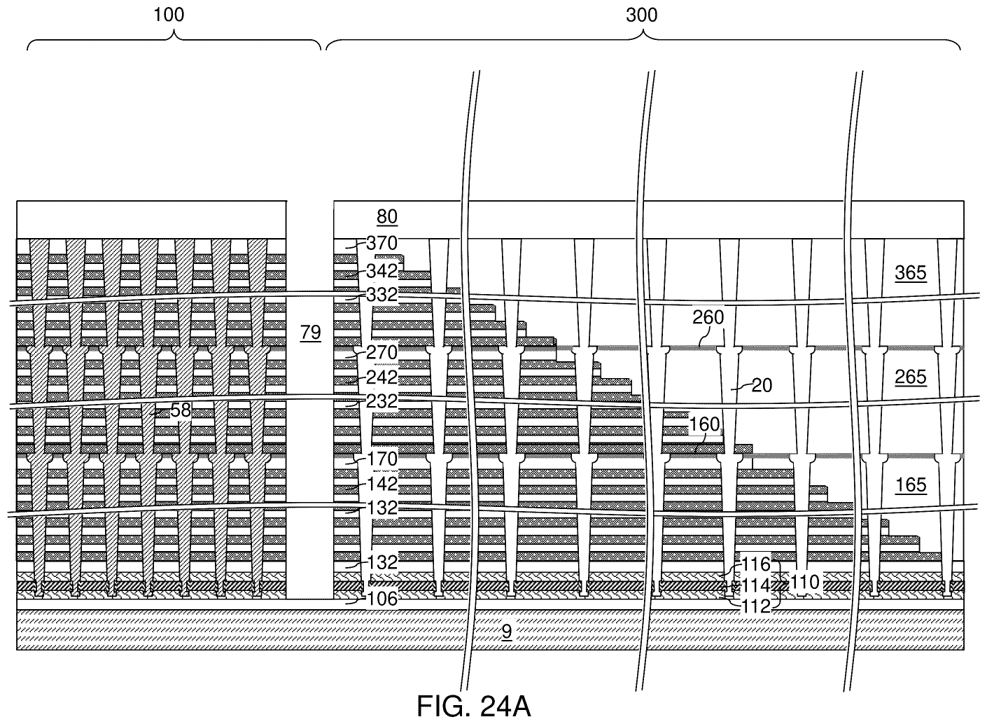

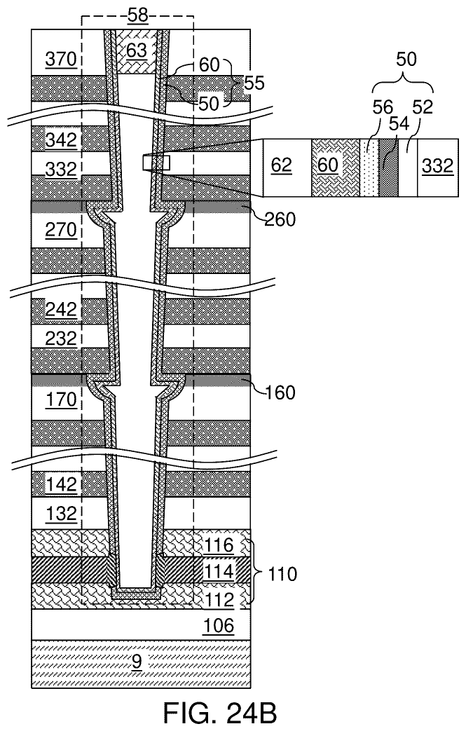

Referring to FIGS. 24A and 24B, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10¹⁹/cm³ to 2.0×10²¹/cm³, such as from 1.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The layer stack including the lower source-level semiconductor layer 112, the source contact layer 114, and the upper source-level semiconductor layer 116 constitutes a source layer 110, which replaces the in-process source-level material layers 110′. The source layer 110 contacts an end portion of each of the vertical semiconductor channels 60.

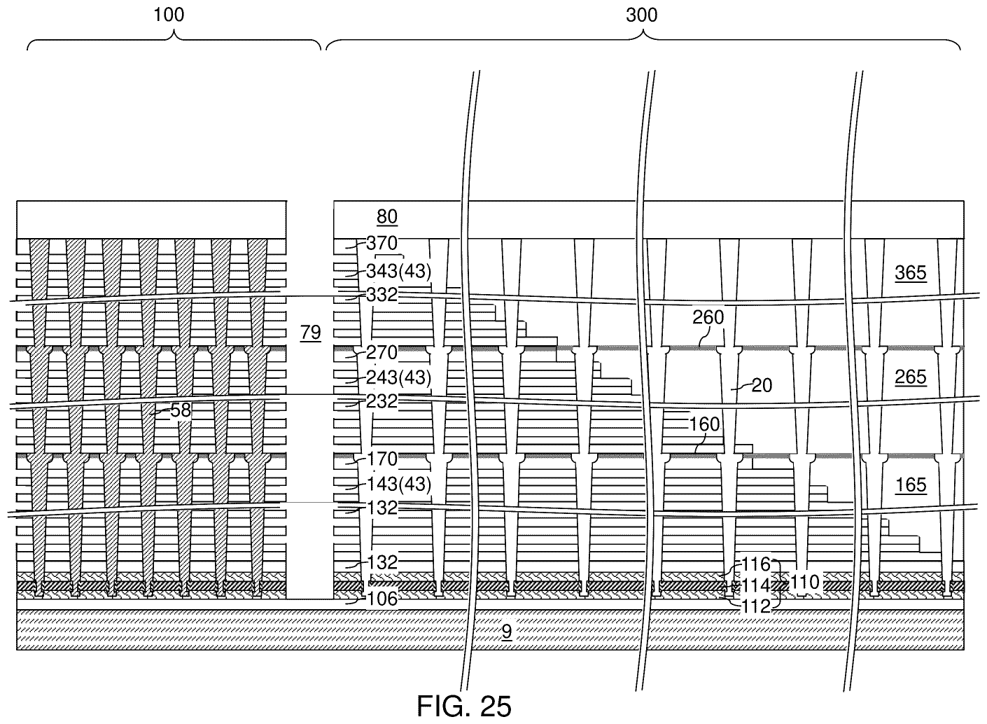

Referring to FIG. 25, an isotropic etch process can be performed to remove the sacrificial material layers (142, 242, 342) selective to the insulating layers (132, 232, 332), the stopper insulating layer 106, the memory opening fill structures 58, and the source layer 110. In an illustrative example, the insulating layers (132, 232, 332) may comprise silicon oxide, the sacrificial material layers (142, 242, 342) may comprise silicon nitride, and the transition-metal oxide etch stop layers (160, 260) may comprise a dielectric oxide of a Group IVB element such as Ti, Zr, or Hf. In this case, the isotropic etch process that removes the sacrificial material layers (142, 242, 342) may comprise a wet etch process employing hot phosphoric acid. Laterally-extending cavities 43 can be formed in volumes from which the sacrificial material layers (142, 242, 342) are removed. Sidewall surface segments of the memory opening fill structures 58 can be physically exposed to the laterally-extending cavities 43.

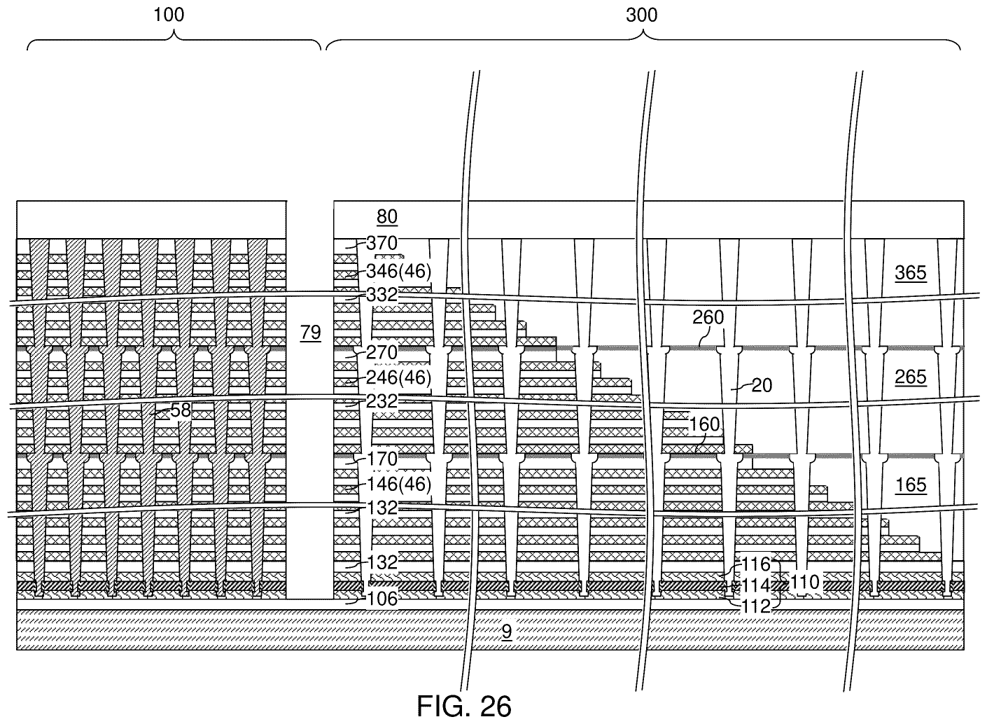

Referring to FIG. 26, an outer blocking dielectric layer (not shown), such as an aluminum oxide layer, can be optionally formed in the laterally-extending cavities 43 by a conformal deposition process. At least one conductive material, such as at least one metallic material, can be conformally deposited in the laterally-extending cavities 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46 (e.g., 146, 246, 346). An alternating stack of insulating layers (132, 232, 332) and electrically conductive layers 46 can be formed between each neighboring pair of lateral isolation trenches 79 over the carrier substate 9. A plurality of alternating stacks of insulating layers (132, 232, 332) and electrically conductive layers 46 can be laterally spaced apart among one another by the lateral isolation trenches 79.

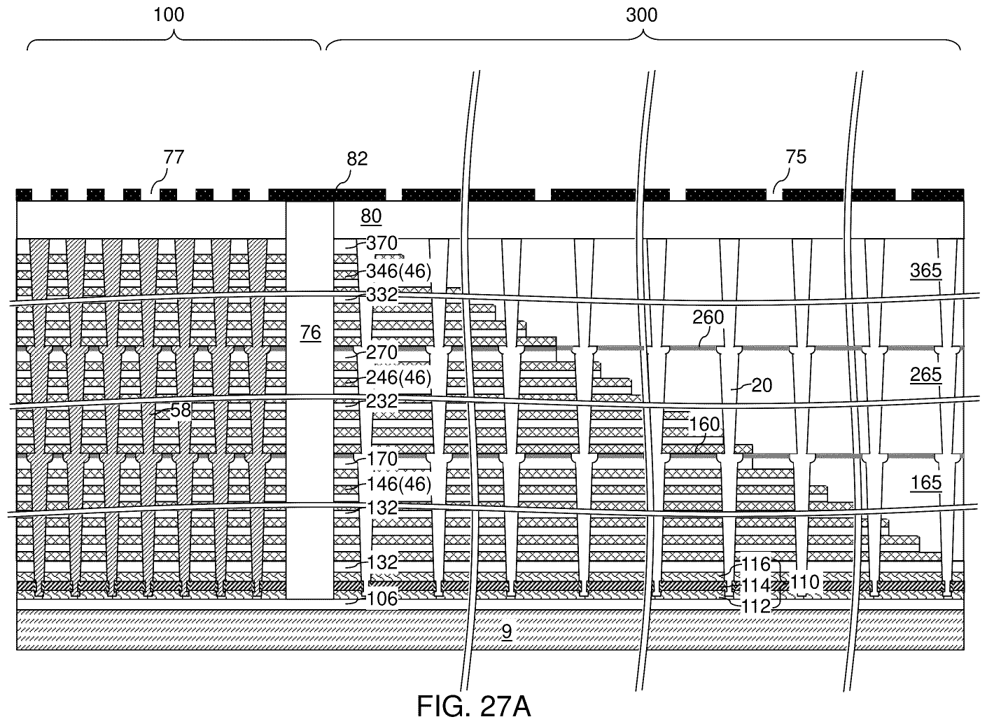

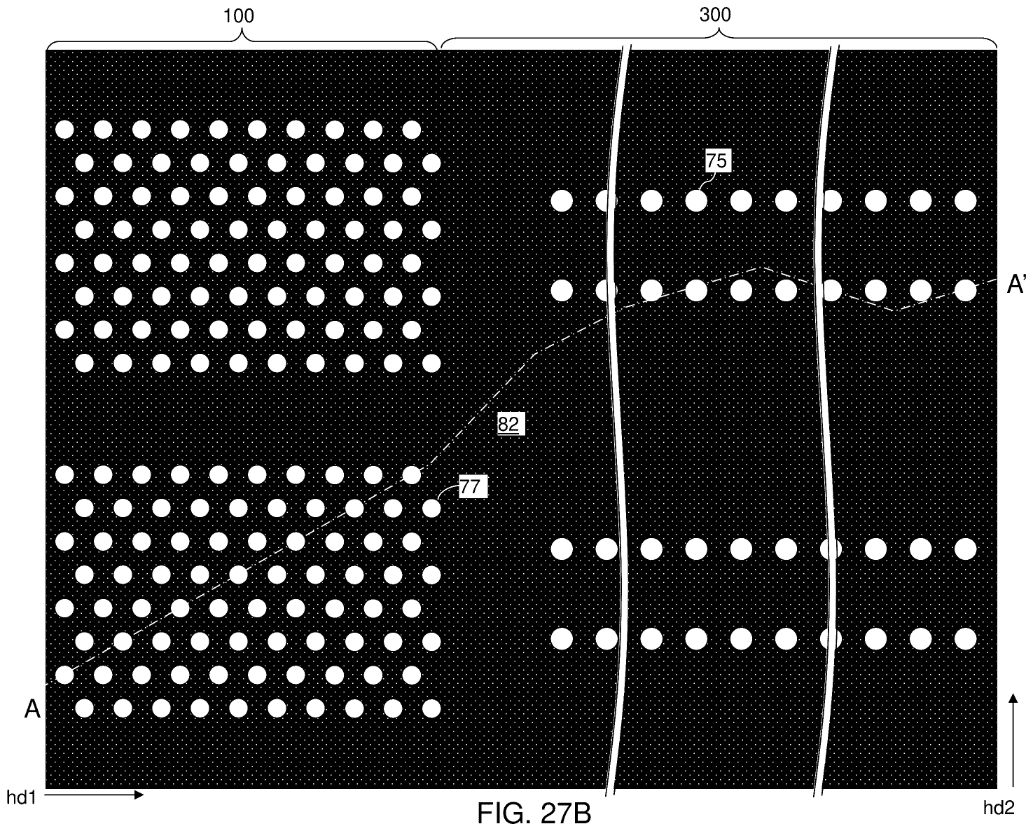

Referring to FIGS. 27A and 27B, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes an isolation trench fill structure 76. Alternatively, each isolation trench fill structure 76 may comprise a combination of a tubular insulating spacer (not expressly shown) and a conductive connection via structure (not expressly shown) that is laterally surrounded by the tubular insulating spacer.

A patterned etch mask layer 82 can be formed over each of the alternating stacks (132, 142), (232, 242), (332, 342)}. In the illustrated example, the patterned etch mask layer 82 may be formed on the top surface of the contact-level dielectric layer 80. The patterned etch mask layer 82 may be formed, for example, by depositing a hard mask material such as an insulating, semiconductor or conductive material, by applying a photoresist layer (not shown) and lithographically patterning the photoresist layer, and by transferring the pattern in the photoresist layer into the hard mask material by performing an anisotropic etch process. The pattern in the patterned hard mask layer 82 may comprise a pattern of openings 75 in the memory array region having an areal overlap with the memory opening fill structures 58, and a pattern of openings 77 in the contact region 300 having an areal overlap with a respective horizontally-extending surface segment of the stepped surfaces of the electrically conductive layers (146, 246, 346) that underlie the stepped dielectric material portions (165, 265, 365). In one embodiment, the patterned photoresist layer may be removed by ashing.

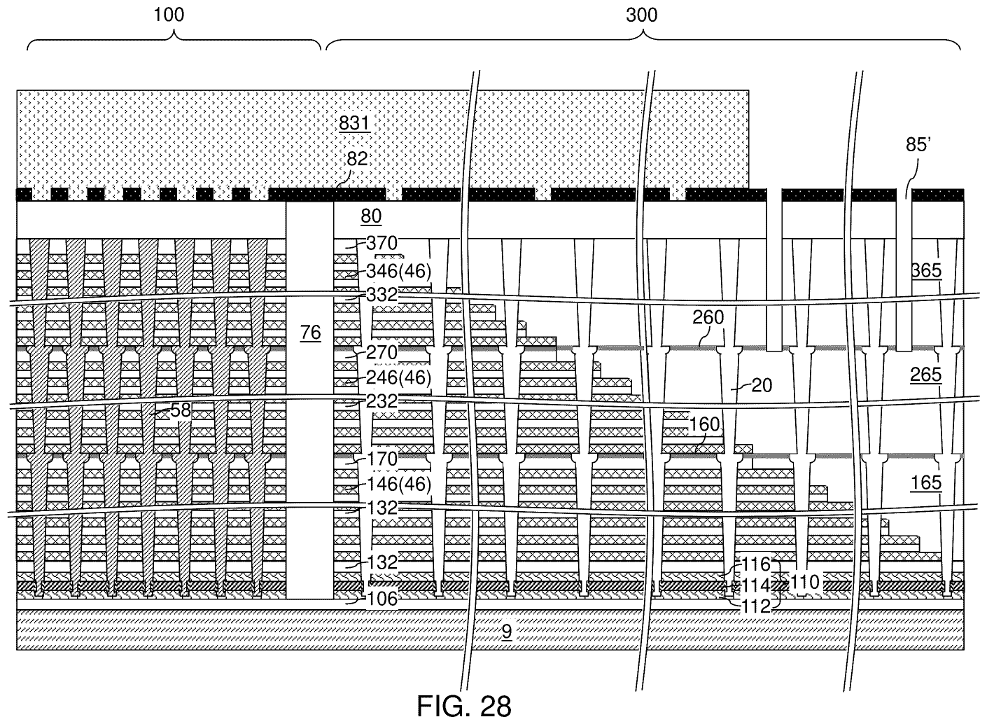

Referring to FIG. 28, a first photoresist layer 831 can be formed over the patterned etch mask layer 82, and can be lithographically patterned to cover the set of all openings 75 in the patterned etch mask layer 82 in the memory array region 100 and the subset of all openings 77 in the patterned etch mask layer 82 that overlie horizontally-extending surface segments of stepped surfaces of the electrically conductive layers (346, 246) that contact the third stepped dielectric material portion 365 or the second stepped dielectric material portion 265. This leaves a remaining subset of all openings 77 in the patterned etch mask layer 82 that overlies horizontally-extending surface segments of stepped surfaces of the first electrically conductive layers 146 and having an areal overlap with the first stepped dielectric material portion 165 in a plan view that are not covered by the first photoresist layer 831. In other words, the subset of openings 77 in the contact region 300 which overlie the first electrically conductive layers 146 are not covered, and the remaining openings (75, 77) are covered.

The subset of the openings 77 in the patterned etch mask layer 82 that are not masked by the first photoresist layer 831 can be transferred through the contact-level dielectric layer 80 and the third stepped dielectric material portion 365 by performing an anisotropic etch process. According to an aspect of the present disclosure, the anisotropic etch process may employ a fluorine-based etch chemistry and may etch the materials of the contact-level dielectric layer 80 and the third stepped dielectric material portion 365 selective to the material of the second transition-metal oxide etch stop layer 260, which acts as an etch stop layer. In-process layer contact via cavities 85′ are formed through the contact-level dielectric layer 80 and the third stepped dielectric material portion 365. A break-through anisotropic etch process employing a chlorine-based etch chemistry may be performed to etch through the physically exposed portions of the second transition-metal oxide etch stop layer 260 in the subset of the openings 77 in the etch mask layer 82. The first photoresist layer 831 may be subsequently removed, for example, by ashing.

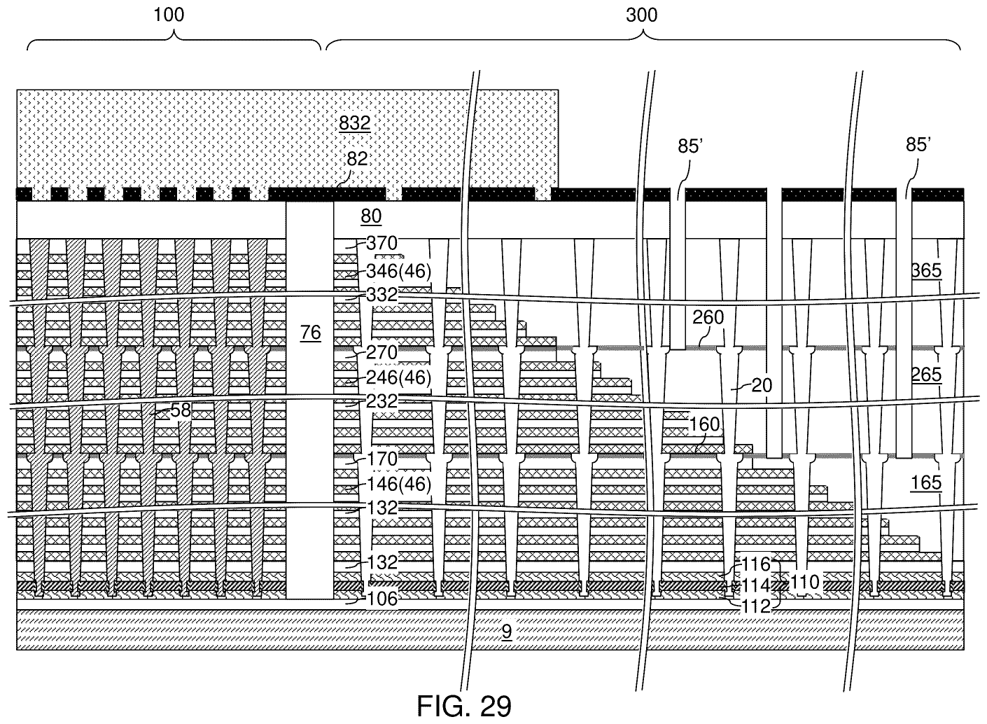

Referring to FIG. 29, a second photoresist layer 832 can be formed over the patterned etch mask layer 82, and can be lithographically patterned to cover the set of all openings in the patterned etch mask layer 82 in the memory array region 100 and the subset of openings 77 in the patterned etch mask layer 82 that overlie horizontally-extending surface segments of stepped surfaces of the third electrically conductive layers 346 that contact the third stepped dielectric material portion 365. The subset of all openings 77 in the patterned etch mask layer 82 having an areal overlap with the horizontally-extending surface segments of stepped surfaces of the first and second electrically conductive layers (146, 246) which contact the first stepped dielectric material portion 165 or with the second stepped dielectric material portion 265 in a plan view are not covered by the first photoresist layer 832.

An anisotropic etch process can be performed to remove portions of the contact-level dielectric layer 80, the third stepped dielectric material portion 365, and the second stepped dielectric material portion 265 that are not covered by the patterned etch mask layer 82 or by the second photoresist layer 832. Portions of the second stepped dielectric material portion 265 that underlie pre-existing in-process layer contact via cavities 85′ are etched, and the pre-existing in-process layer contact via cavities 85′ are vertically extended through the second stepped dielectric material portion 265. Portions of the contact-level dielectric layer 80 and the third stepped dielectric material portion 365 that underlie openings in the patterned etch mask layer 82 having an areal overlap with the stepped surfaces of the second alternating stack (232, 242) in a plan view are etched by the anisotropic etch process to form new in-process layer contact via cavities 85′.

According to an aspect of the present disclosure, the anisotropic etch process may employ a fluorine-based etch chemistry and may etch the materials of the contact-level dielectric layer 80, the third stepped dielectric material portion 365, and the second stepped dielectric material portion 265 selective to the material of the second transition-metal oxide etch stop layer 260 and the first transition-metal oxide etch stop layer 160, which function as etch stop layers. The pre-existing in-process layer contact via cavities 85′ are vertically extended through the second stepped dielectric material portion 265, and new in-process layer contact via cavities 85′ are formed through the contact-level dielectric layer 80 and the third stepped dielectric material portion 365. A break-through anisotropic etch process employing a chlorine-based etch chemistry may be performed to etch through the physically exposed portions of the second transition-metal oxide etch stop layer 260 and to etch through the physically exposed portions of the first transition-metal oxide etch stop layer 160 in the subset of openings 77 in the etch mask layer 82. The second photoresist layer 832 may be subsequently removed, for example, by ashing.

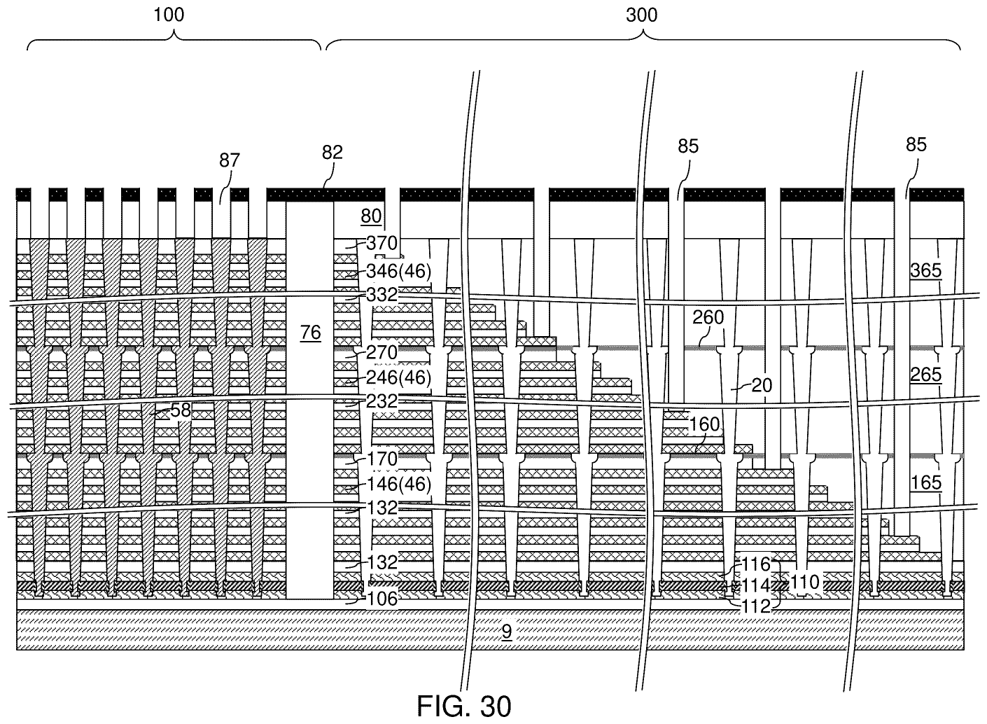

Referring to FIG. 30, an additional anisotropic etch process can be performed to etch through unmasked portions of the contact-level dielectric layer 80 and the stepped dielectric material portions (165, 265, 365). The additional anisotropic etch process may employ an etch chemistry that etches silicon oxide selective to the material(s) of the electrically conductive layers (146, 246, 346) and selective to the semiconductor material (e.g., silicon) of the drain regions 63. For example, the additional anisotropic etch process may employ a fluorine-based etch chemistry. Top surfaces of the electrically conductive layers (146, 246, 346) and top surfaces of the drain regions 63 of the memory opening fill structures 58 can be employed as etch stop surfaces for the anisotropic etch process. The in-process layer contact via cavities 85′ are extended downward to a top surface of a respective electrically conductive layer (146, 246) to reach the full depths for subsequently forming contact via structures therein, and become a first subset of layer contact via structures 85. A second subset of layer contact via structures 85 can be formed through the third stepped dielectric material portion 365 directly on a top surface of a respective one of the third electrically conductive layers 346. Drain contact via cavities 87 are formed through the contact-level dielectric layer 80 on a top surface of a respective one of the drain regions 63.

Generally, the pattern of openings in the etch mask layer 82 can be transferred through the stepped dielectric material portions (365, 265, 165) to form layer contact via cavities 85. At least one anisotropic etch process employed to form the layer contact via cavities 85 has an etch chemistry (e.g., fluorine based chemistry) that etches the materials of the stepped dielectric material portions (365, 265, 165) selective to the materials of the transition-metal oxide etch stop layers (160, 260). A subset of the layer contact via cavities 85 can be vertically extended through at least one transition-metal oxide etch stop layer (160, 260) by performing a respective break-through anisotropic etch process using a chlorine based chemistry. The etch mask layer 82 may then be removed by selective etching or retained in the final device.

In an alternative embodiment, the order of process steps may be changed. For example, the openings 85 in the etch mask layer 82 in the memory array region 100 may be omitted. In this alternative embodiment, the etch mask layer 82 is removed after forming the layer contact via cavities 85. The drain contact via cavities 87 are then formed through the contact-level dielectric layer 80 on a top surface of a respective one of the drain regions 63 using a separate photoresist layer.

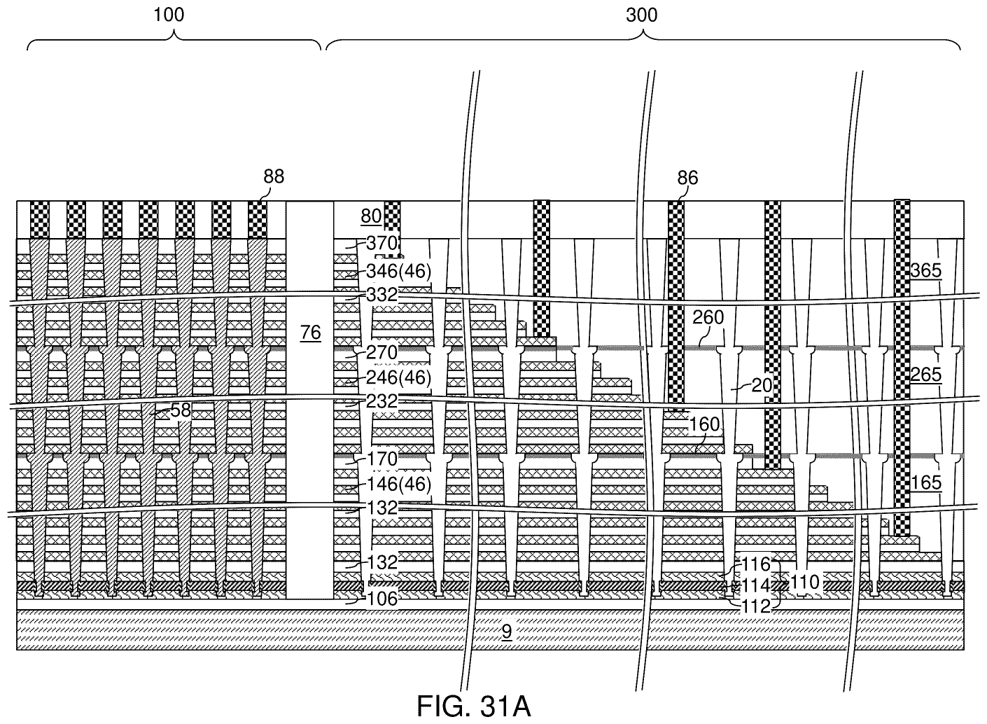

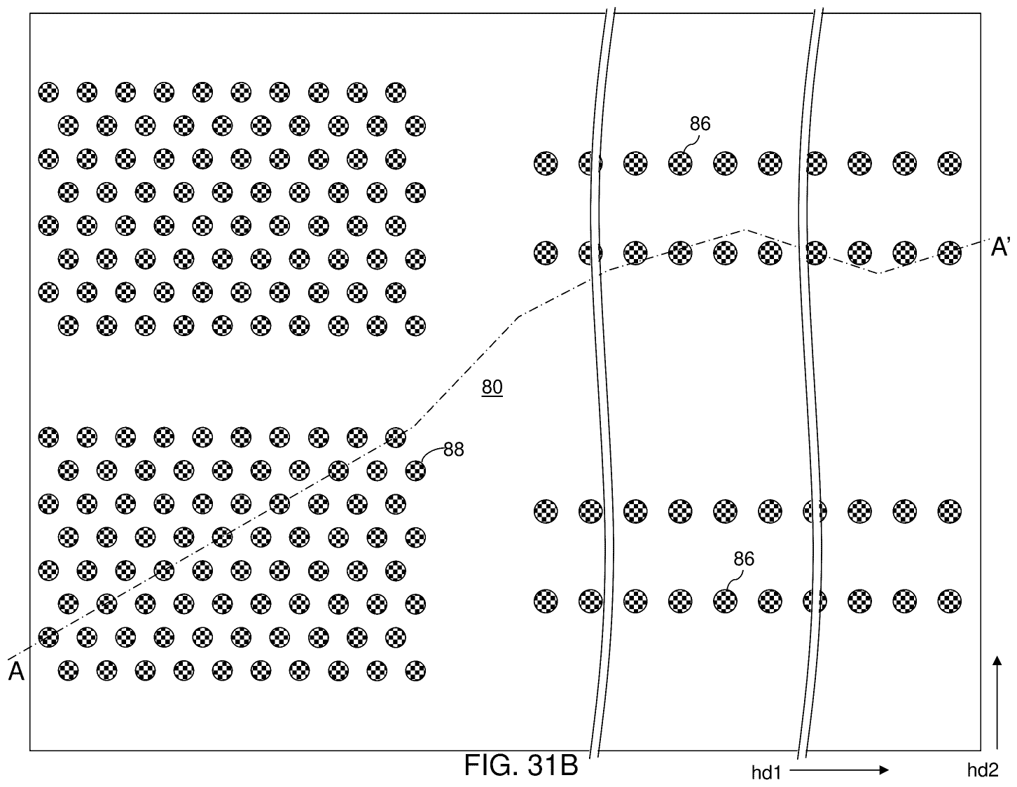

Referring to FIGS. 31A and 31B, at least one conductive material, such as a combination of an electrically conductive barrier material and an electrically conductive fill material, can be deposited in the drain contact via cavities 87 and the layer contact via cavities 85. Excess portions of the at least one conductive material and optionally the etch mask layer 82 (if present at this step) can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities 87 constitute drain contact via structures 88 contacting a top surface of a respective one of the drain regions 63. Remaining portions of the at least one conductive material that fill the layer contact via cavities 85 constitute layer contact via structures 86 contacting a top surface of a respective one of the electrically conductive layers 46. The electrically conductive layers 46 comprise first electrically conductive layers 146 that replace the first sacrificial material layers 142, second electrically conductive layers 246 that replace the second sacrificial material layers 242, and third electrically conductive layers 346 that replace the third sacrificial material layers 342.

In one embodiment, the layer contact via structures 86 vertically extend through the contact-level dielectric layer 80, through the third stepped dielectric material portion 365, optionally through the second transition-metal oxide etch stop layer 260, optionally through the second stepped dielectric material portion 265, optionally through the first transition-metal oxide etch stop layer 160, and optionally through the first stepped dielectric material portion 165, and are formed on a top surface of a respective one of the electrically conductive layers 46. A first subset of the layer contact via structures 86 vertically extends through the second stepped dielectric material portion 265, the first transition-metal oxide etch stop layer 160, and the first stepped dielectric material portion 165, and contacts a top surface of a respective one of the first electrically conductive layers 146. The first subset of the layer contact via structures 86 is in contact with the second stepped dielectric material portion 265, the first transition-metal oxide etch stop layer 160, and the first stepped dielectric material portion 165.

In one embodiment, the second insulating cap layer 270 may overlie the second alternating stack (232, 246), the second transition-metal oxide etch stop layer 260 may overlie the second insulating cap layer 270, the third alternating stack of third insulating layers 332 and third electrically conductive layers 346 may have third stepped surfaces and overlie the second transition-metal oxide etch stop layer 260, and the third stepped dielectric material portion 365 may overlie the second stepped surfaces. In one embodiment, a memory opening 49 vertically extends through the third alternating stack (332, 346) and the second transition-metal oxide etch stop layer 260, and a layer contact via structure 86 vertically extends through the third stepped dielectric material portion 365 and the second transition-metal oxide etch stop layer 260.

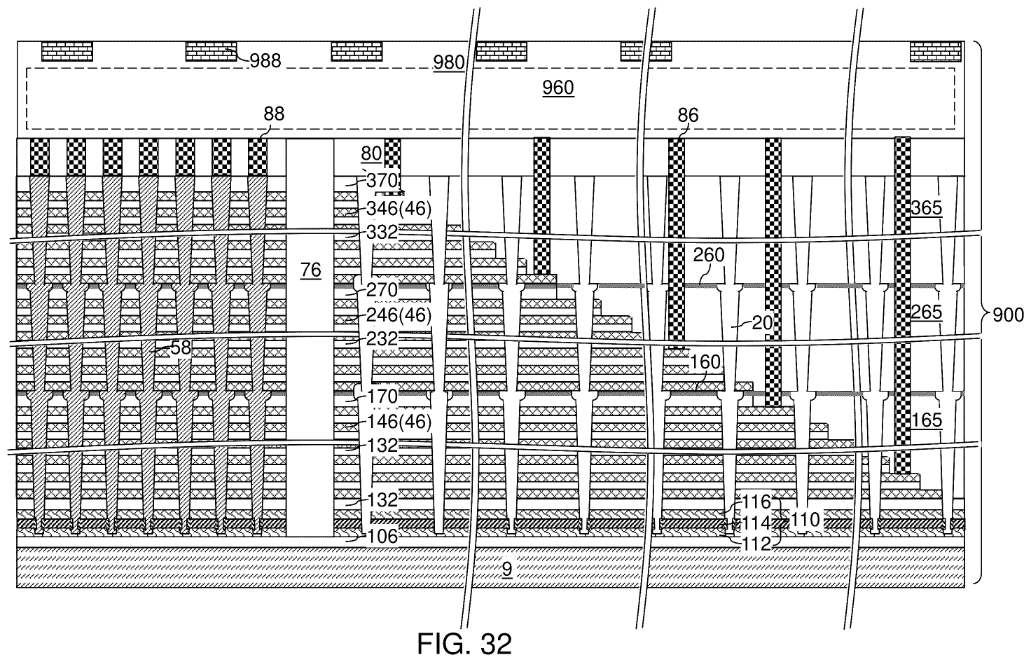

Referring to FIG. 32, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

In one embodiment, a peripheral (i.e., driver) circuit is formed on the substrate 9 below the stopper insulating layer 106. In this embodiment, the peripheral circuit is electrically connected to the various nodes of the memory device.

In another embodiment, described below, the peripheral circuit is formed on a separate substrate and is then bonded to the memory device. Metal bonding pads, which are herein referred to as upper bonding pads 988, may be formed at the topmost level of the memory-side dielectric material layers 960. The upper bonding pads 988 may be electrically connected to the memory-side metal interconnect structures 980 and various nodes of the three-dimensional memory array including the alternating stacks of insulating layers (132, 232, 332) and electrically conductive layers 46 and the memory opening fill structures 58. A memory die 900 is formed by the above steps.

In one embodiment, the memory die 900 may comprise: a three-dimensional memory array underlying the first dielectric material layer 110 and comprising an alternating stack of insulating layers (132, 232, 332) and electrically conductive layers 46, a two-dimensional array of memory openings 49 vertically extending through the alternating stack, and a two-dimensional array of memory opening fill structures 58 located in the two-dimensional array of memory openings 49 and comprising a respective vertical stack of memory elements and a respective vertical semiconductor channel 60, a two-dimensional array of drain contact via structures 88 electrically connected to a respective one of the vertical semiconductor channels 60 via respective drain regions 63; and a two-dimensional array of layer contact via structures 86 electrically connected to a respective one of the electrically conductive layers 46, a subset of which functions as word lines for the three-dimensional memory array.

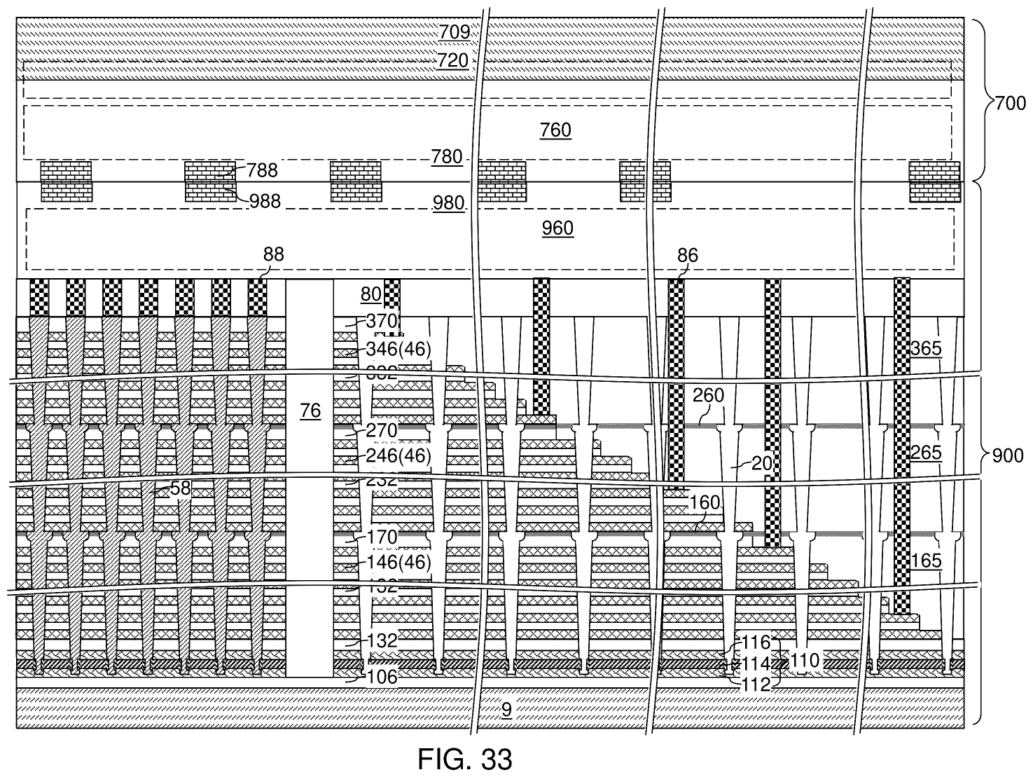

Referring to FIG. 33, a peripheral circuit 720 can be formed on a logic-side substrate 709, which can be a semiconductor substrate. The peripheral circuit 720 can be configured to control operation of the memory array within the memory die 900. Logic-side metal interconnect structures 780 embedded within logic-side dielectric material layers 760 can be formed over the logic-side substrate 709 (which may comprise a semiconductor substrate) to form a logic die 700. The logic die 700 also comprises logic-side bonding pads 788 embedded within logic-side dielectric material layers 760.

A bonded assembly can be formed by bonding the logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

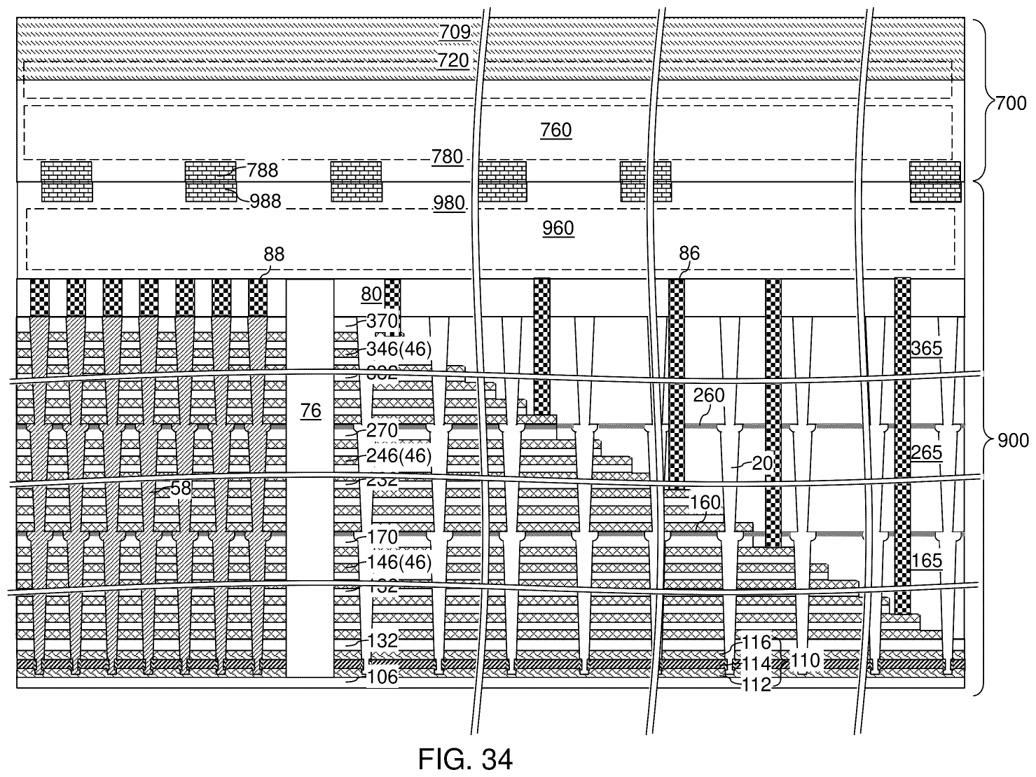

Referring to FIG. 34, the carrier substrate 9 can optionally be removed, for example, by grinding, polishing, cleaving, an isotropic etch process, and/or an anisotropic etch process. If a polishing process such as a chemical mechanical polishing process is employed to remove the carrier substrate 9, the stopper insulating layer 106 may be subsequently employed as a polishing stopper material layer. If an etch process, such as a wet etch process, is employed to remove the carrier substrate 9, the stopper insulating layer 106 may be subsequently employed as an etch stop material layer.

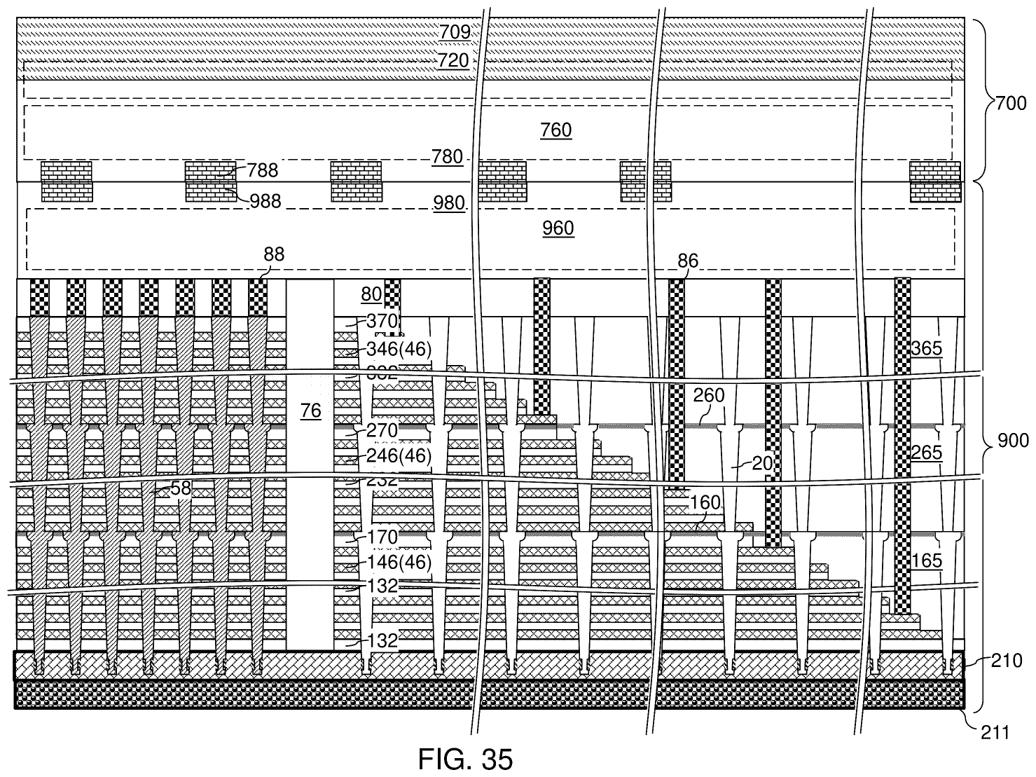

Referring to FIG. 35, in an alternative embodiment, the source layer 110 formation is omitted at the step shown in FIG. 1. The stopper insulating layer 106 may be removed after removing the carrier substrate 9 or its formation may also be omitted at the step shown in FIG. 1. After the removal of the carrier substrate 9, the bottom portions of the memory film 50 may be removed to expose the bottom tips of the vertical semiconductor channel 60. A heavily doped semiconductor source layer 210 is deposited on the exposed bottom tips of the vertical semiconductor channel 60. A source electrode 211 may be formed on the semiconductor source layer 210.

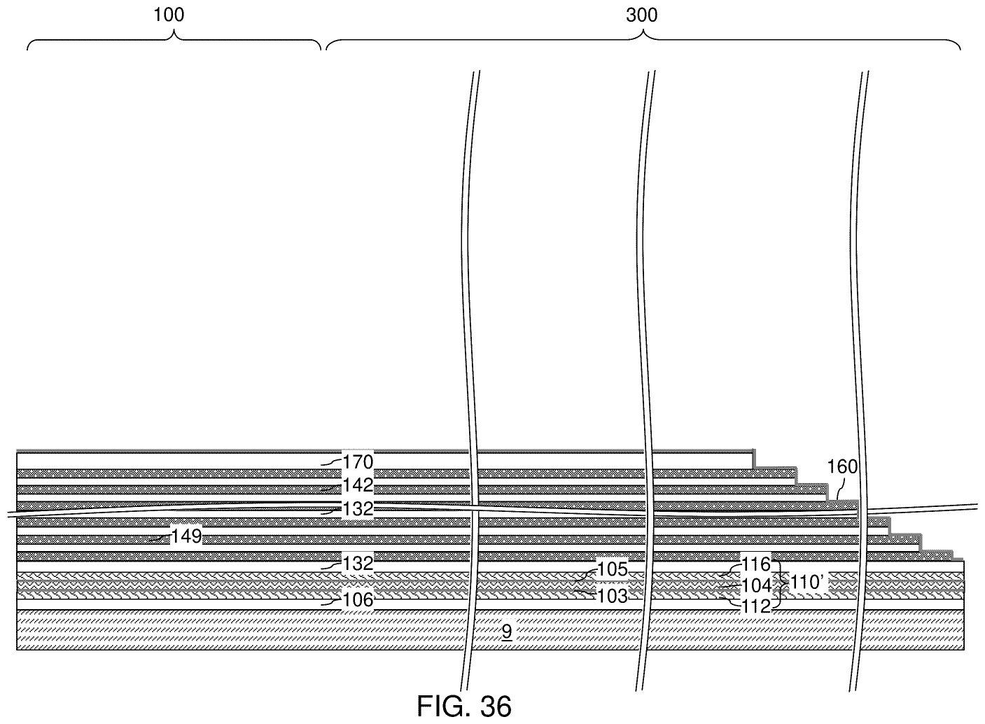

Referring to FIG. 36, a second exemplary structure according to a second embodiment of the present disclosure is illustrated, which can be derived from the first exemplary structure illustrated with reference to FIG. 1 by forming patterning the first alternating stack (132, 142) to form first stepped surfaces in the contact region 300, and by depositing a first transition-metal oxide etch stop layer 160 over the first insulating cap layer 170 and over the first stepped surfaces of the first alternating stack (132, 142). The first transition-metal oxide etch stop layer 160 may be the same in composition and in the thickness range as the first transition metal-oxide etch stop layer 160 described with reference to FIG. 2. The first transition-metal oxide etch stop layer 160 in the second exemplary structure may be formed by the same method as the first transition-metal oxide etch stop layer 160 described with reference to FIG. 2.

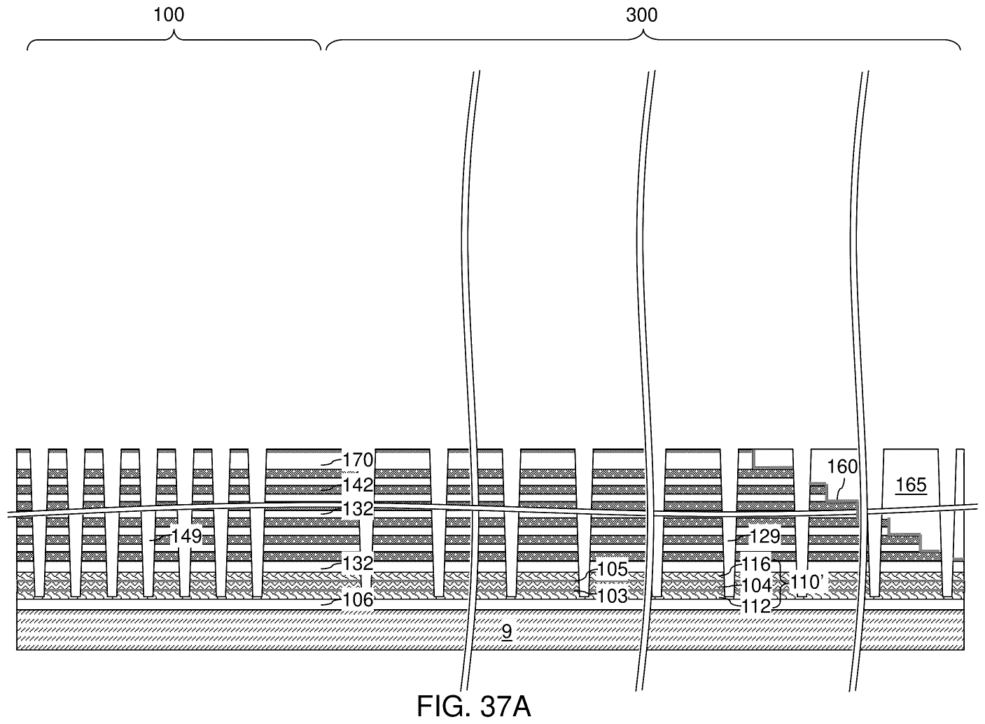

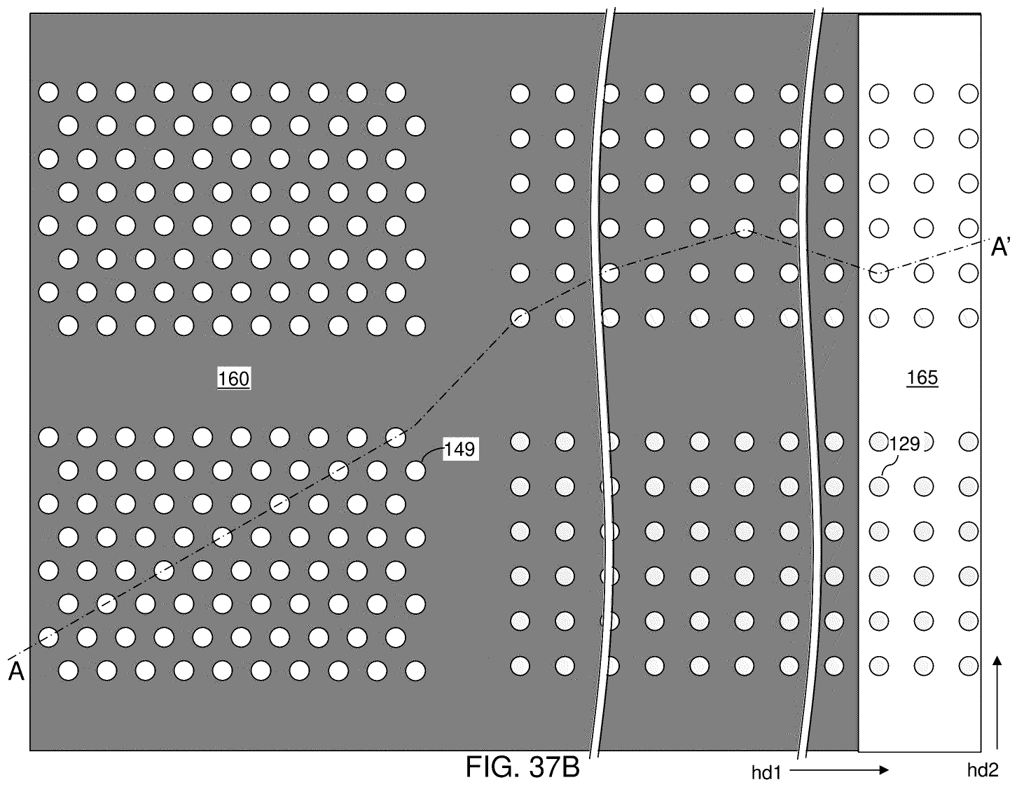

Referring to FIGS. 37A and 37B, the first stepped dielectric material portion 165 can be formed over and directly on physically exposed surfaces of the first transition-metal oxide etch stop layer 160 by depositing and planarizing a dielectric fill material such as undoped silicate glass or a doped silicate glass. Specifically, portions of the deposited dielectric fill material can be removed from above the horizontal plane including the top surface of the horizontally-extending portion of the first transition-metal oxide etch stop layer 160 that overlies the first insulating cap layer 170. Thus, the horizontal top surface of the first stepped dielectric material portion 165 may be coplanar with the topmost surface of the first transition-metal oxide etch stop layer 160. In the second embodiment, the first transition-metal oxide etch stop layer 160 is formed on the first stepped surfaces, and the first stepped dielectric material portion 165 is formed over and on the first transition-metal oxide etch stop layer 160. The first transition-metal oxide etch stop layer 160 underlies and contacts a stepped bottom surface of the first stepped dielectric material portion 165. Thus, the order of steps of forming layer 160 and portion 165 are reversed in the second embodiment compared to the first embodiment. Then the processing steps described with reference to FIGS. 3A and 3B may be performed with any needed changes to form first-tier memory openings 149 and first-tier support openings 119.

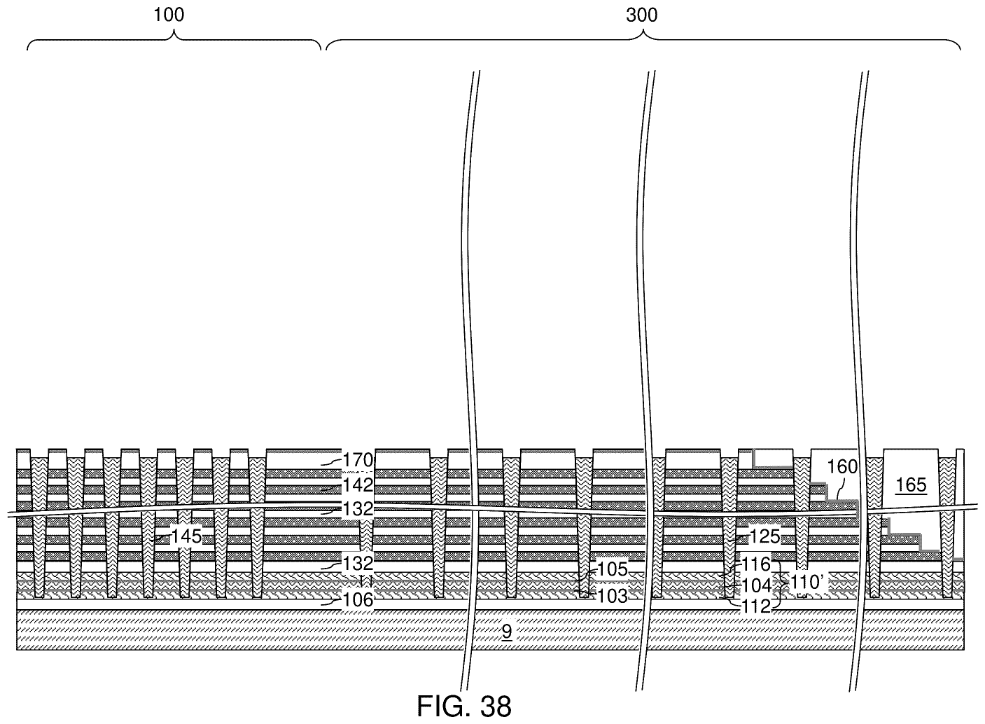

Referring to FIG. 38, the processing steps described with reference to FIG. 4 may be performed to form first lower sacrificial opening fill material portions (145, 125).

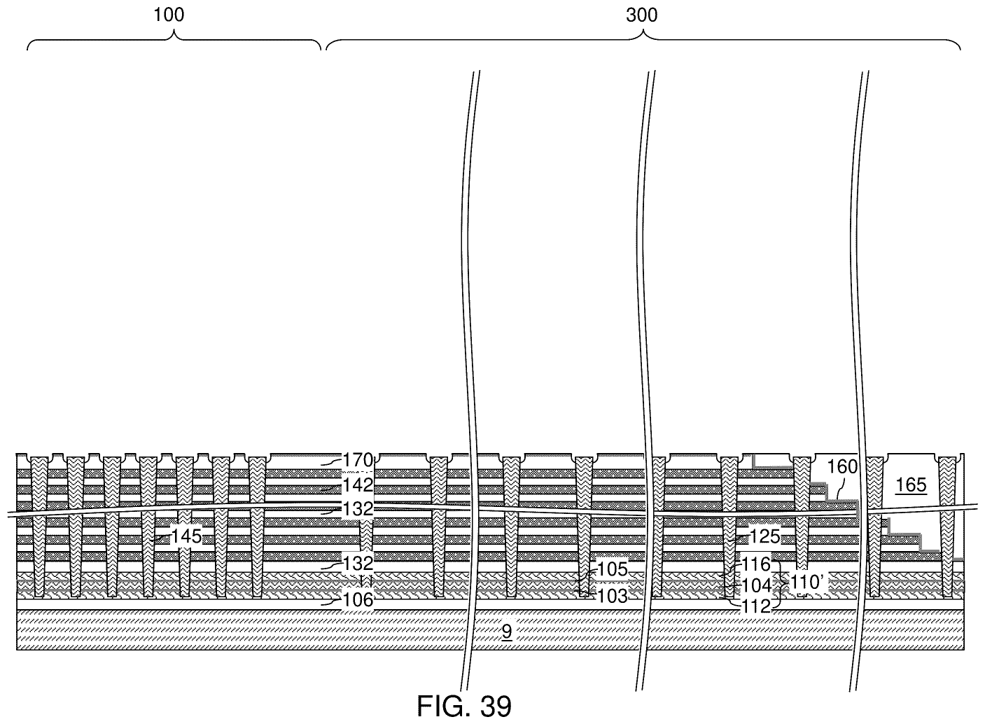

Referring to FIG. 39, the processing steps described with reference to FIG. 5 may be optionally performed to isotropically recess physically exposed surfaces of the first insulating cap layer 170.

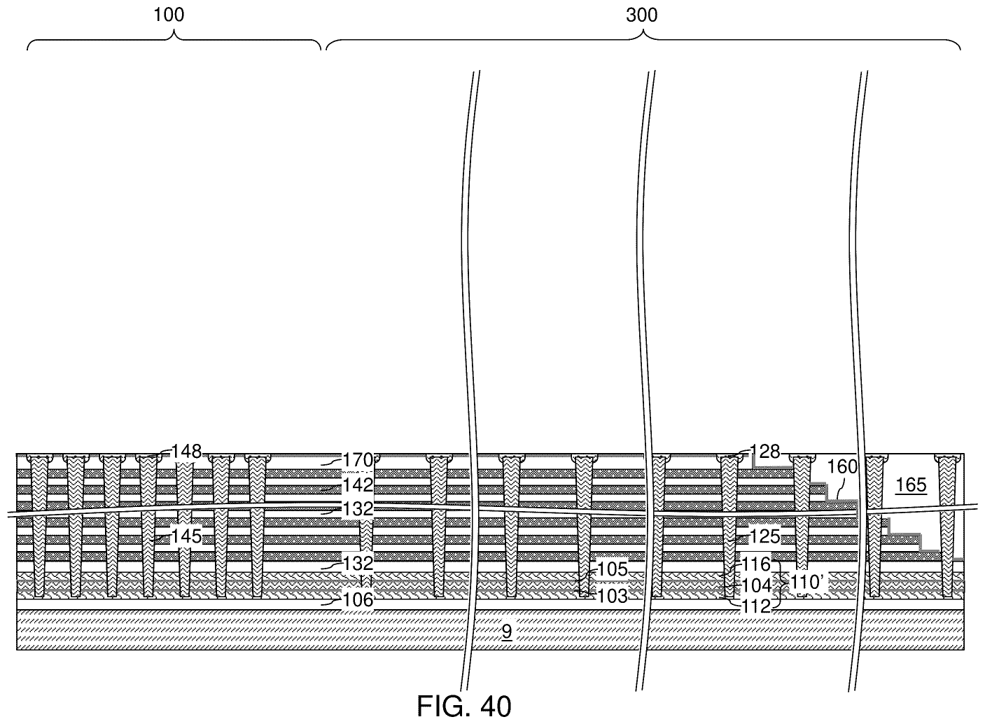

Referring to FIG. 40, the processing steps described with reference to FIG. 6 may be performed to form first upper sacrificial opening fill material portions (148, 248).

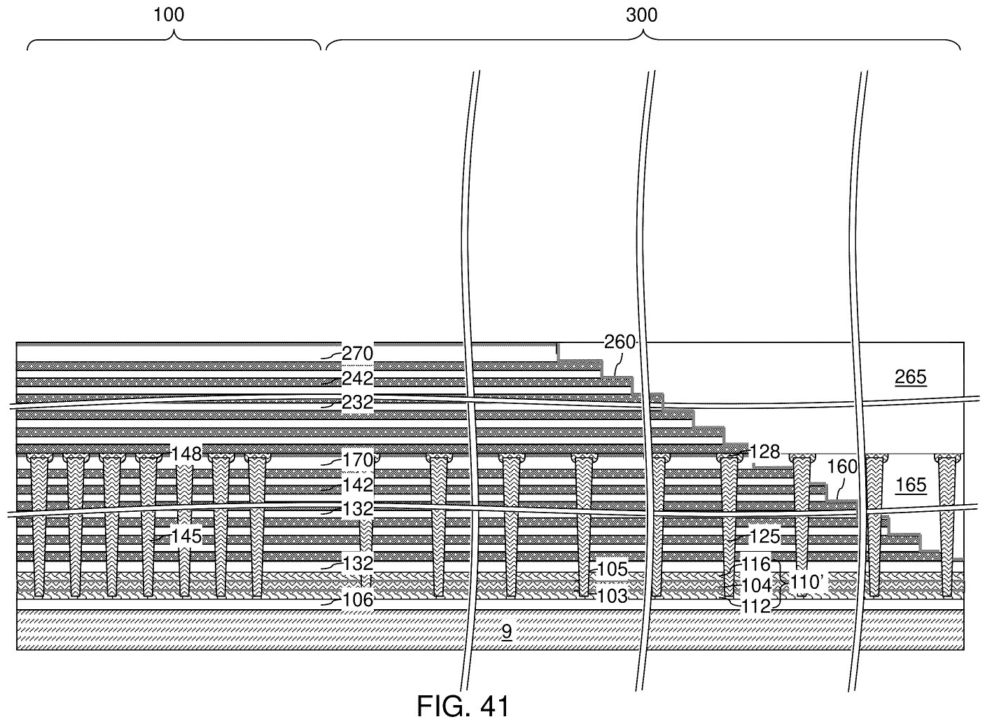

Referring to FIG. 41, the processing steps described with reference to FIG. 7 may be performed to form a second alternating stack (232, 242) of second insulating layers 232 and second sacrificial material layers 242 and a second first insulating cap layer 170. Second stepped surfaces can be formed in the contact region 300 by patterning the second alternating stack (232, 242).

A second transition-metal oxide etch stop layer 260 can be formed over the second insulating cap layer 270 and over the second stepped surfaces of the second alternating stack (232, 242). The second transition-metal oxide etch stop layer 260 may be the same in composition and in the thickness range as the second transition metal-oxide etch stop layer 260 described with reference to FIG. 8. The second transition-metal oxide etch stop layer 260 in the second exemplary structure may be formed by the same method as the second transition-metal oxide etch stop layer 260 described with reference to FIG. 8.

A second stepped dielectric material portion 265 can be formed over and directly on physically exposed surfaces of the second transition-metal oxide etch stop layer 260 by depositing and planarizing a dielectric fill material, such as undoped silicate glass or a doped silicate glass. Specifically, portions of the deposited dielectric fill material can be removed from above the horizontal plane including the top surface of the horizontally-extending portion of the second transition-metal oxide etch stop layer 260 that overlies the second insulating cap layer 270. Thus, the horizontal top surface of the second stepped dielectric material portion 265 may be coplanar with the topmost surface of the second transition-metal oxide etch stop layer 260. In the second embodiment, the second transition-metal oxide etch stop layer 260 is formed on the second stepped surfaces, and the second stepped dielectric material portion is formed over, and on, the second transition-metal oxide etch stop layer 260. The second transition-metal oxide etch stop layer 260 underlies and contacts a stepped bottom surface of the second stepped dielectric material portion 265.

In the second exemplary structure, a first transition-metal oxide etch stop layer 160 overlies first stepped surfaces of the first alternating stack (132, 142) and overlies the first insulating cap layer 170. A first stepped dielectric material portion 165 can be formed over the first transition-metal oxide etch stop layer 160. A second alternating stack (232, 242) of second insulating layers 232 and second spacer material layers (such as the second sacrificial material layers 242) can be formed over the first transition-metal oxide etch stop layer 160 and the first stepped dielectric material portion 165. Second stepped surfaces can be formed by patterning at least the second alternating stack (232, 242). A second transition-metal oxide etch stop layer 260 can be formed over the second stepped surfaces. A second stepped dielectric material portion 265 can be formed over the second transition-metal oxide etch stop layer 160.

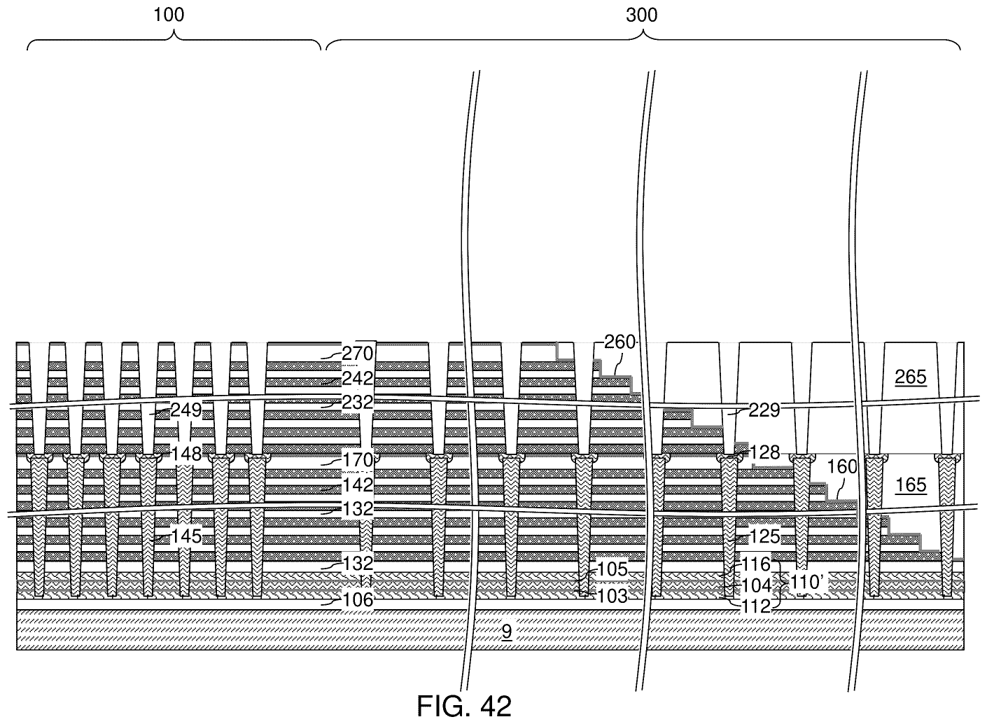

Referring to FIG. 42, the processing steps described with reference to FIG. 9 may be performed with any needed changes to form second-tier memory openings 249 and second-tier support openings 229.

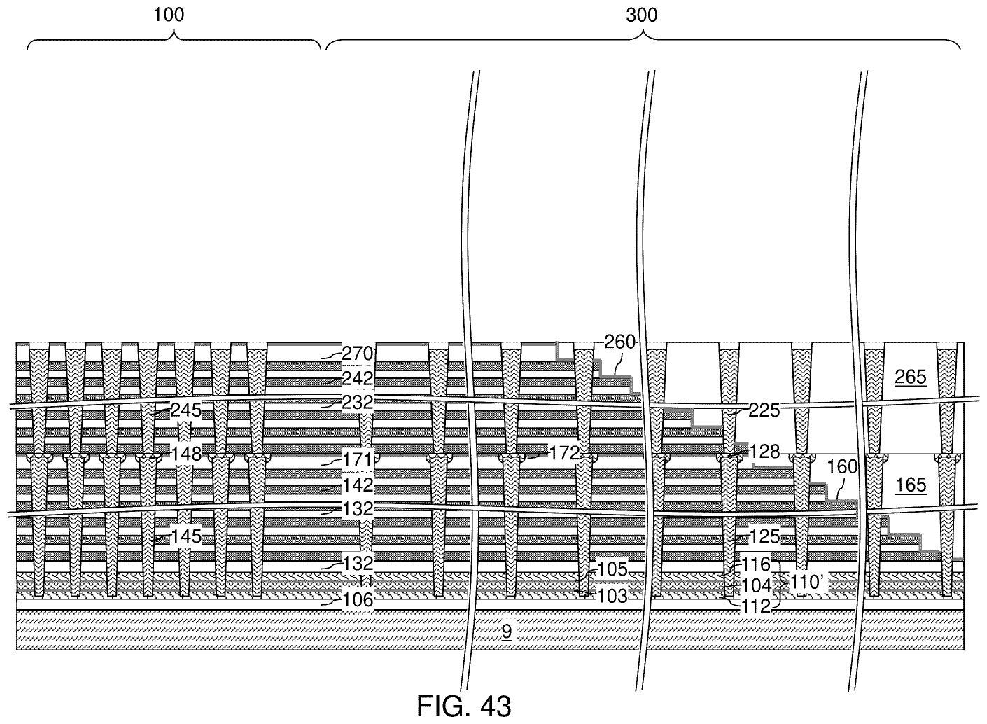

Referring to FIG. 43, the processing steps described with reference to FIG. 10 may be performed to form second lower sacrificial opening fill material portions (245, 225).

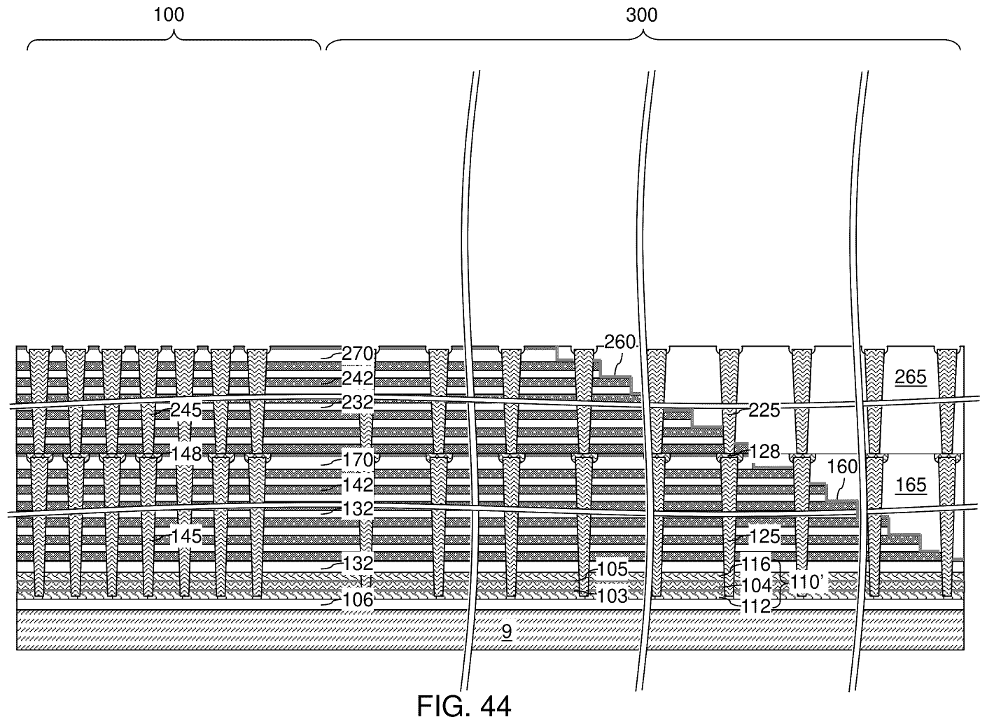

Referring to FIG. 44, the processing steps described with reference to FIG. 11 may be optionally performed to isotropically recess physically exposed surfaces of the second insulating cap layer 270.

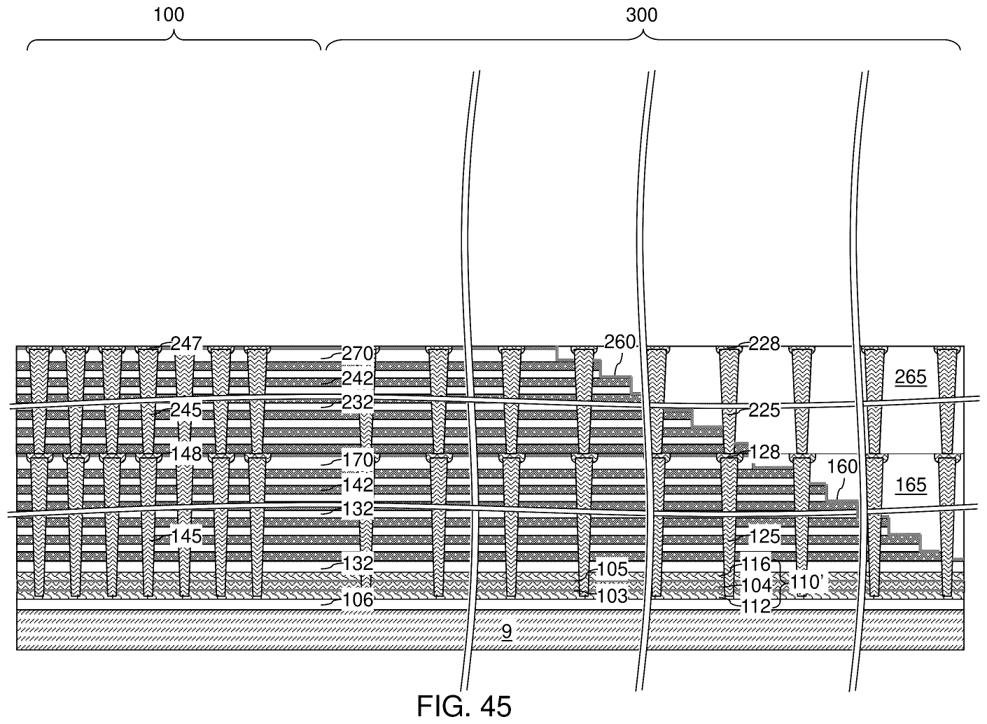

Referring to FIG. 45, the processing steps described with reference to FIG. 12 may be performed to form second upper sacrificial opening fill material portions (248, 248).

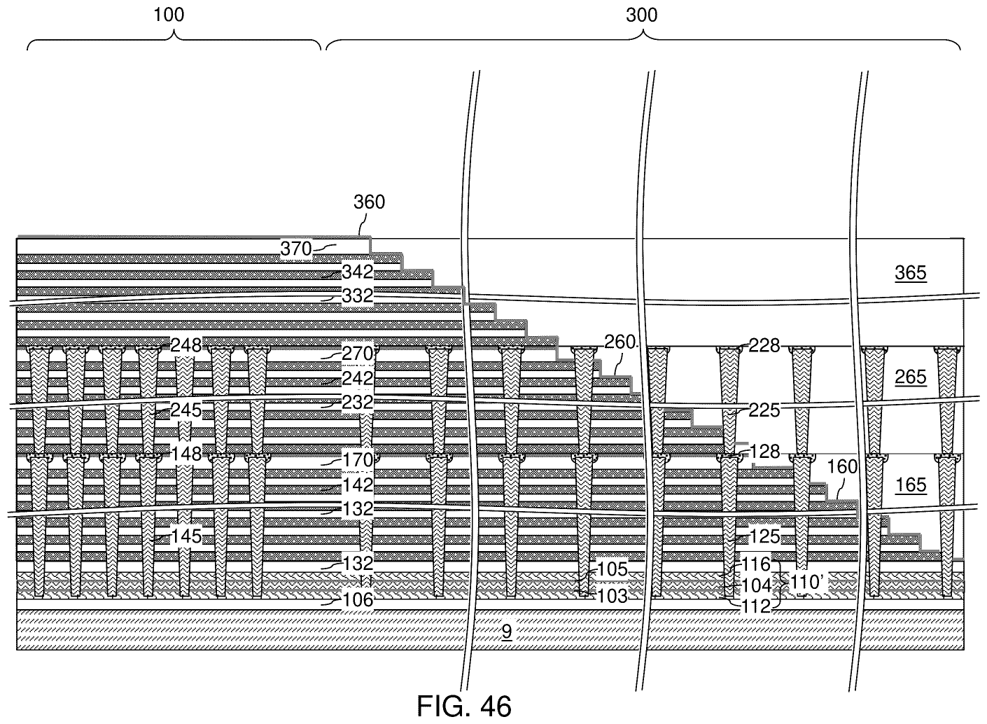

Referring to FIG. 46, the processing steps described with reference to FIG. 13 may be performed to form a third alternating stack of third insulating layers 332 and third sacrificial material layers 342, a third insulating cap layer 370, third stepped surfaces, and a third stepped dielectric material portion 365. Optionally, a third transition-metal oxide etch stop layer 360 including a dielectric metal oxide of a transition metal can be deposited over the top surface of third insulating cap layer 370 and over the stepped surfaces of the third tier.

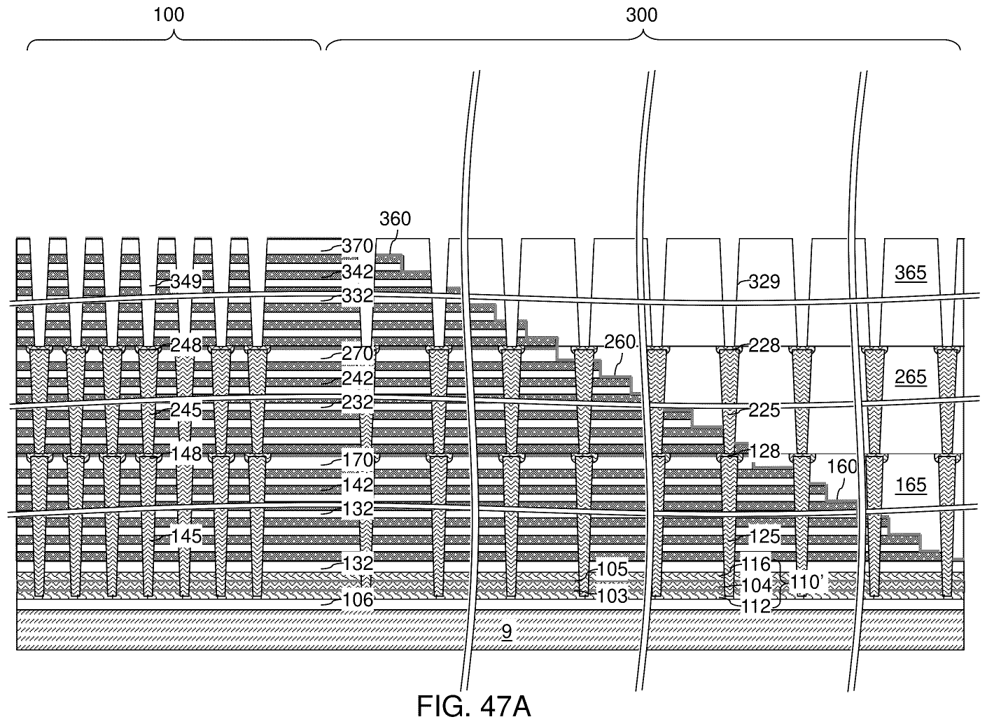

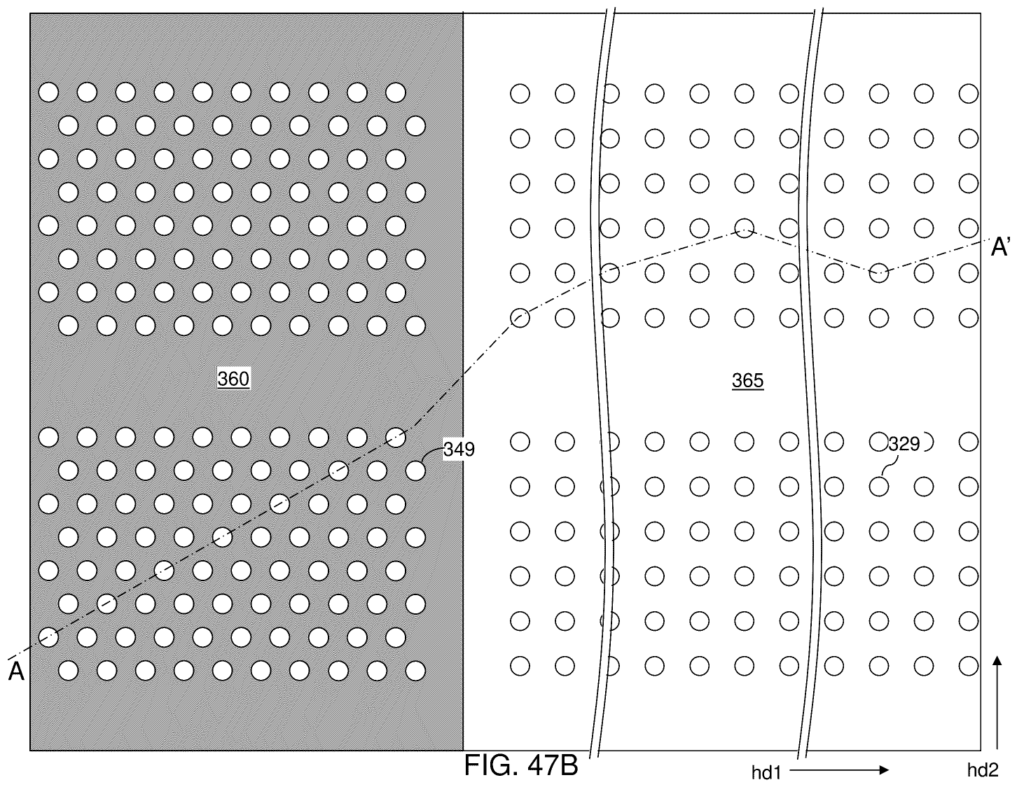

Referring to FIGS. 47A and 47B, the processing steps described with reference to FIGS. 14A and 14B may be performed to form third-tier memory openings 49 and third-tier support openings 19.

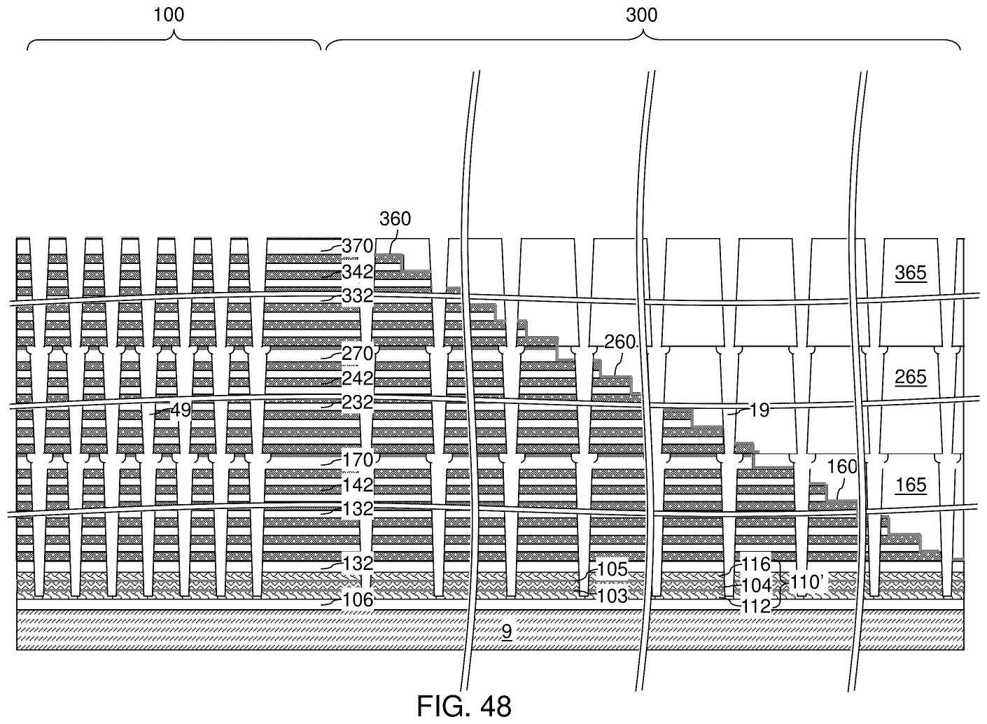

Referring to FIG. 48, the processing steps described with reference to FIG. 15 may be performed to form multi-tier memory openings 49 and multi-tier support openings 19.

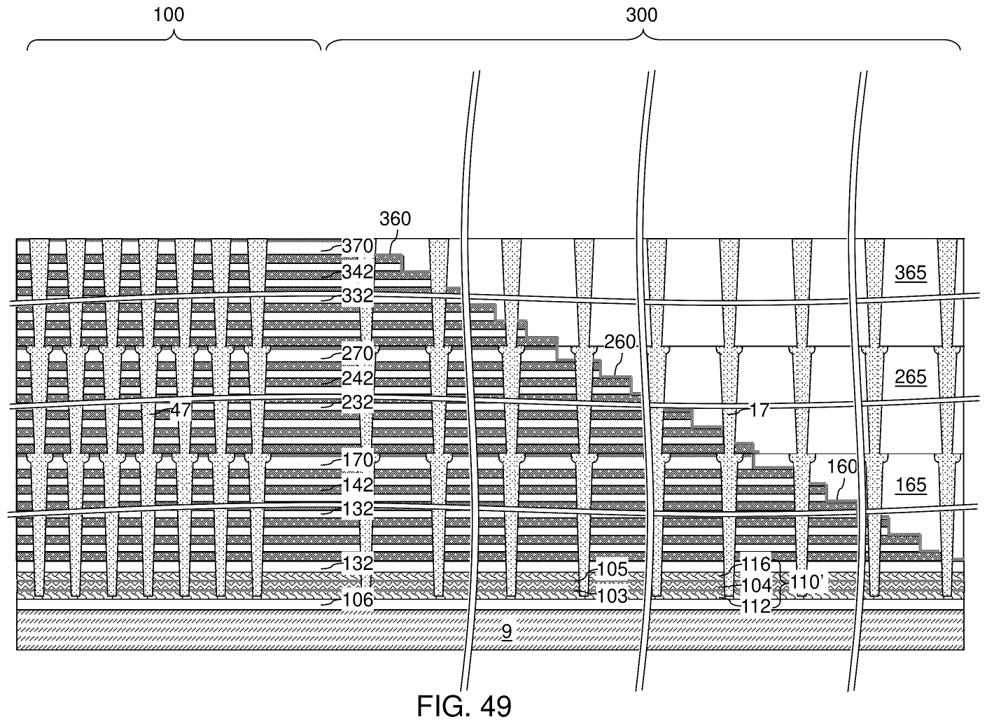

Referring to FIG. 49, the processing steps described with reference to FIG. 16 may be performed to form sacrificial multi-tier memory opening fill structures 47 and sacrificial multi-tier support opening fill structures 17.

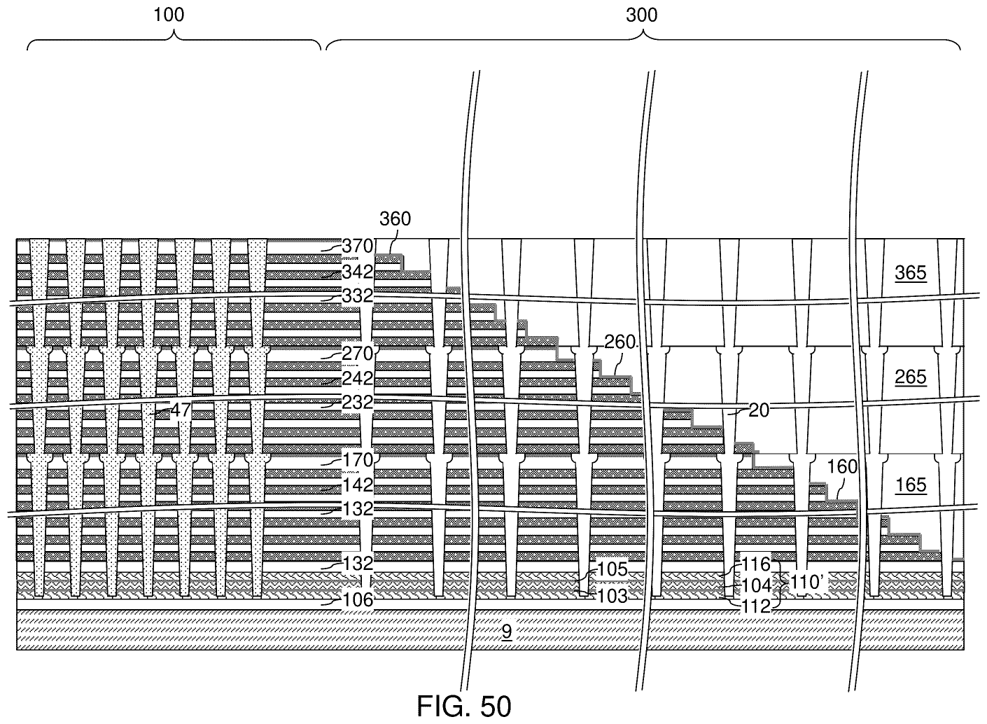

Referring to FIG. 50, the processing steps described with reference to FIG. 17 may be performed to replace the sacrificial multi-tier support opening fill structures 17 with support pillar structures 20.

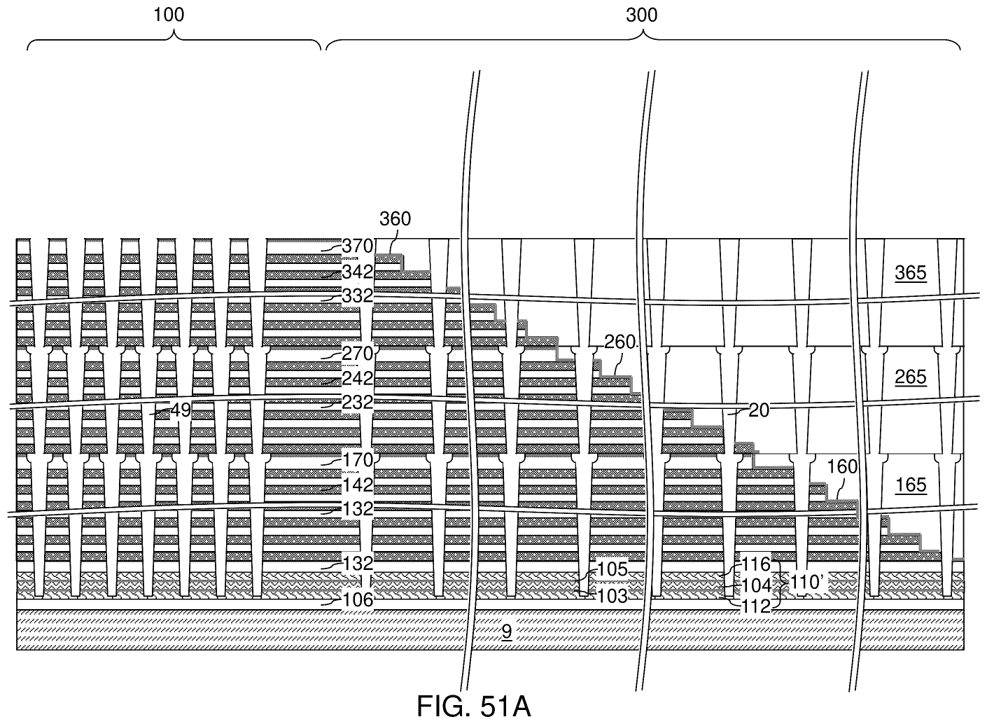

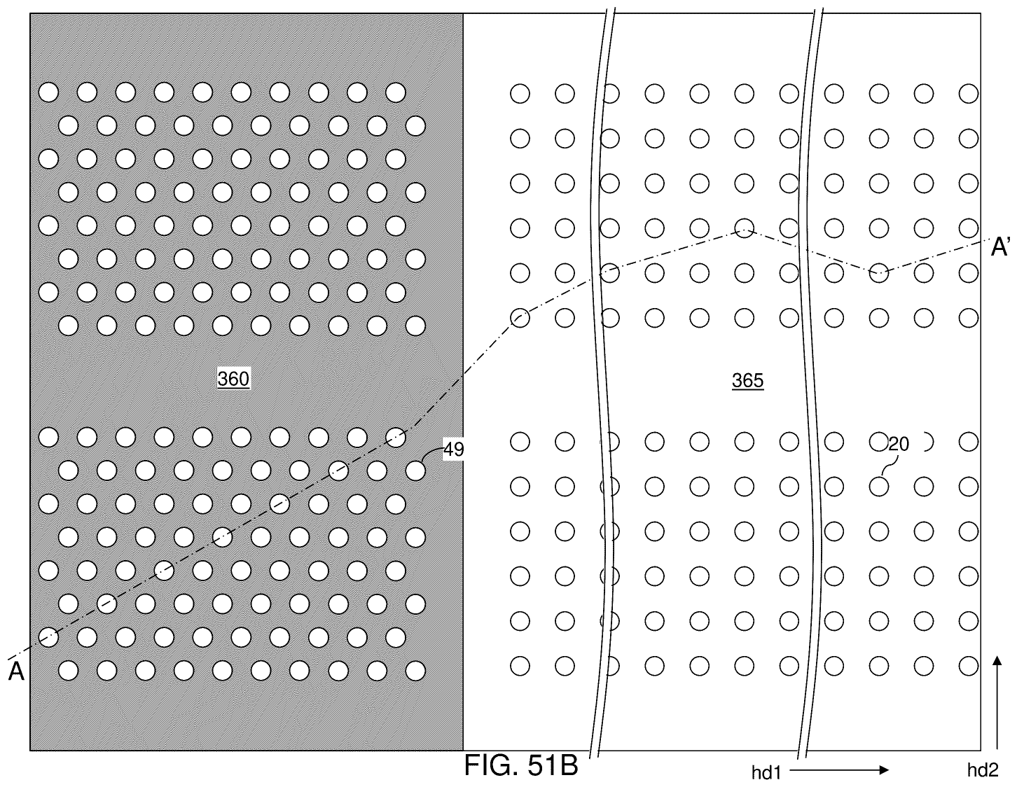

Referring to FIGS. 51A and 51B, the processing steps described with reference to FIGS. 18A and 18B may be performed to remove the sacrificial multi-tier memory opening fill structures 47 and to form voids in the volumes of the memory openings 49.

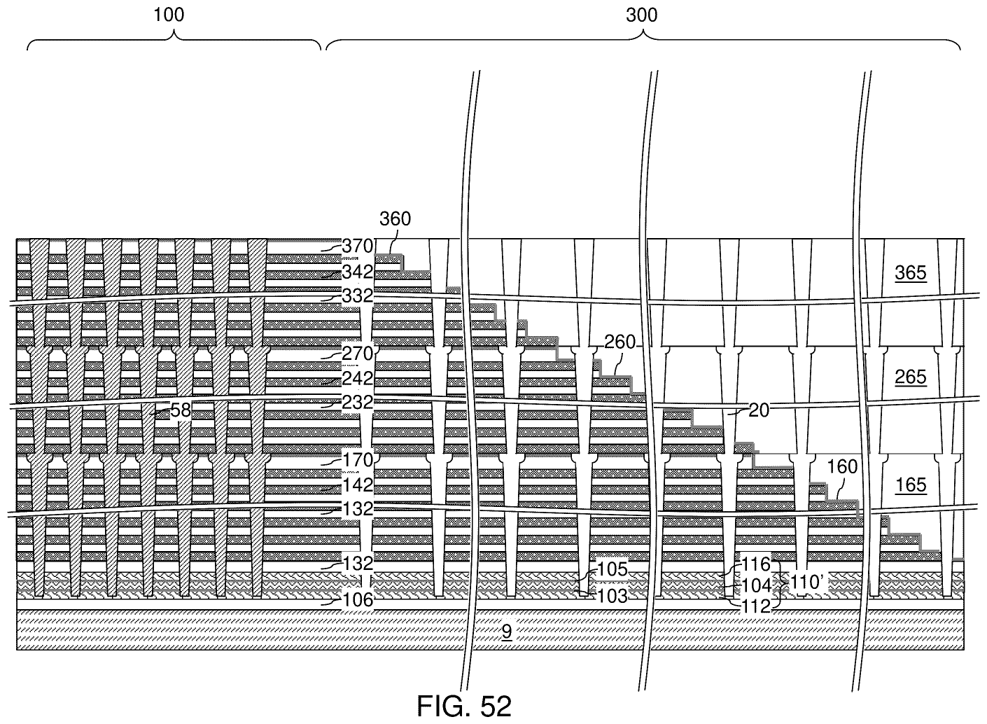

Referring to FIG. 52, the processing steps described with reference to FIGS. 19A-19D and 20 may be performed to for memory opening fill structures 58 in the memory openings 49.

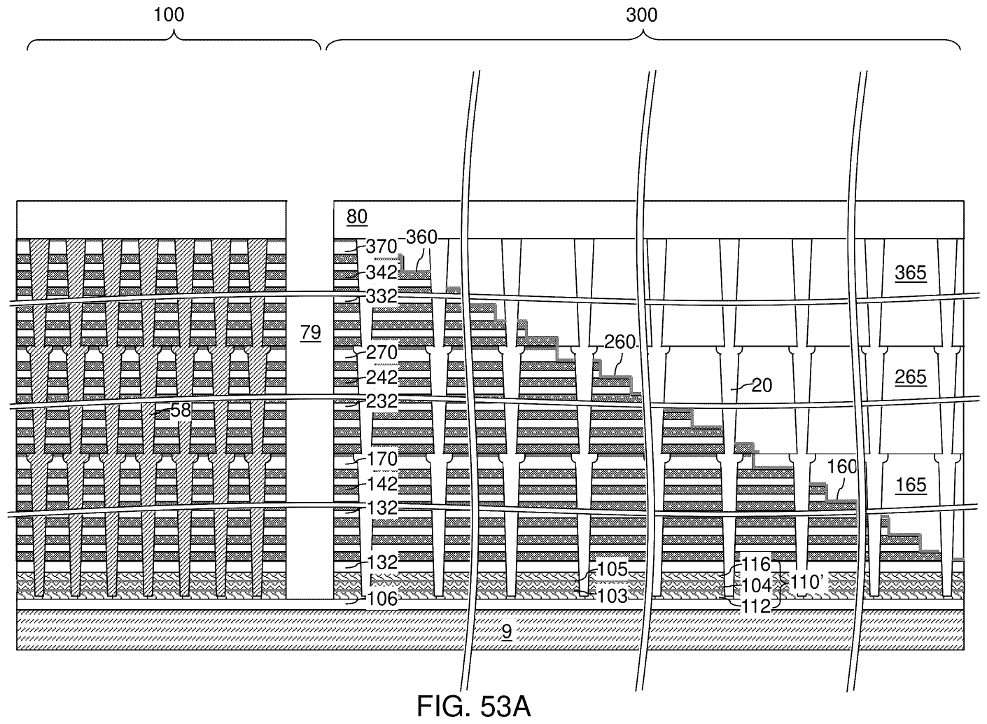

Referring to FIGS. 53A and 53B, the processing steps described with reference to FIGS. 21A and 21B may be performed to form a contact-level dielectric layer 80 and lateral isolation trenches 79.

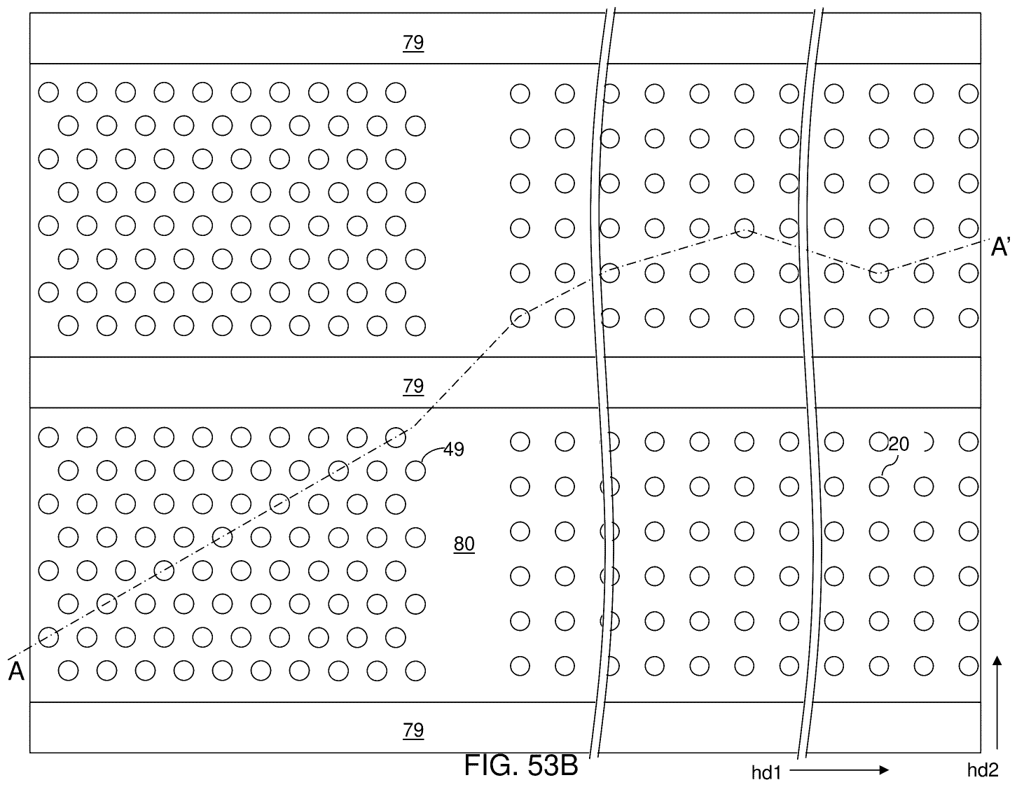

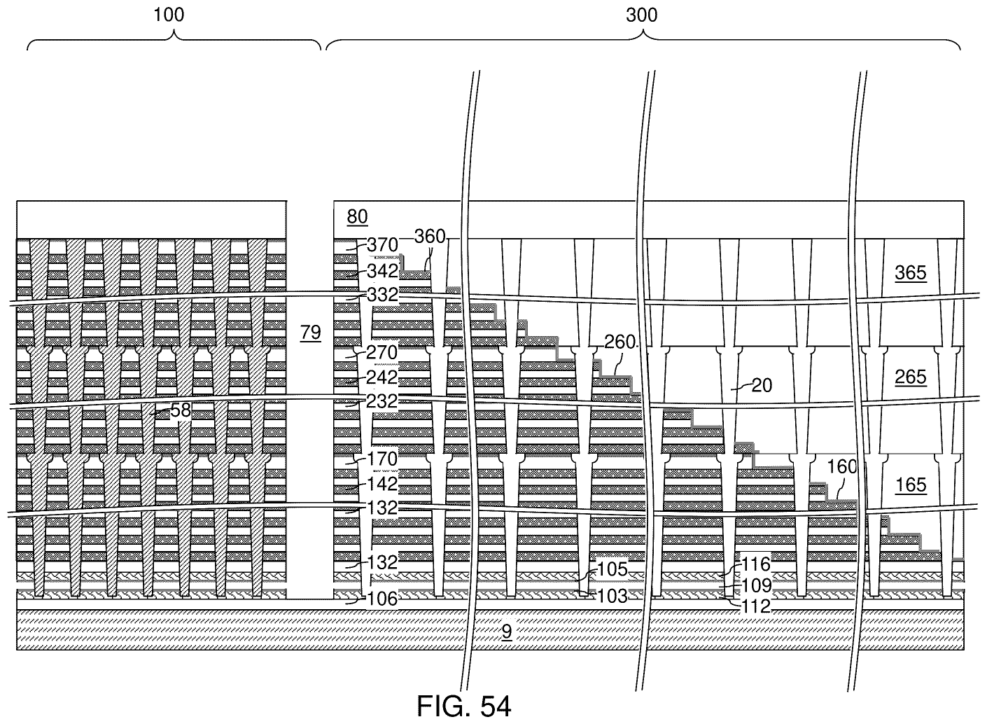

Referring to FIG. 54, the processing steps described with reference to FIGS. 22A and 22B may be performed to form a source cavity 109.

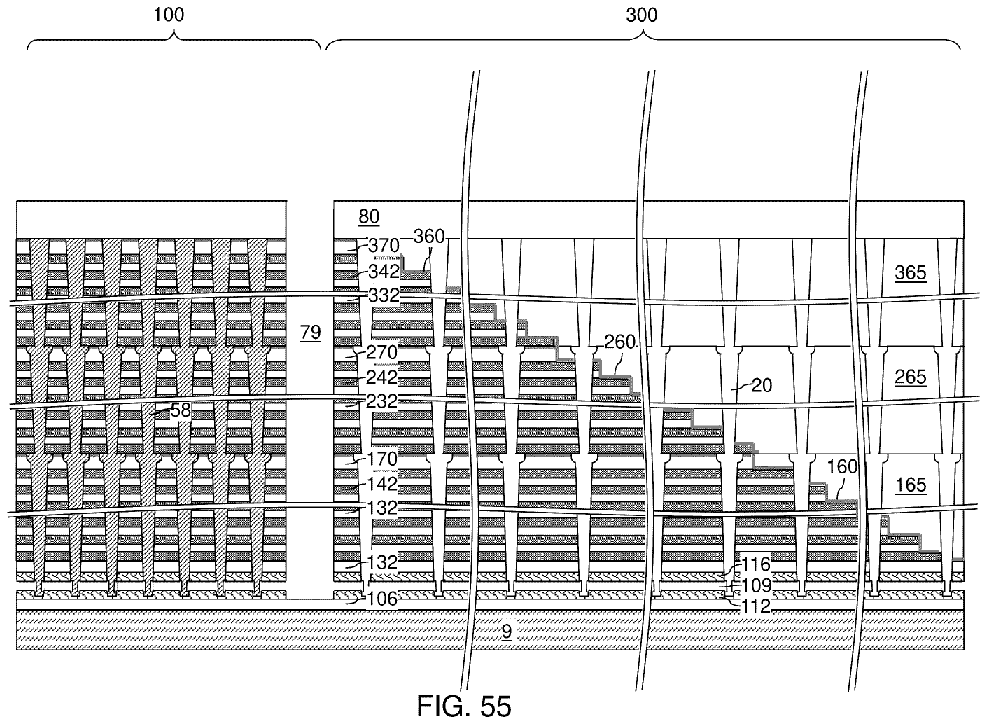

Referring to FIG. 55, the processing steps described with reference to FIGS. 23A and 23B may be performed to remove portions of the memory films 50 that are exposed to the source cavity 109.

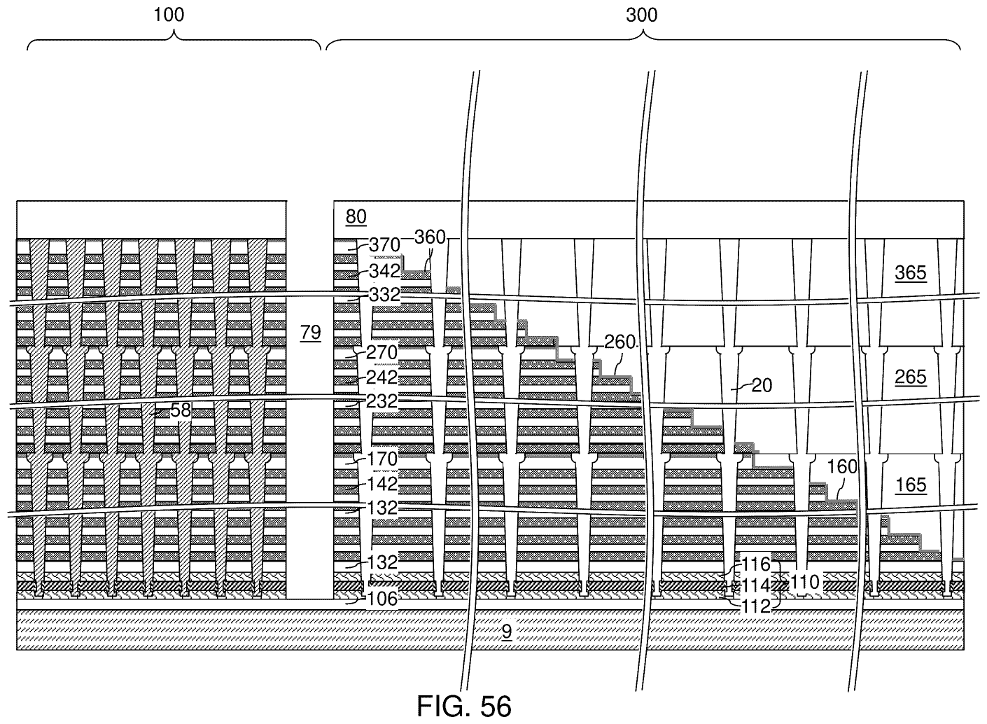

Referring to FIG. 56, the processing steps described with reference to FIGS. 24A and 24B may be performed to form a source contact layer 114 in the source cavity 109.

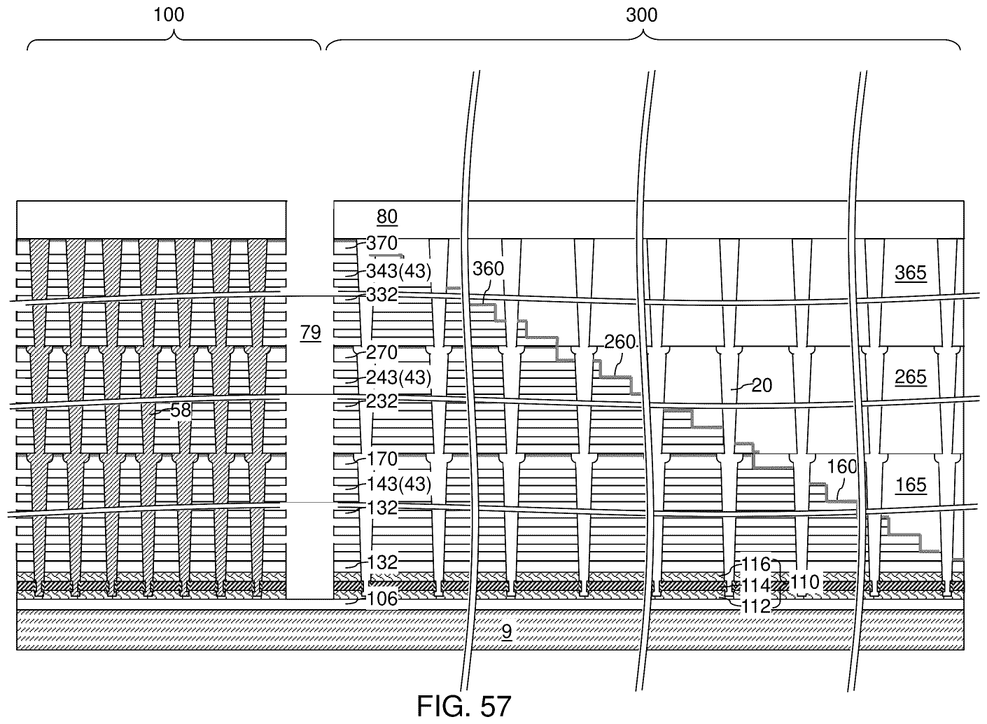

Referring to FIG. 57, the processing steps described with reference to FIG. 25 may be performed to form laterally-extending cavities 43.

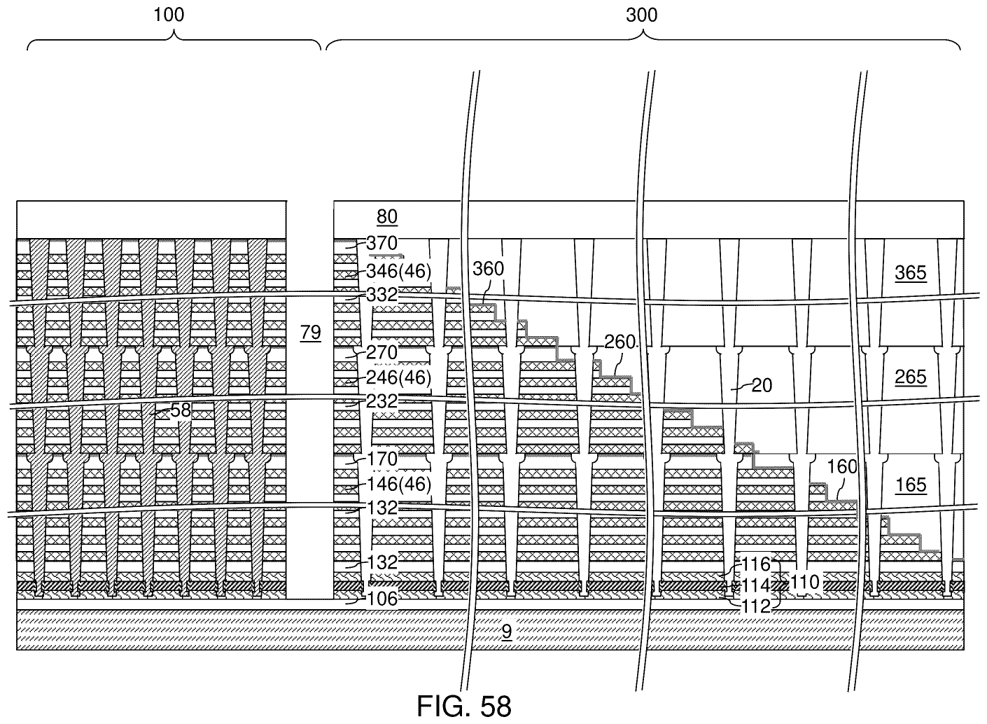

Referring to FIG. 58, the processing steps described with reference to FIG. 26 may be performed to form electrically conductive layers 46 in the laterally-extending cavities 43.

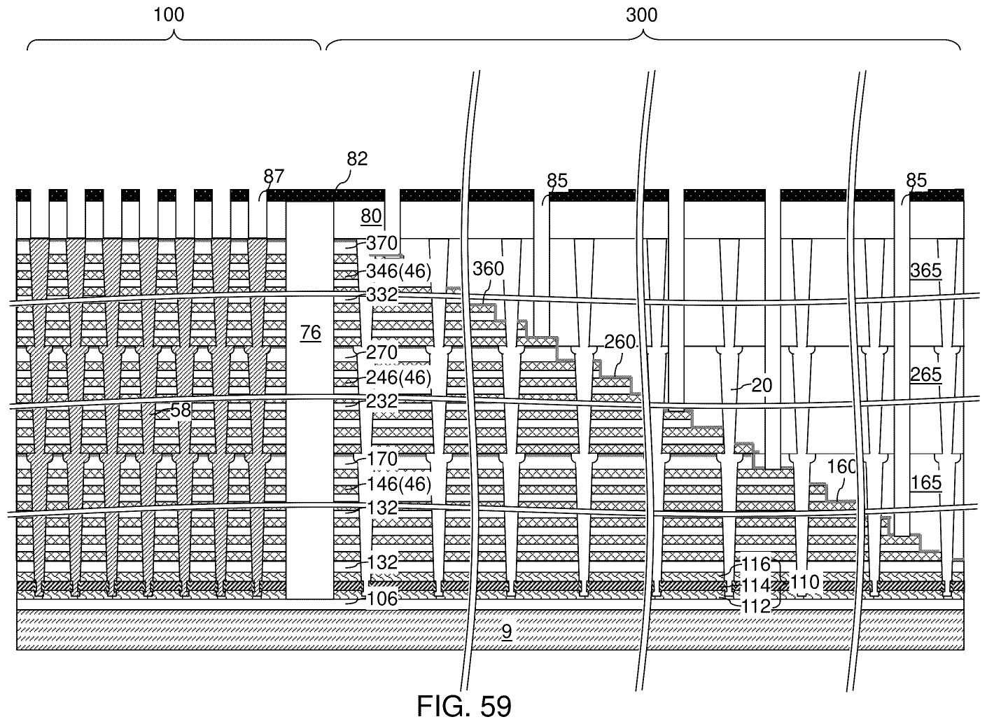

Referring to FIG. 59, the processing steps described with reference to FIGS. 27A and 27B may be performed to form an etch mask layer 82. The material composition, the thickness range, and the pattern of the etch mask layer 82 may be the same as the etch mask layer 82 described with reference to FIGS. 27A and 27B. Generally, the patterned etch mask layer 82 over each of the alternating stacks {(132, 142), (232, 242), (332, 242)}.

The pattern of the openings in the patterned etch mask layer 82 can be transferred through the contact-level dielectric layer 80 and the stepped dielectric material portions (165, 265, 365) by performing an anisotropic etch process. According to an aspect of the present disclosure, the anisotropic etch process may employ a fluorine-based etch chemistry and may etch the materials of the contact-level dielectric layer 80 and the third stepped dielectric material portions (165, 265, 365) selective to the material of the transition-metal oxide etch stop layers (160, 260) and selective to the semiconductor material of the drain regions 63. Thus, the transition-metal oxide etch stop layers (160, 260) located over the stepped surfaces of the electrically conductive layers (146, 246, 346) act as etch stop layers in the contact region 300. Contact via cavities (85, 87) are formed through the contact-level dielectric layer 80 and the stepped dielectric material portions (165, 265, 365). The contact via cavities (85, 87) comprise layer contact via cavities 85 that overlie a respective horizontally-extending surface of the stepped surfaces, and drain contact via cavities 87 that overlie the drain regions 63. A break-through anisotropic etch process employing a chlorine-based etch chemistry is then performed to etch through the physically exposed portions of the transition-metal oxide etch stop layers (160, 260). Top surfaces of the electrically conductive layers 46 can be physically exposed underneath the layer contact via cavities 85. Top surfaces of drain regions 63 can be physically exposed underneath the drain contact via cavities 87.

Generally, the pattern of openings in the patterned etch mask layer 82 can be transferred through the stepped dielectric material portions (165, 265, 365) to form layer contact via cavities 87 by performing an anisotropic etch process (which is also referred to as a main anisotropic etch process which may employ a fluorine-based etch chemistry utilizing, for example, CF₄ and/or CHF₃) that etches materials of the stepped dielectric material portions (165, 265, 365) selective to materials of the transition-metal oxide etch stop layers (160, 260). The layer contact via cavities 87 can be vertically extended through the transition-metal oxide etch stop layers (160, 260) by performing a break-through anisotropic etch process (which may employ a chlorine-based etch chemistry described above).

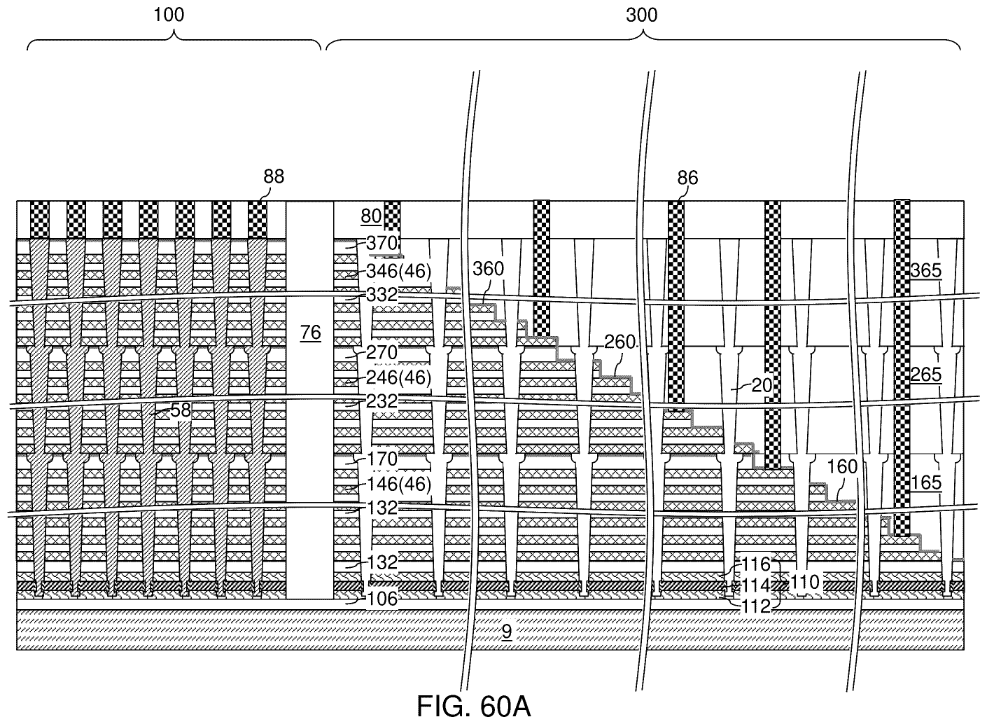

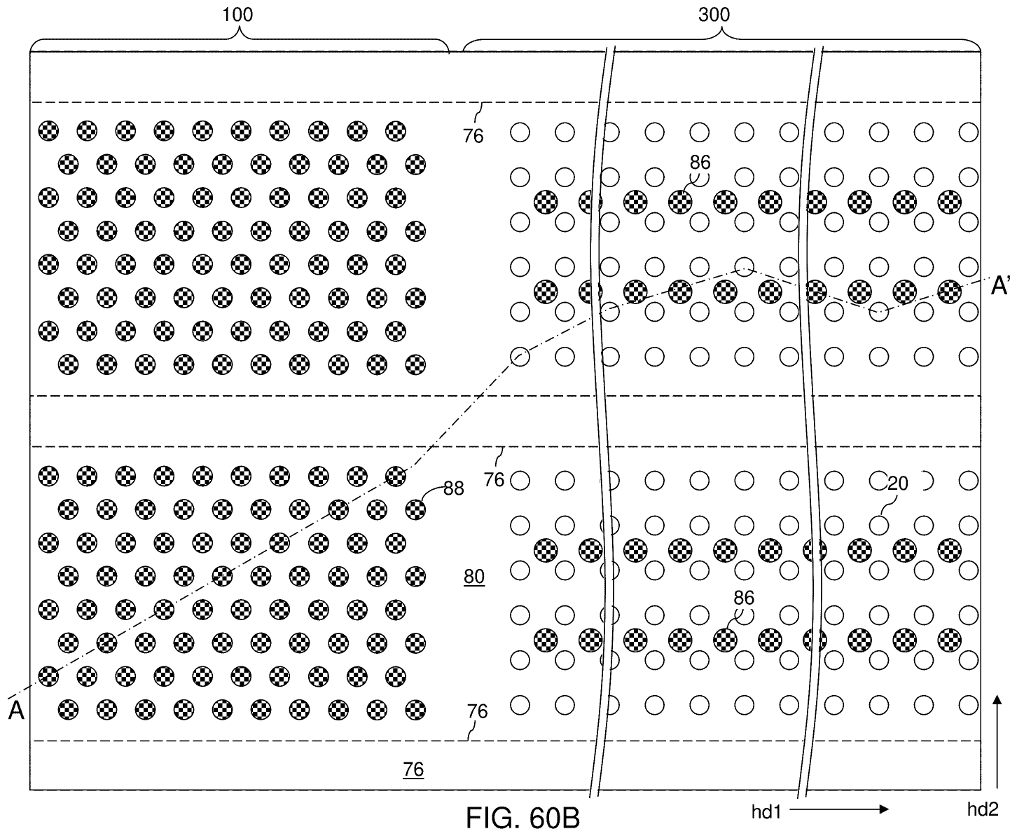

Referring to FIGS. 60A and 60B, the processing steps described with reference to FIGS. 31A and 31B may be performed to form drain contact via structures 88 in the drain contact via cavities 87, and to form layer contact via structures 86 in the layer contact via cavities 85.

In one embodiment, the layer contact via structures 86 vertically extend through the contact-level dielectric layer 80, through the third stepped dielectric material portion 365, optionally through the second transition-metal oxide etch stop layer 260, optionally through the second stepped dielectric material portion 265, optionally through the first transition-metal oxide etch stop layer 160, and optionally through the first stepped dielectric material portion 165, and are formed on a top surface of a respective one of the electrically conductive layers 46. A first subset of the layer contact via structures 86 vertically extends through the second stepped dielectric material portion 265, the first transition-metal oxide etch stop layer 160, and the first stepped dielectric material portion 165, and contacts a top surface of a respective one of the first electrically conductive layers 146. The first subset of the layer contact via structures 86 is in contact with the second stepped dielectric material portion 265, the first transition-metal oxide etch stop layer 160, and the first stepped dielectric material portion 165.

In one embodiment, the second insulating cap layer 270 may overlie the second alternating stack (232, 246), the second transition-metal oxide etch stop layer 260 may overlie the second insulating cap layer 270, the third alternating stack of third insulating layers 332 and third electrically conductive layers 346 may have third stepped surfaces and overlying the second transition-metal oxide etch stop layer 260, and the third stepped dielectric material portion 365 may overlie the second stepped surfaces. In one embodiment, a memory opening 49 vertically extends through the third alternating stack (332, 346) and the second transition-metal oxide etch stop layer 260, and a layer contact via structure 86 vertically extends through the third stepped dielectric material portion 365 and the second transition-metal oxide etch stop layer 260.

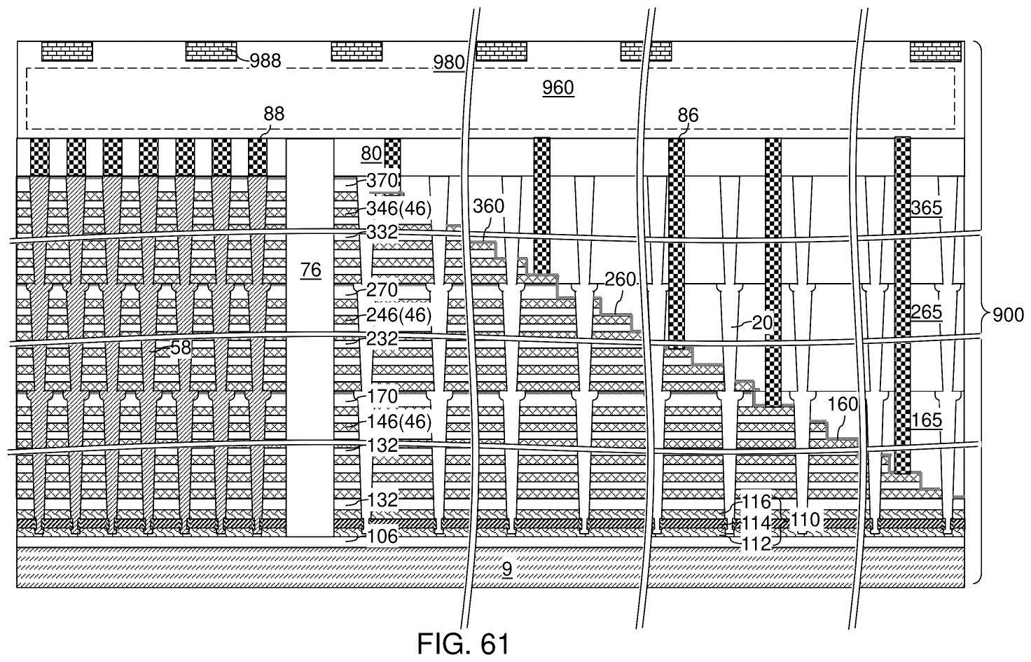

Referring to FIG. 61, the processing steps described with reference to FIG. 32 may be performed to form memory-side dielectric material layers 960 and memory-side metal interconnect structures 980.

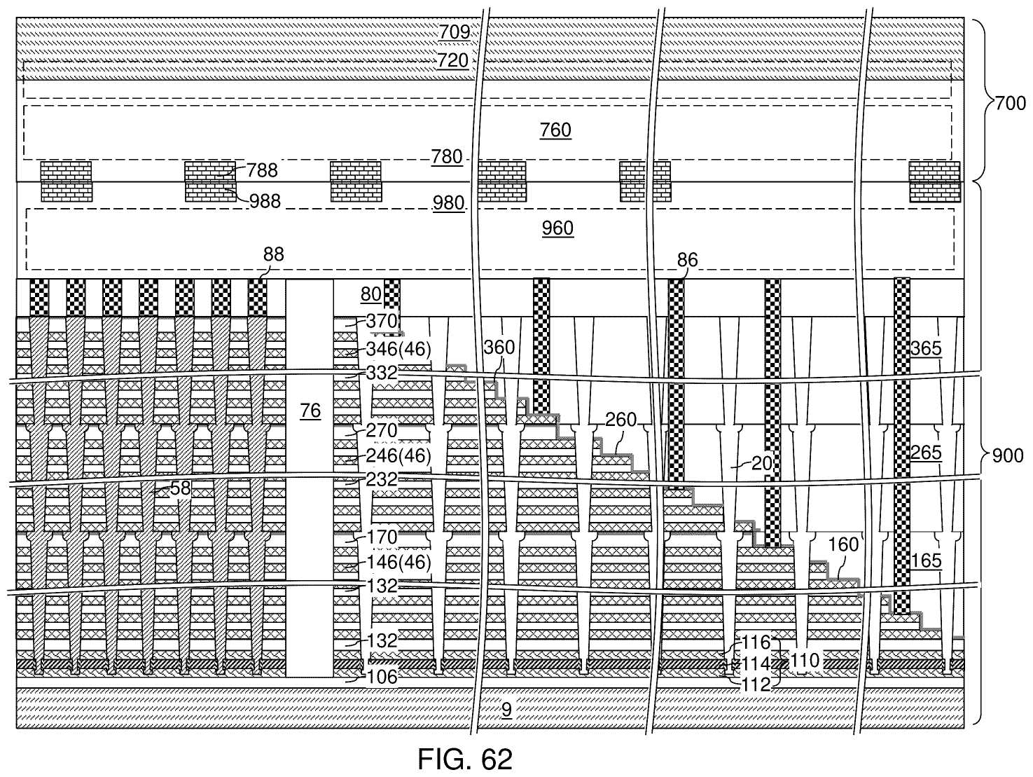

Referring to FIG. 62, the processing steps described with reference to FIG. 33 may be performed to attach a logic die 700 to a memory die 900.

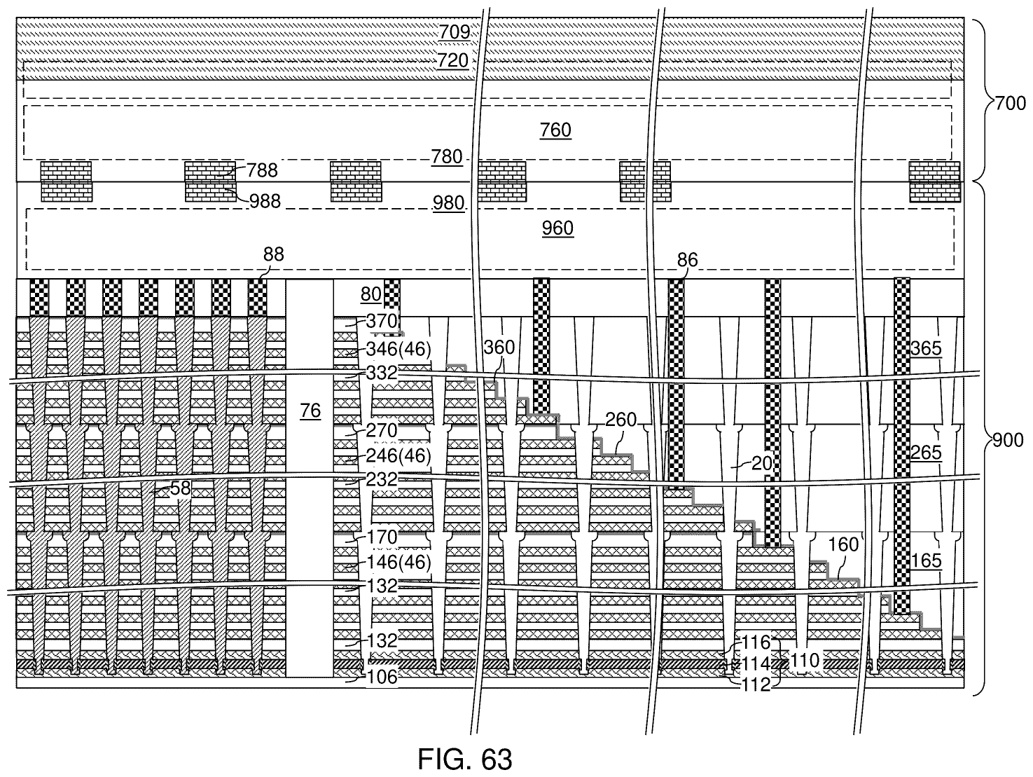

Referring to FIG. 63, the processing steps described with reference to FIG. 34 may be performed to remove the carrier substrate 9.

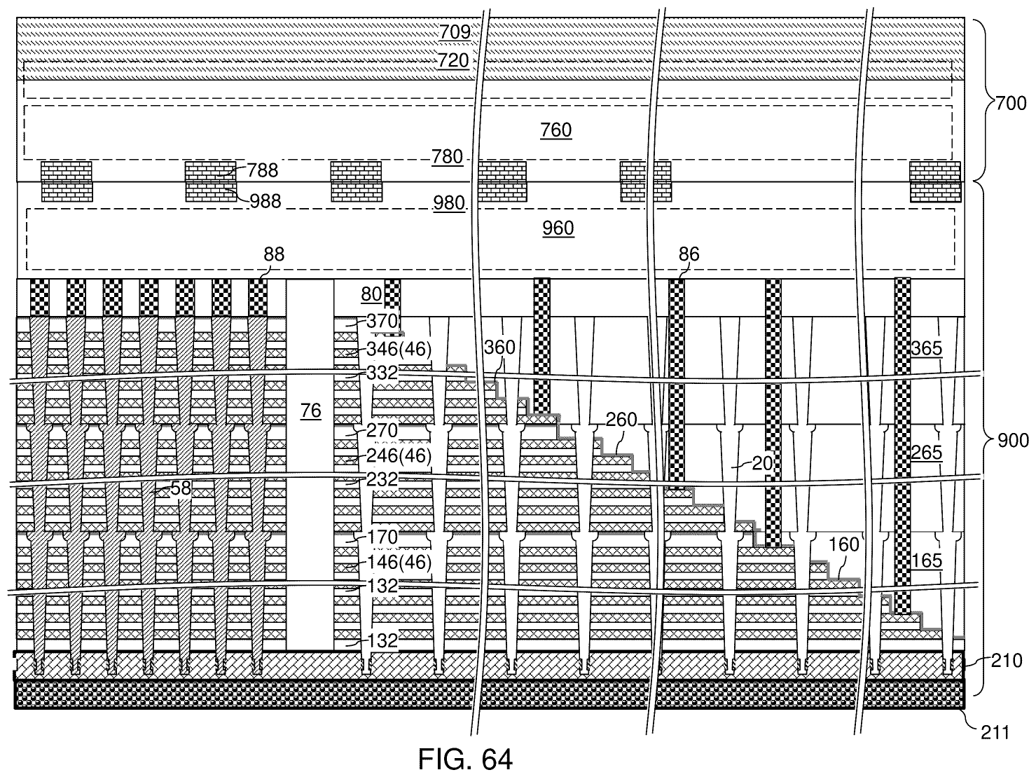

Referring to FIG. 64, the processing steps described with reference to FIG. 35 may be performed to form the source layer 210.

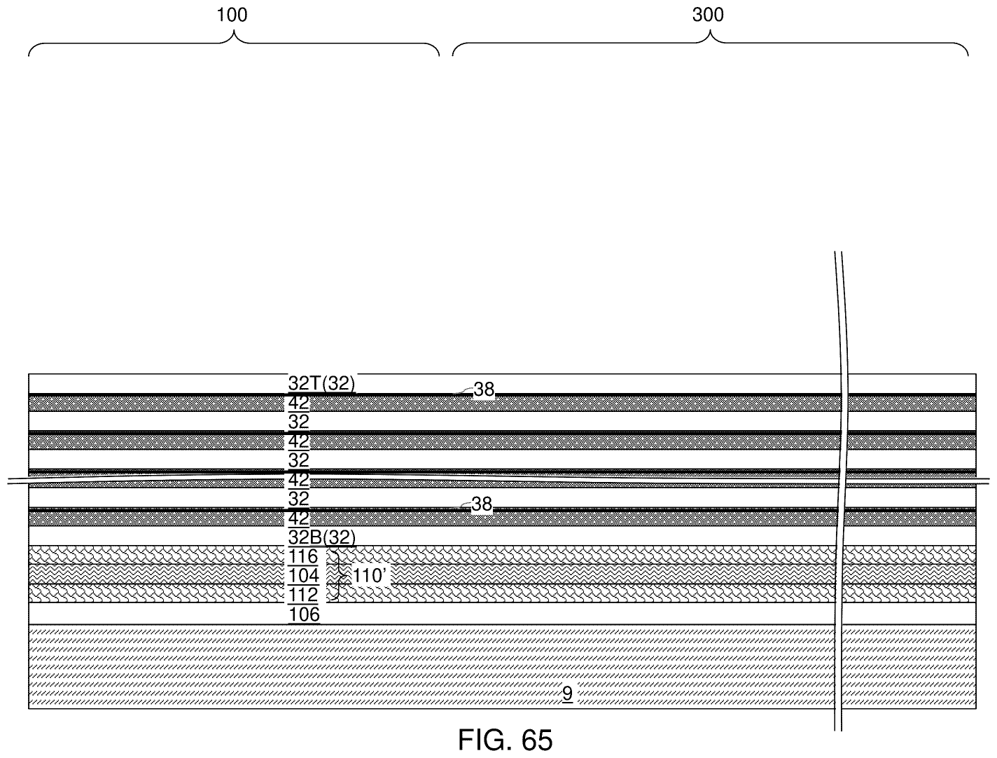

Referring to FIG. 65, a third exemplary structure according to a third embodiment of the present disclosure is illustrated. The third exemplary structure can be derived from the first exemplary structure illustrated in FIG. 1 by forming a vertical repetition of multiple instances of a unit layer stack (32, 42, 38) in lieu of the first alternating stack of first insulating layers 132 and first spacer material layers 142. According to an aspect of the present disclosure, the unit layer stack (32, 42, 38) may comprise and/or may consist of an insulating layer 32, a sacrificial material layer 42, and a transition-metal oxide etch stop layer 38. A topmost insulating layer 32T, which may have the same material composition as the insulating layers 32, may be formed over the vertical repetition of the multiple instances of the unit layer stack (32, 42, 38). The total number of instance of the unit layer stack (32, 42, 38) in the multiple instances of the unit layer stack (32, 42, 38) may be in a range from 8 to 1,024, such as from 64 to 256, although lesser and greater numbers may also be employed.

Each instance of the insulating layer 32, each instance of the sacrificial material layer 42, and each instance of the transition-metal oxide etch stop layer 38 may be formed as a planar material layer having a respective uniform thickness throughout. The insulating layers 32 may have the same material composition and the same thickness range as any of the first insulating layers 132, the second insulating layers 232, or the third insulating layers 332 described above. The sacrificial material layers 42 may have the same material composition and the same thickness range as any of the first sacrificial material layers 142, the second sacrificial material layers 242, or the third sacrificial material layers 342. The transition-metal oxide etch stop layers 38 may have the same material composition and the same thickness range as any of the first or second transition-metal oxide etch stop layers (160, 260). In the third embodiment, each instance of the transition-metal oxide etch stop layer 38 overlies and contacts a top surface of a respective spacer material layer, which may be formed as an electrically conductive layer or as a sacrificial material layer 42.

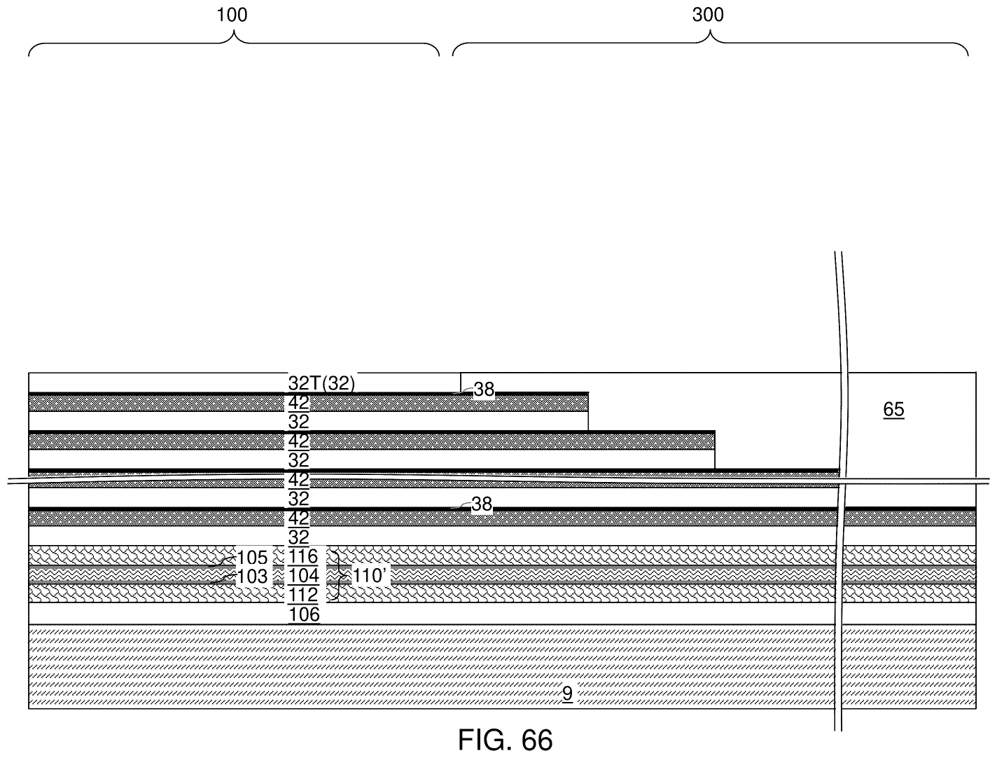

Referring to FIG. 66, the processing steps described with reference to FIG. 2 may be performed with any needed changes to form the stepped surfaces are formed in the contact region 300. The stepped surfaces comprise top surface segments of the transition-metal oxide etch stop layers 38. In one embodiment, each of the transition-metal oxide etch stop layers 38 may have a respective top surface segment that is physically exposed to the stepped cavity.

A stepped dielectric material portion 65 (i.e., an insulating fill material portion) can be formed in the stepped cavity by deposition of a dielectric material therein as described above with respect to FIG. 2. The stepped dielectric material portion 65 overlies the stepped surfaces. In one embodiment, the transition-metal oxide etch stop layer 38 within each instance of the unit layer stack (32, 42, 38) can be in contact with a surface segment of a stepped bottom surface of the stepped dielectric material portion 65.

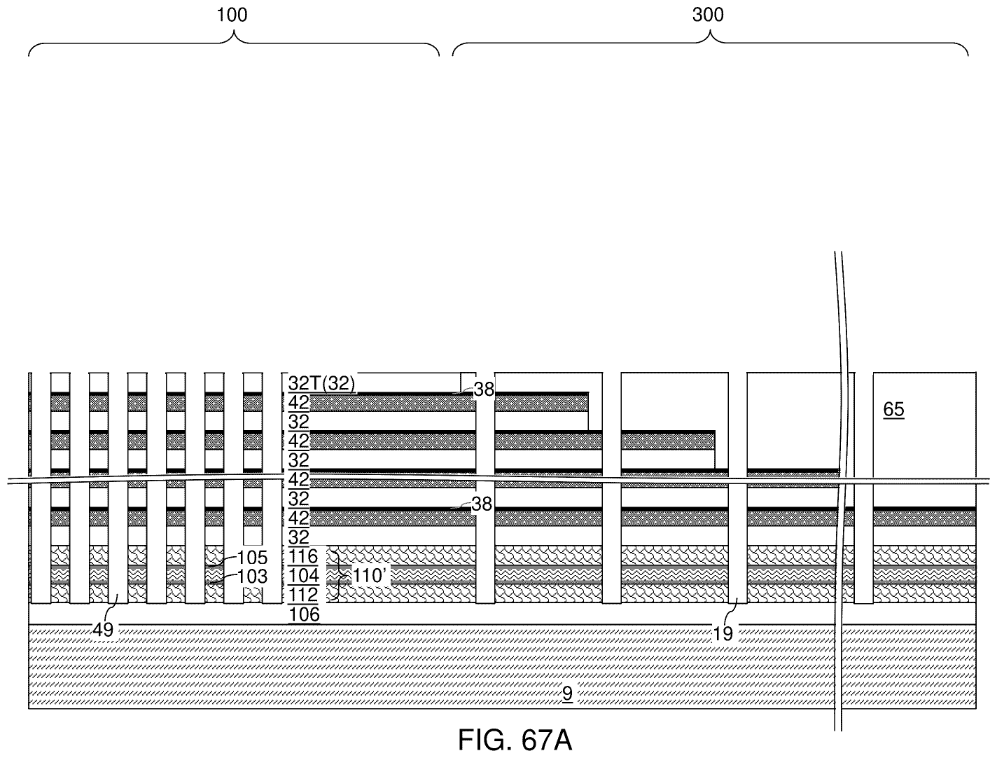

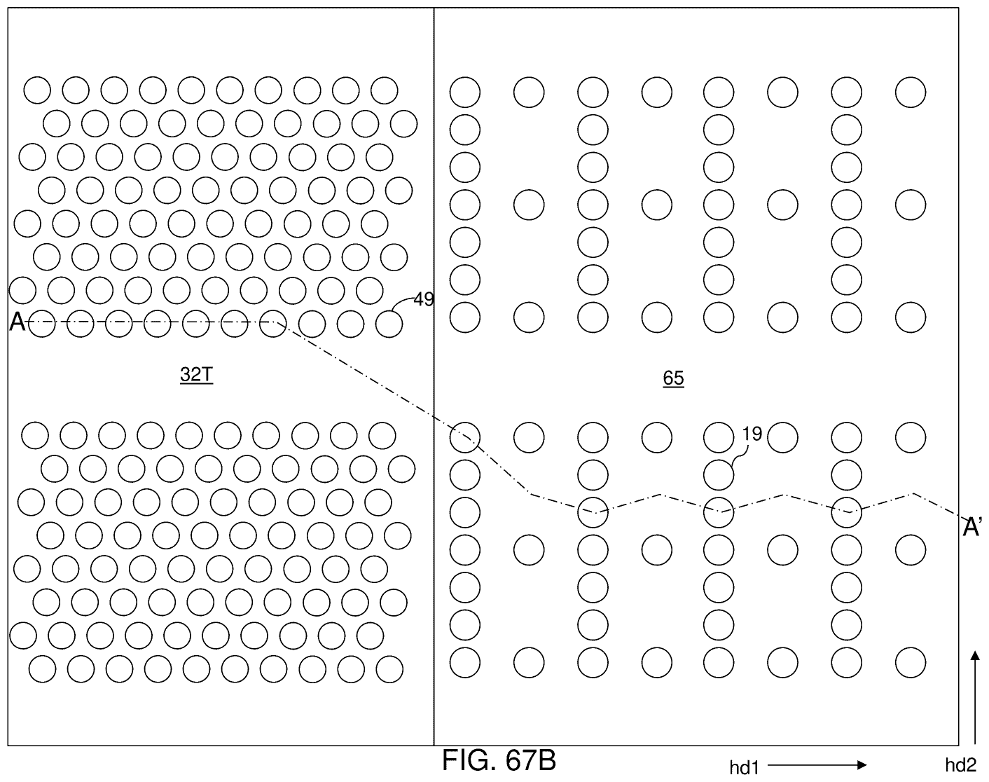

Referring to FIGS. 67A and 67B, an etch mask layer (not shown) can be formed over the topmost insulating layer 32T and the stepped dielectric material portion 65, and can be lithographically patterned to form various openings therein. An anisotropic etch process can be performed to transfer the pattern of the openings in the etch mask layer through the topmost insulating layer 32T, the multiple repetitions of the unit layer stack (32, 42, 38), and the stepped dielectric material portion 65. The anisotropic etch process may employ alternating fluorine-based chemistry which etched the silicon oxide insulating layers 32 and the silicon nitride sacrificial material layers 42, and chlorine-based etch chemistry that etches the transition-metal oxide etch stop layers 38.

Various openings can be formed through the topmost insulating layer 32T, the multiple repetitions of the unit layer stack (32, 42, 38), and the stepped dielectric material portion 65. The various openings may comprise memory opening 49 that are formed in the memory array region 100 and support openings 19 that are formed in the contact region 300. Each of the memory openings 49 and the first-tier support openings 19 can vertically extend through the multiple repetitions of the unit layer stack (32, 42, 38) and into the in-process source-level material layers 110′ (if present). In one embodiment, bottom surfaces of the memory openings 49 and the support openings 19 may be formed within the lower source-level semiconductor layer 112 or at an interface between the lower source-level semiconductor layer and the stopper insulating layer 106.

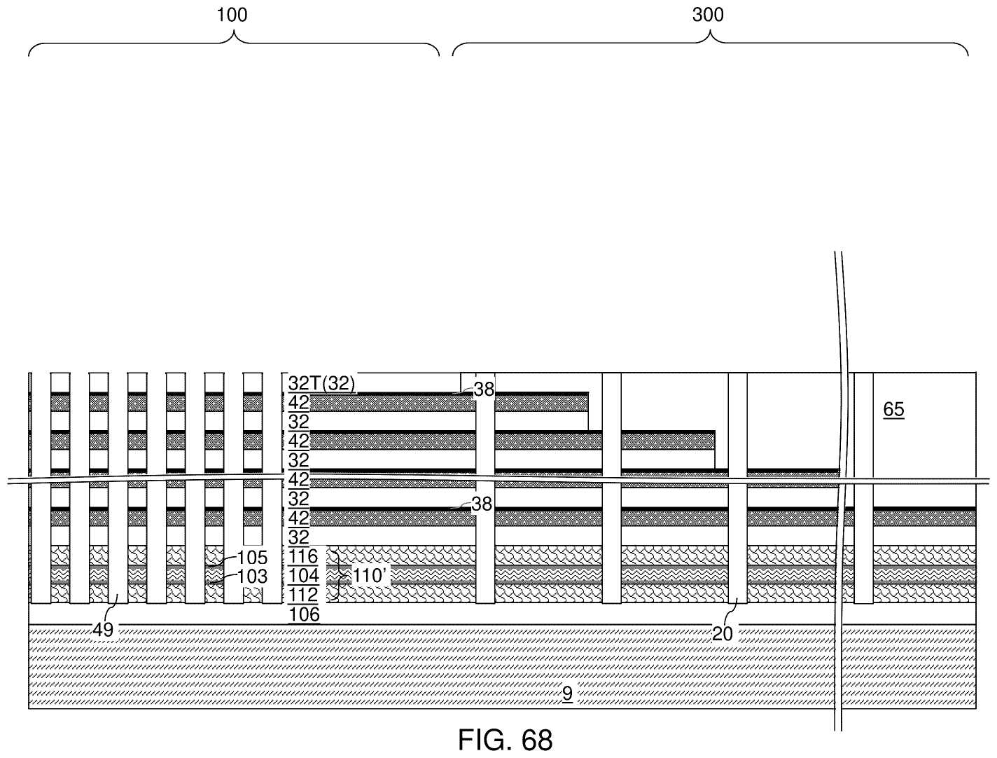

Referring to FIG. 68, an optional sacrificial fill material can be deposited in the memory openings 49 and the support openings 19. The sacrificial fill material may be formed by a non-conformal deposition or a conformal deposition method. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material may be removed from above the horizontal plane including the top surfaces of the topmost insulating layer 32T and the stepped dielectric material portion 65 by a planarization process such as a recess etch process. Sacrificial multi-tier memory opening fill structures (not illustrated) can be formed in the multi-tier memory openings 49, and sacrificial support opening fill structures (not illustrated) can be formed in the multi-tier support openings 19.

A photoresist layer (not shown) can be applied over the topmost insulating layer 32T and the stepped dielectric material portion 65, and can be lithographically patterned to cover the memory array region 100 without covering the contact region 300. The sacrificial support opening fill structures in the contact region 300 can be removed selective to the materials of the unit layer stack (32, 42, 38), the topmost insulating layer 32T, the in-process source-level material layers 110′, the stopper insulating layer 106, and the stepped dielectric material portion 65. For example, an etch process or an ashing process may be employed to remove the sacrificial opening fill structures in the contact region 300. The photoresist layer can be subsequently removed.

A dielectric fill material, such as silicon oxide, can be deposited in the cavities in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion during subsequent replacement of the sacrificial material layers 42 with electrically conductive layers.

Each support pillar structure 20 vertically extends at least from a horizontal plane including the bottom surface of the multiple repetitions of the unit layer stack (32, 42, 38), and at least to a horizontal plane including the top surface of the multiple repetitions of the unit layer stack (32, 42, 38). In one embodiment, each support pillar structure 20 consists essentially of at least one dielectric fill material.

Subsequently, the sacrificial memory opening fill structures in the memory array region 100 can be removed selective to the materials of the multiple repetitions of the unit layer stack (32, 42, 38), the topmost insulating layer 32T, the in-process source-level material layers 110′, the stopper insulating layer 106, and the stepped dielectric material portion 65. For example, a selective etch process or an ashing process may be employed to remove the sacrificial memory opening fill structures in the memory array region 100. Cavities are formed in the volumes of the multi-tier memory openings 49.

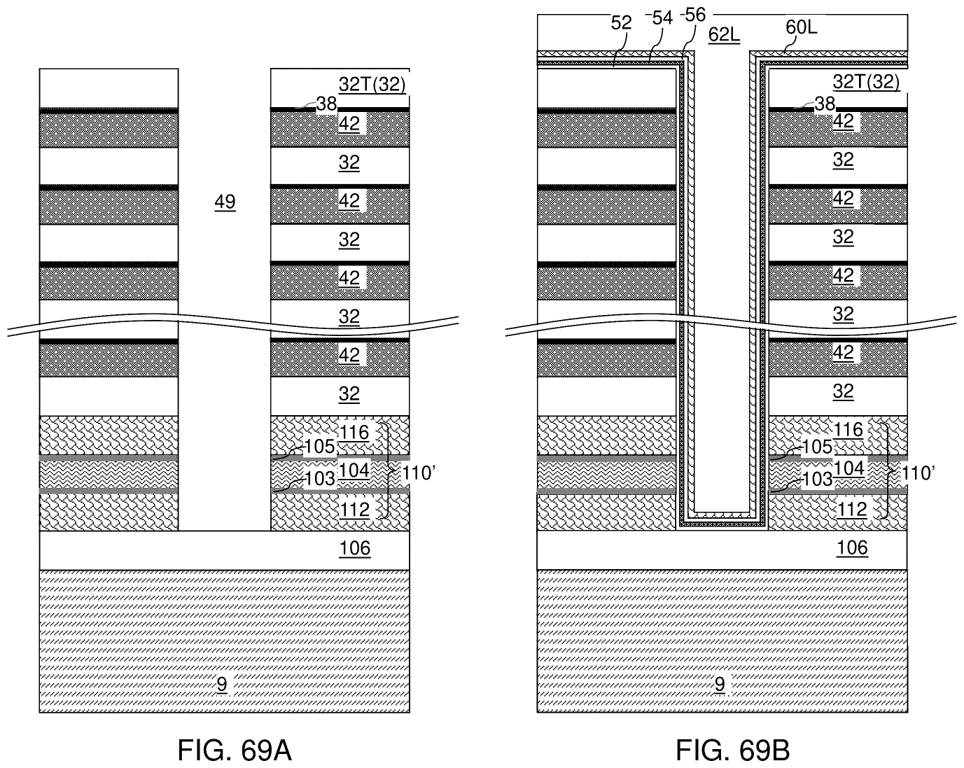

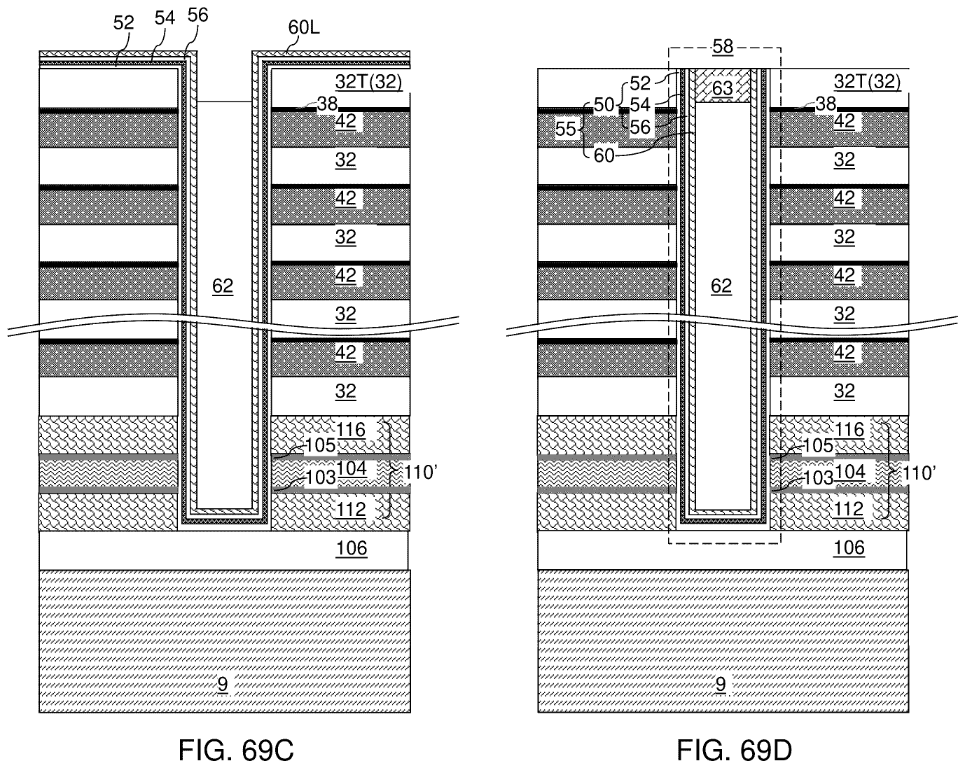

FIGS. 69A-69D are sequential vertical cross-sectional views of a memory opening 49 during formation of a memory opening fill structure 58 in the third exemplary structure according to the third embodiment of the present disclosure.

Referring to FIG. 69A, a memory opening 49 is illustrated after the processing steps of FIG. 68.

Referring to FIG. 69B, a layer stack (52, 54, 56) including a memory material layer 54 can be conformally deposited. The layer stack (52, 54, 56) may be the same as the layer stack (52, 54, 56) described with reference to FIG. 19B. In one embodiment, the layer stack (52, 54, 56) may comprise an optional blocking dielectric layer 52, the memory material layer 54, and an optional dielectric liner 56. A semiconductor channel material layer 60L can be deposited over the layer stack (52, 54, 56) by performing a conformal deposition process. The semiconductor material layer 60L may be the same as the semiconductor material layer 60L described with reference to FIG. 19B. A dielectric core layer 62L can be formed in the same manner as described with reference to FIG. 19B.

Referring to FIG. 69C, the processing steps described with reference to FIG. 19C can be performed to form a dielectric core 62 within each memory opening 49.

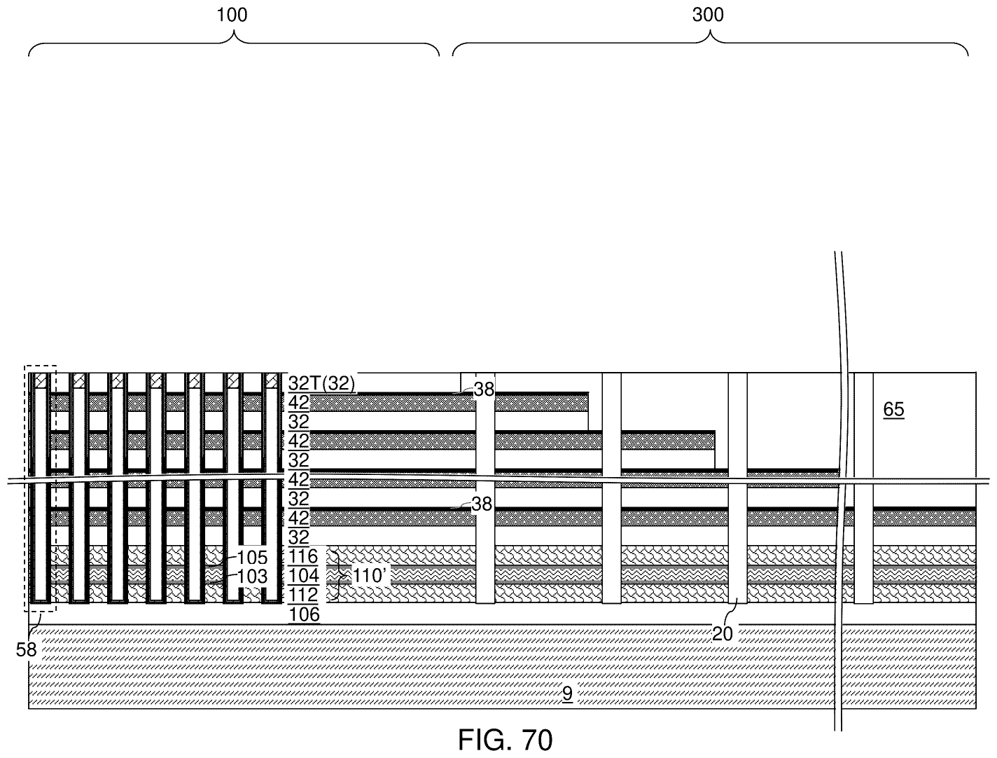

Referring to FIGS. 69D and 70, drain regions 63 may be formed in the same manner as described with reference to FIGS. 19D and 20.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

In an alternative embodiment in which the memory opening fill structures 58 and the support pillar structures 20 comprise a same set of materials, the processing steps shown in FIG. 68 may be omitted. In this alternative embodiment, the support pillar structures 20 are formed in the support openings 19 at the same time as the memory opening fill structures 58 are formed in the memory opening 49.

While an embodiment is described in which a single alternating stack and a single stepped dielectric material portion 65 are employed, in alternative embodiments, a structure includes N repetitions of alternating stacks (e.g., N tiers) and multiple stepped dielectric material portions 65, where N is integer greater than 1 (e.g., N is 2 or 3).

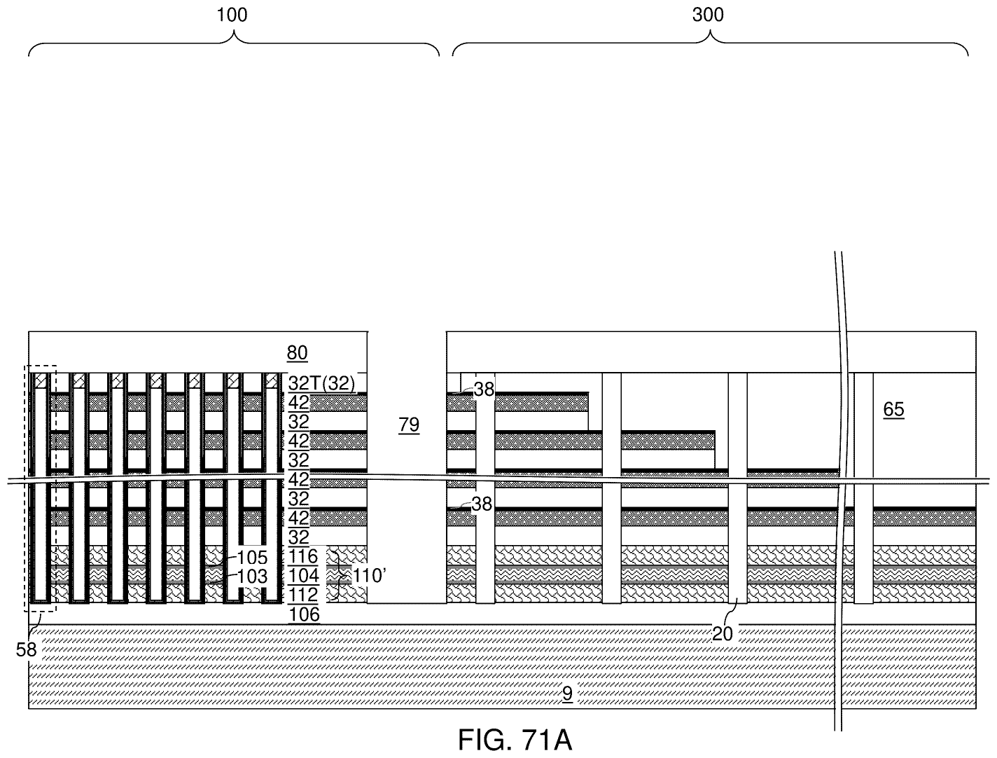

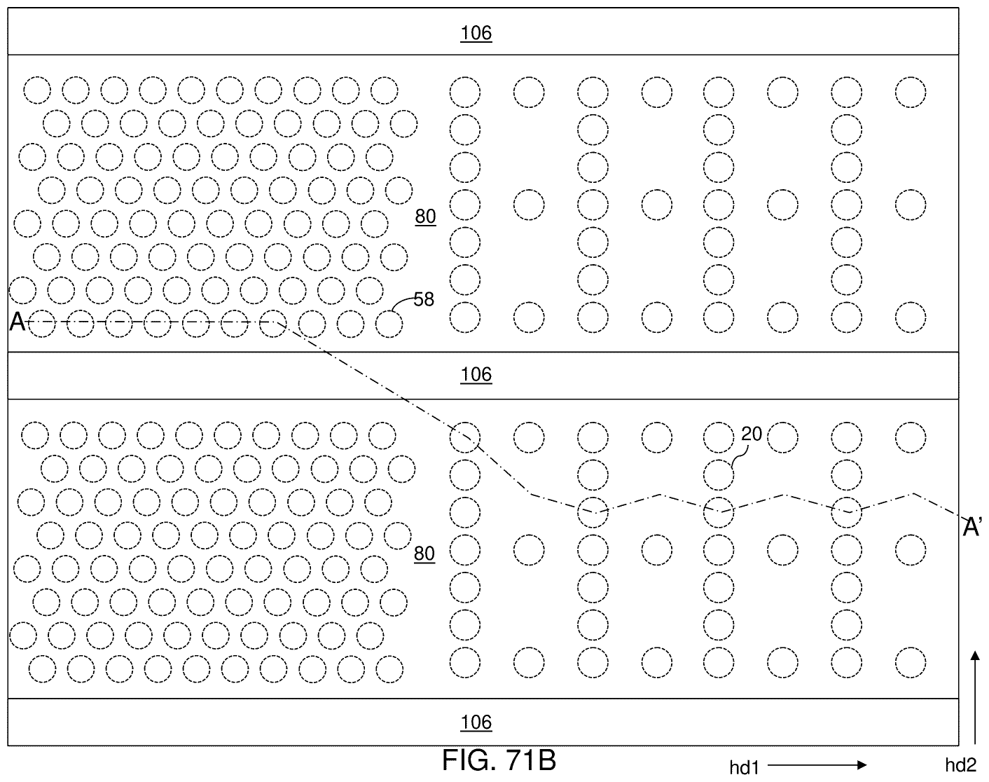

Referring to FIGS. 71A and 71B, the processing steps described with reference to FIGS. 21A and 21B may be performed with any needed changes to form a contact-level dielectric layer 80 and lateral isolation trenches 79.

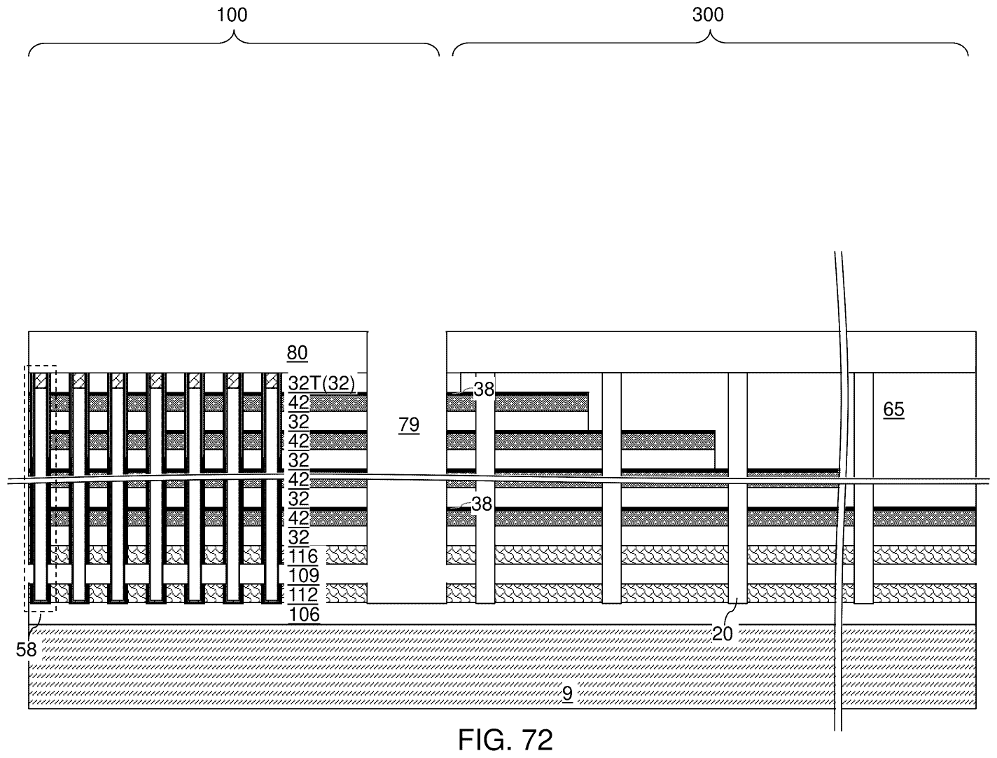

Referring to FIG. 72, the processing steps described with reference to FIGS. 22A, 22B, and 23 may be performed to form a source cavity 109, and to remove portions of the memory films 50 that are exposed to the source cavity 109.

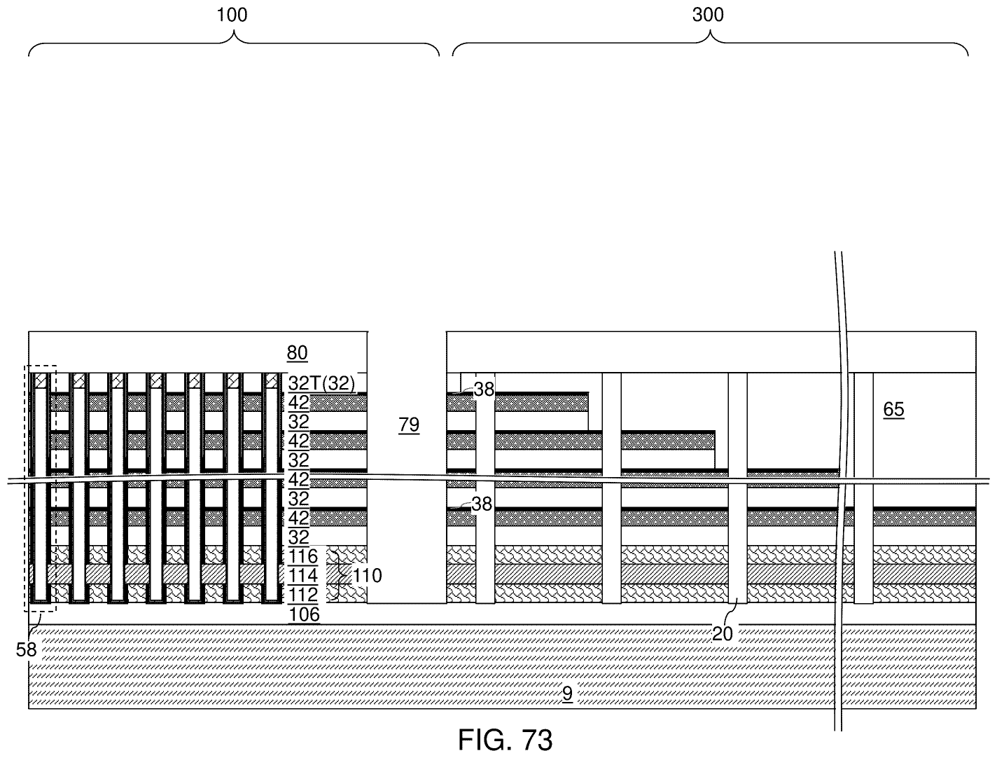

Referring to FIG. 73, the processing steps described with reference to FIGS. 24A, 24B, and 25 may be performed to form a source contact layer 114 in the source cavity 109.

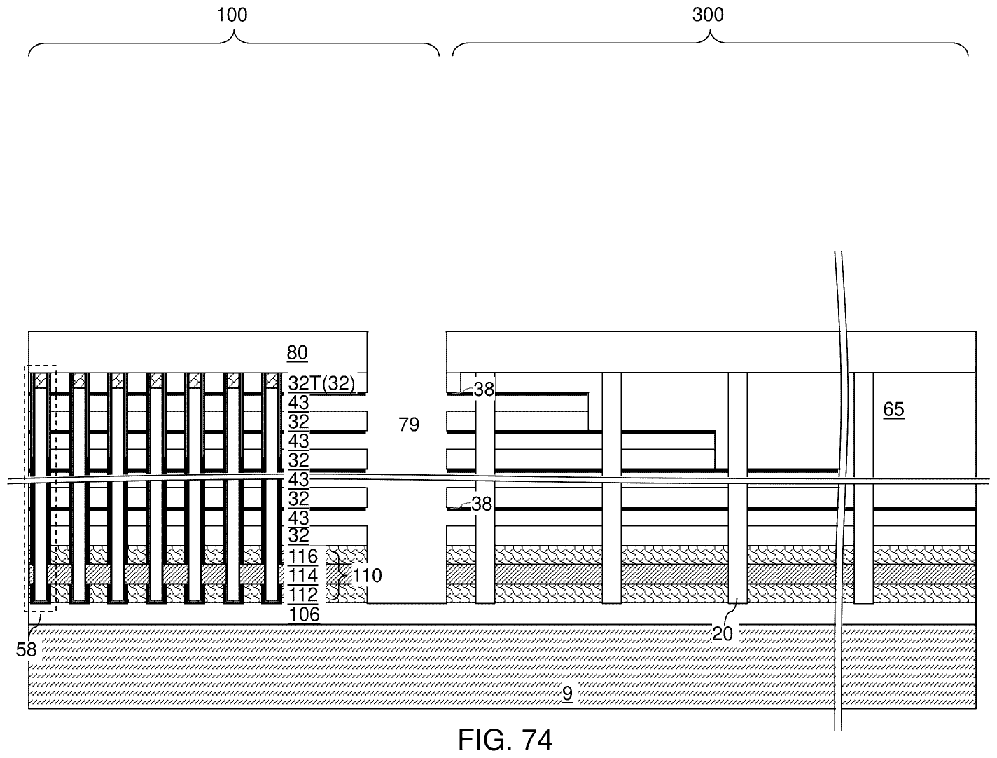

Referring to FIG. 74, an isotropic etch process can be performed to remove the sacrificial material layers 42 selective to the insulating layers 32, the transition-metal oxide etch stop layers 38, the stopper insulating layer 106, the memory opening fill structures 58, and the source layer 110. In an illustrative example, the insulating layers 32 may comprise silicon oxide, the sacrificial material layers 42 may comprise silicon nitride, and the transition-metal oxide etch stop layers 38 may comprise a dielectric oxide of a Group IVB element such as Ti, Zr, or Hf. In this case, the isotropic etch process that removes the sacrificial material layers 42 may comprise a wet etch process employing hot phosphoric acid. Laterally-extending cavities 43 can be formed in volumes from which the sacrificial material layers 42 are removed. Sidewall surface segments of the memory opening fill structures 58 can be physically exposed to the laterally-extending cavities 43.

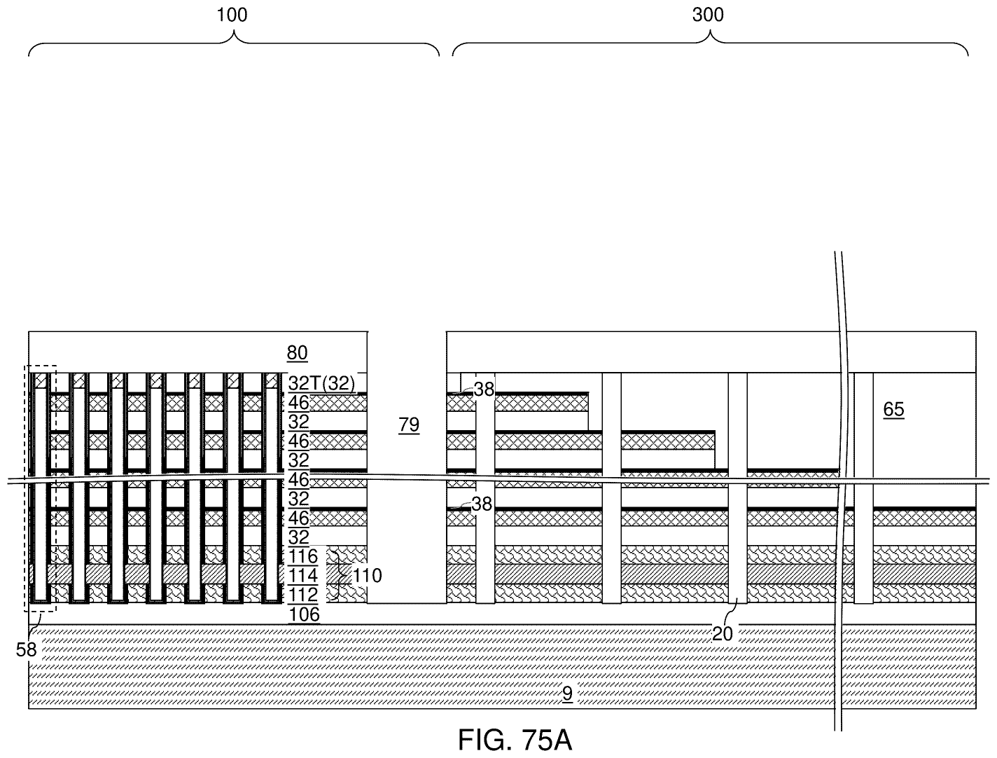

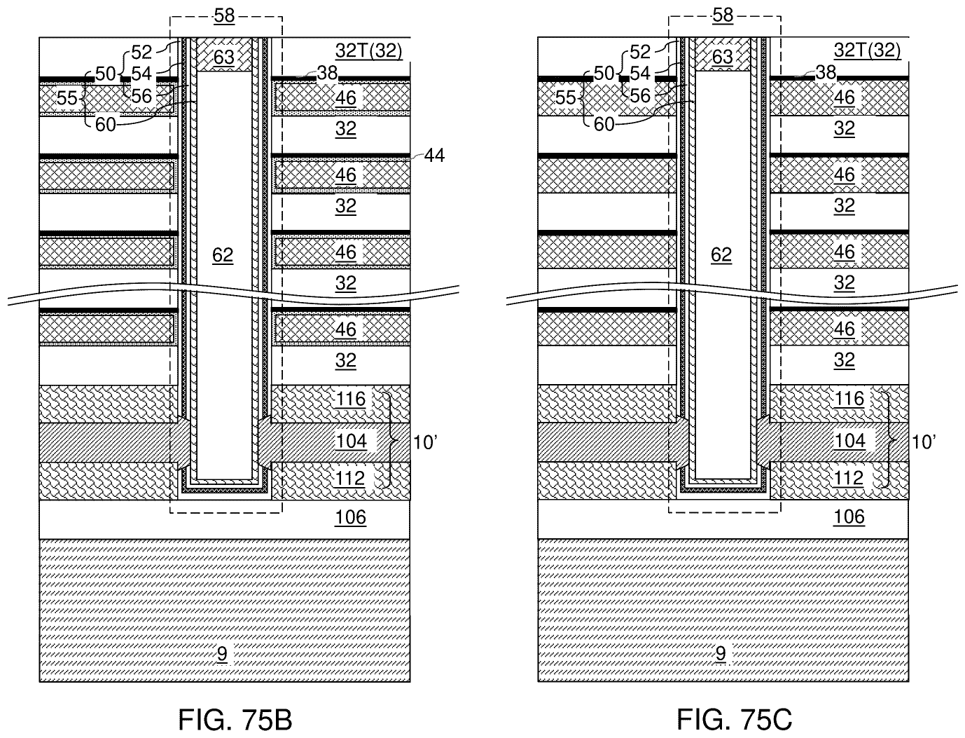

Referring to FIGS. 75A, 75B, and 75C, the processing steps described with reference to FIG. 26 may be performed to form electrically conductive layers 46 in the laterally-extending cavities 43. FIG. 75B is a magnified view of a region of a first configuration of the third exemplary structure of FIG. 75A. FIG. 75C is a magnified view of a region of a second configuration of the third exemplary structure of FIG. 75A.

FIG. 75B illustrates an embodiment in which an outer blocking dielectric layer 44 is formed prior to formation of the electrically conductive layers 46 directly on surface segments of outer sidewalls of the memory opening fill structures 58, on horizontally-extending top surfaces of the insulating layers 32, and on horizontally-extending bottom surfaces of the transition-metal oxide etch stop layers 38. The electrically conductive layers 46 are formed on the outer blocking dielectric layer 44. FIG. 75C illustrates an embodiment in which the electrically conductive layers 46 are formed directly on surface segments of outer sidewalls of the memory opening fill structures 58, on horizontally-extending top surfaces of the insulating layers 32, and on horizontally-extending bottom surfaces of the transition-metal oxide etch stop layers 38, and the outer blocking dielectric layer 44 is omitted.

Referring collectively to FIGS. 75A-75C, vertical repetition of multiple instances of a unit layer stack (32, 46, 38, optionally 44) can be formed along a vertical direction. Each instance of the unit layer stack (32, 46, 38, optionally 44) comprises an insulating layer 32, an electrically conductive layer 46, and a transition-metal oxide etch stop layer 38 that is located entirely above, and does not protrude downward below, a top surface of the electrically conductive layer 46. In other words, with each instance of the unit layer stack (32, 46, 38, optionally 44), the transition-metal oxide etch stop layer 38 is located entirely above the horizontal plane including the top surface of the electrically conductive layer 46 within the same instance of the unit layer stack (32, 46, 38, optionally 44). In one embodiment, the multiple instances of the unit layer stack (32, 46, 38, optionally 44) has stepped surfaces such that lateral extents of the multiple instances of the unit layer stack (32, 46, 38, optionally 44) decreases with an upward vertical distance from a horizontal plane including a bottommost surface of the vertical repetition.

In one embodiment (such as the first configuration illustrated in FIG. 75B), each instance of the unit layer stack (32, 46, 38, optionally 44) comprises a blocking dielectric layer (such as an outer blocking dielectric layer 44) that comprises: a lower horizontally-extending portion interposed between the insulating layer 32 and the electrically conductive layer 46; an upper horizontally-extending portion interposed between the electrically conductive layer 46 and the transition-metal oxide etch stop layer 38; and a vertically-extending portion (such as a cylindrical portion that laterally surrounds a respective memory opening fill structure 58) connecting the lower horizontally-extending portion and the upper horizontally-extending portion.

In one embodiment (such as the second configuration illustrated in FIG. 75C), the electrically conductive layer 46 is in contact with a bottom surface of the transition-metal oxide etch stop layer 38 within each instance of the unit layer stack (32, 46, 38, optionally 44).

In both embodiments, each of the transition-metal oxide etch stop layer 38 extends over the top stepped surface of the respective underlying electrically conductive layer 46 in the contact region 300.

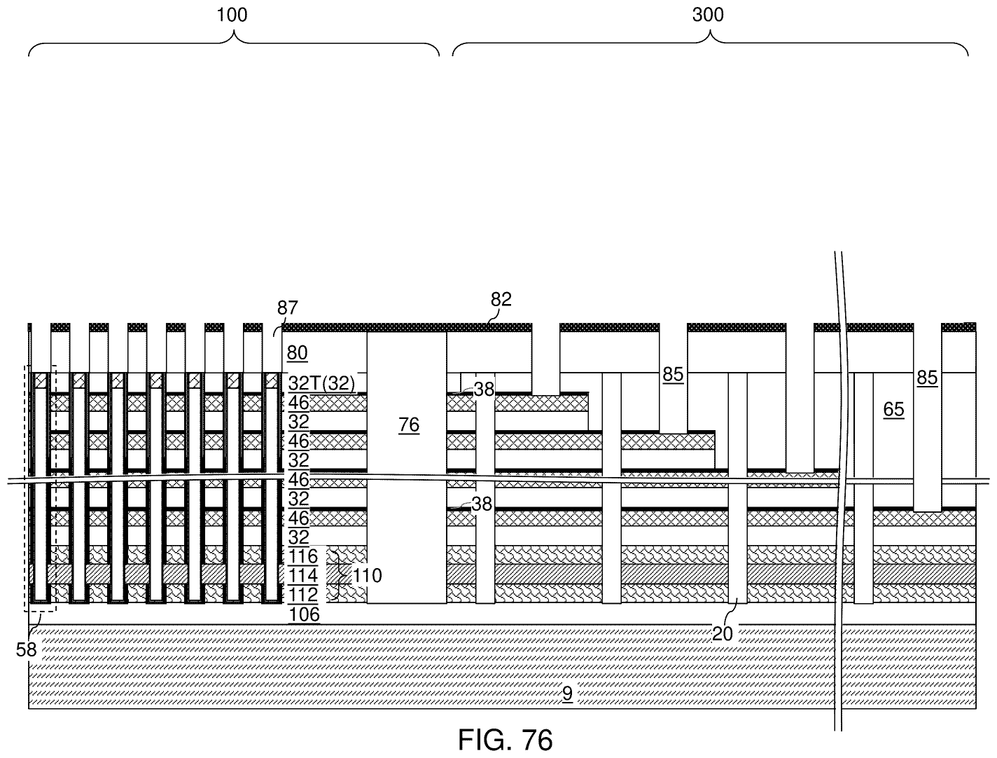

Referring to FIG. 76, the processing steps described with reference to FIGS. 27A and 27B may be performed to form an etch mask layer 82. The material composition, the thickness range, and the pattern of the etch mask layer 82 may be the same as the etch mask layer 82 described with reference to FIGS. 27A and 27B.

The pattern of the openings in the patterned etch mask layer 82 can be transferred through the contact-level dielectric layer 80 and the stepped dielectric material portion 65 by performing an anisotropic etch process. According to an aspect of the present disclosure, the anisotropic etch process may employ a fluorine-based etch chemistry and may etch the materials of the contact-level dielectric layer 80 and the stepped dielectric material portion 65 selective to the material of the transition-metal oxide etch stop layers 38 and selective to the semiconductor material of the drain regions 63. The transition-metal oxide etch stop layers 38 are used as etch stop layers. Contact via cavities (85, 87) are formed through the contact-level dielectric layer 80 and the stepped dielectric material portion 65. The contact via cavities (85, 87) comprise layer contact via cavities 85 that overlie a respective horizontally-extending surface of the stepped surfaces, and drain contact via cavities 87 that overlie the drain regions 63. A break-through anisotropic etch process employing a chlorine-based etch chemistry may be performed to etch through the physically exposed portions of the transition-metal oxide etch stop layers 38 in the stepped surfaces. Top stepped surfaces of the electrically conductive layers 46 can be physically exposed underneath the layer contact via cavities 85. Top surfaces of drain regions 63 can be physically exposed underneath the drain contact via cavities 87.

Generally, the pattern of openings in the patterned etch mask layer 82 can be transferred through the stepped dielectric material portion 65 to form layer contact via cavities 87 by performing an anisotropic etch process (which is also referred to as a main anisotropic etch process using a fluorine-based etch chemistry utilizing, for example, CF₄ or CHF₃) that etches materials of the stepped dielectric material portion 65 selective to materials of the transition-metal oxide etch stop layers 38. The layer contact via cavities 87 can be vertically extended through the transition-metal oxide etch stop layers 38 by performing a break-through anisotropic etch process (which may employ a chlorine-based etch chemistry).

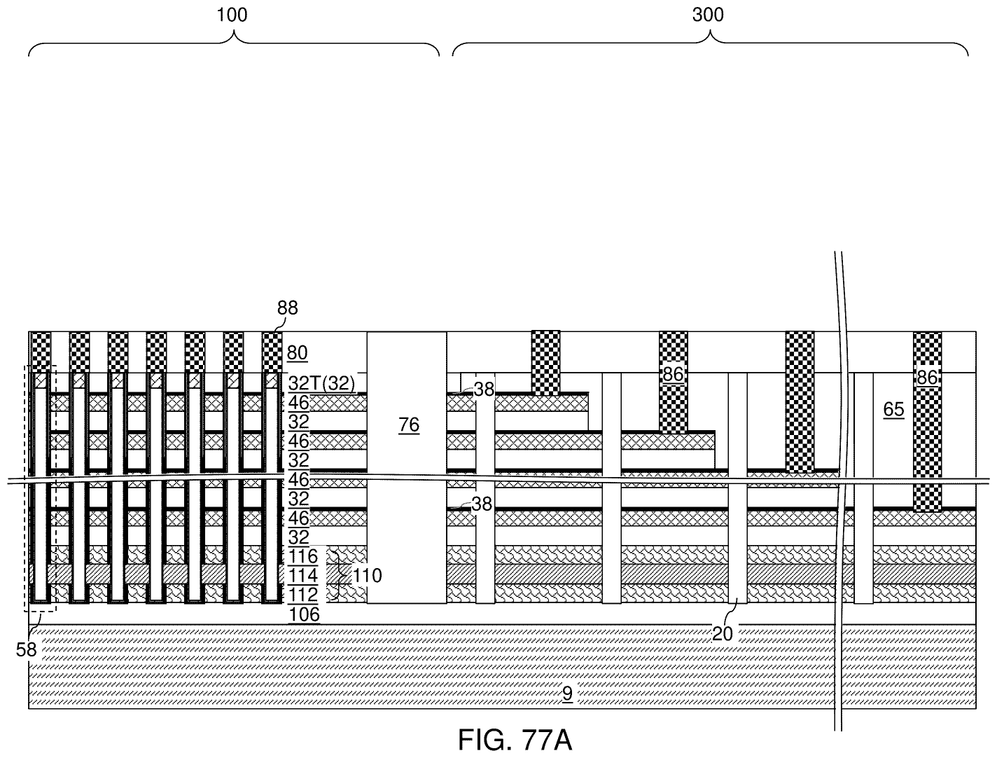

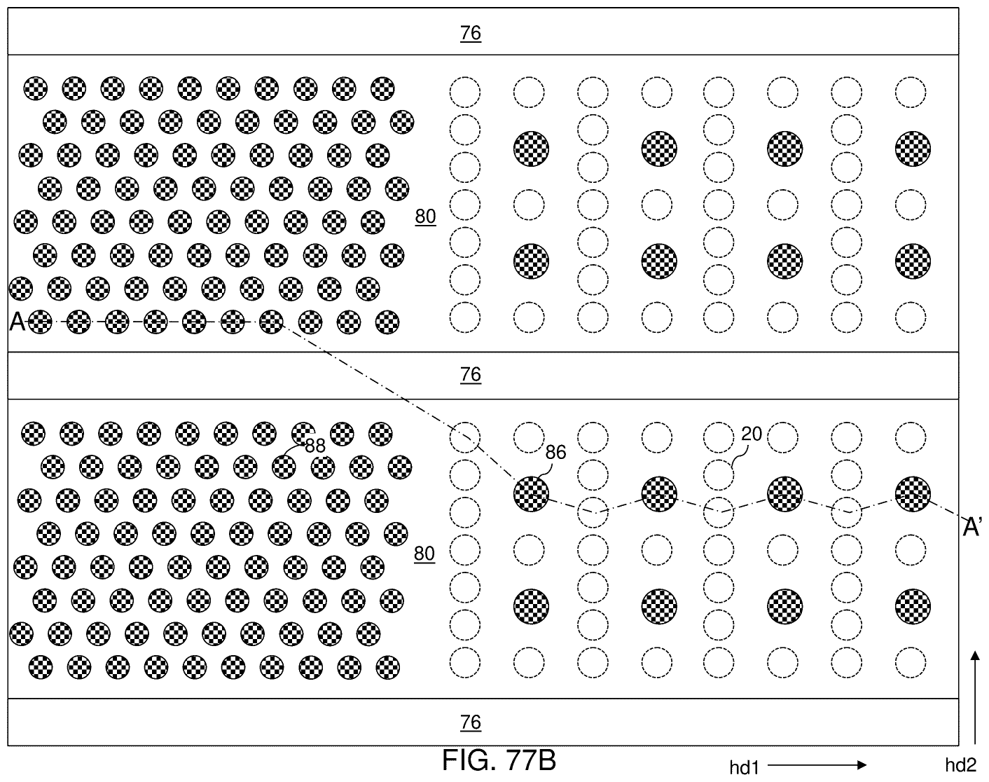

Referring to FIGS. 77A and 77B, the processing steps described with reference to FIGS. 31A and 31B may be performed to form drain contact via structures 88 in the drain contact via cavities 87, and to form layer contact via structures 86 in the layer contact via cavities 85.

In one embodiment, each of the layer contact via structures 86 vertically extends through the contact-level dielectric layer 80, through the stepped dielectric material portion 65, and through a respective transition-metal oxide etch stop layer 38, and is formed on a top surface of a respective one of the electrically conductive layers 46.

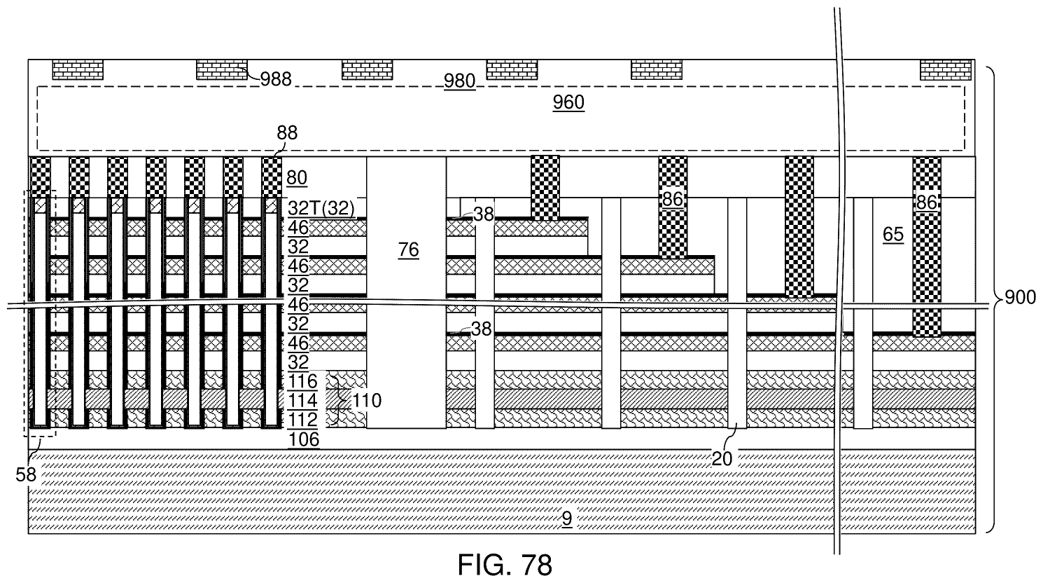

Referring to FIG. 78, the processing steps described with reference to FIG. 32 may be performed to form memory-side dielectric material layers 960 and memory-side metal interconnect structures 980.

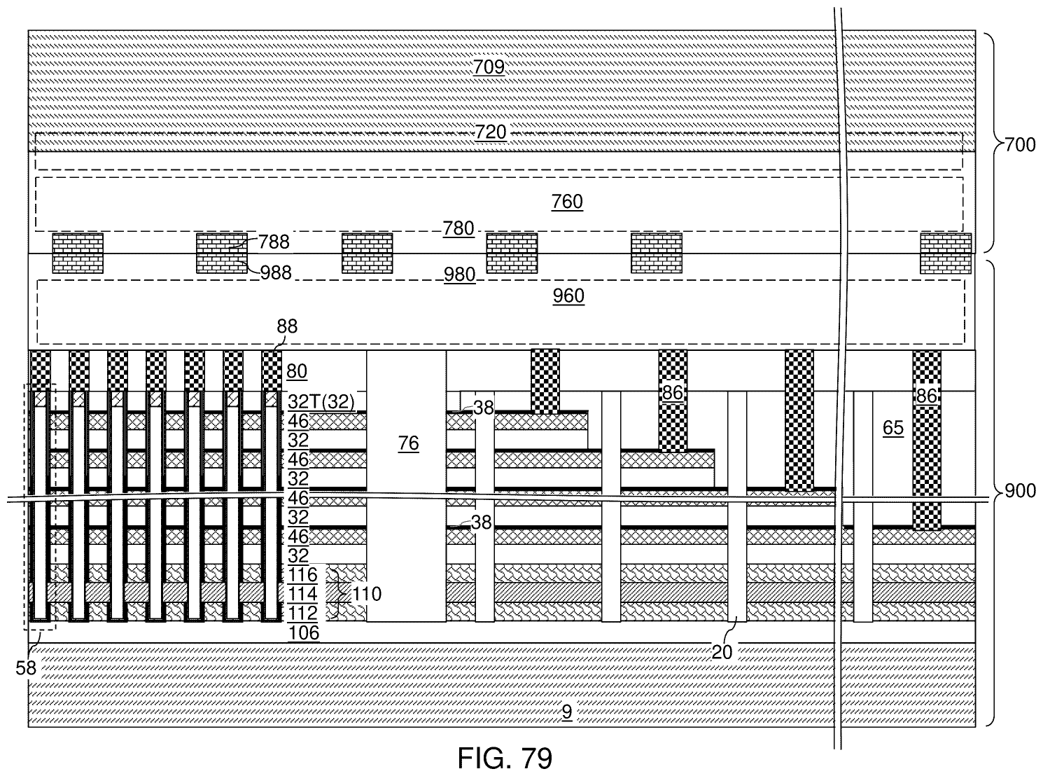

Referring to FIG. 79, the processing steps described with reference to FIG. 33 may be performed to attach a logic die 700 to a memory die 900.

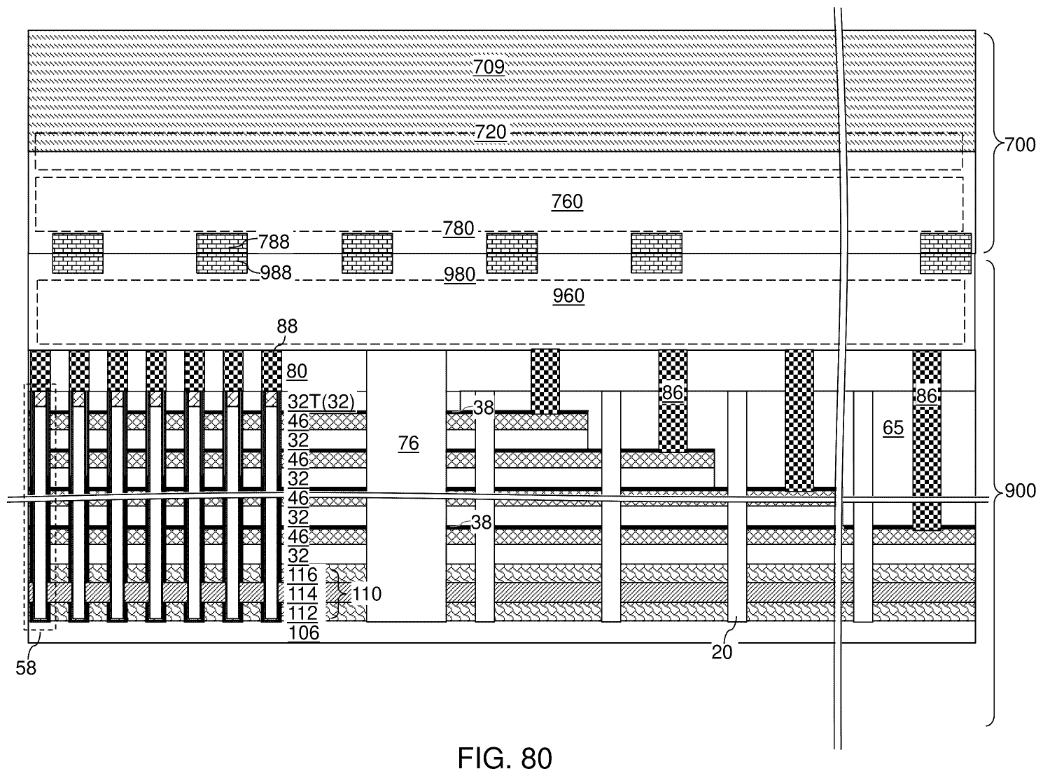

Referring to FIG. 80, the processing steps described with reference to FIG. 34 may be performed to remove the carrier substrate 9.

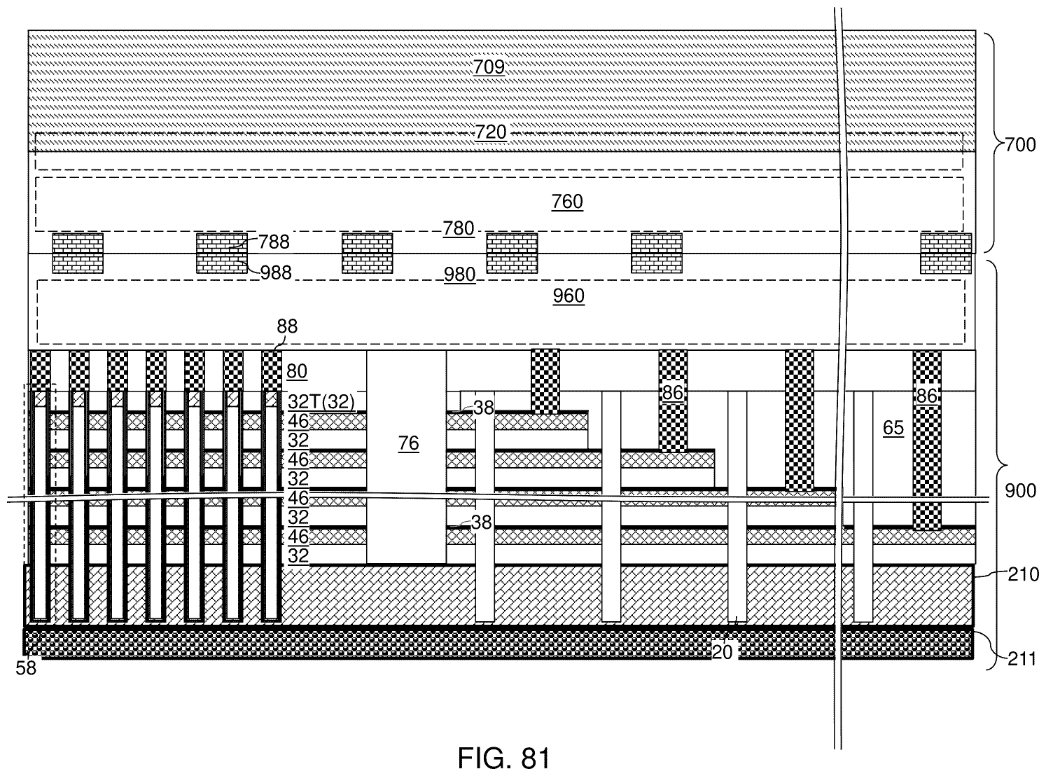

Referring to FIG. 81, the processing steps described with reference to FIG. 35 may be performed to form the source layer 210.

According to the second and third embodiments of the present disclosure, a semiconductor structure, such as the memory die 900 includes a first alternating stack of first insulating layers (32, 132) and first electrically conductive layers (46, 146), the first alternating stack {(32, 46), (132, 146)] having first stepped surfaces; at least one first metal oxide etch stop layer (38, 160) overlying and contacting the first stepped surfaces; a first stepped dielectric material portion (65, 165) overlying the at least one first metal oxide etch stop layer (38, 160) and the first stepped surfaces; a memory opening 49 vertically extending through the first alternating stack; a memory opening fill structure 58 located in the memory opening 49 and comprising a memory film 50 and a vertical semiconductor channel 60; and an electrically conductive layer contact via structure 86 vertically extending through the first stepped dielectric material portion (65, 165) and the at least one first metal oxide etch stop layer (38, 160), and contacting a respective one of the first electrically conductive layers (46, 146).

In some embodiments, the at least one first metal oxide etch stop layer (38, 160) comprises at least one first transition-metal oxide layer, and the at least one first transition-metal oxide layer comprises at least one of hafnium oxide or zirconium oxide.

In the second embodiment, the at least one first metal oxide etch stop layer 160 comprises a continuous first metal oxide etch stop layer which contacts both horizontal and vertical portions of the first stepped surfaces. The second embodiment further comprises a second alternating stack of second insulating layers 232 and second electrically conductive layers 246 overlying the first alternating stack (132, 146), the second alternating stack having second stepped surfaces; and a second stepped dielectric material portion 265 overlying the second stepped surfaces.

In the second embodiment, the first metal oxide etch stop layer 160 further overlies the first alternating stack (132, 146); the second alternating stack (232, 246) overlies the first metal oxide etch stop layer 160; the second stepped dielectric material portion 265 overlies the first stepped dielectric material portion 165; the memory opening 49 vertically further extends through the second alternating stack (232, 246), and through the first metal oxide etch stop layer 160; and the layer contact via structure 86 further vertically extends through the second stepped dielectric material portion 265.

In one embodiment, the first stepped surfaces of the first alternating stack (132, 146) further comprise a metal oxide blocking dielectric layer 44 located between the first electrically conductive layers 146 and the first metal oxide etch stop layer 160. In an alternative embodiment, the first metal oxide etch stop layer 160 directly contacts the horizontal surfaces of the first electrically conductive layers 146 in the first stepped surfaces.

In an optional configuration of the second embodiment, the semiconductor structure further comprises a second metal oxide etch stop layer 260 overlying the second alternating stack (232, 246); a third alternating stack of third insulating layers 332 and third electrically conductive layers 346 having third stepped surfaces and overlying the second metal oxide etch stop layer 260; and a third stepped dielectric material portion 365 overlying the second stepped surfaces. The memory opening 49 further vertically extends through the third alternating stack (332, 346) and through the second metal oxide etch stop layer 260; and the layer contact via structure 86 further vertically extends through the third stepped dielectric material portion 365 and the second metal oxide etch stop layer 260.

In the third embodiment, the at least one first metal oxide etch stop layer (38, 160) comprises a plurality transition-metal oxide etch stop layers 38. Each of the plurality transition-metal oxide etch stop layers 38 contacts a respective horizontal portion of the first stepped surfaces, and extends into the first alternating stack (32, 46) between of a respective underlying one of the first electrically conductive layers 46 and a respective overlying one of the first insulating layers 32.

In the third embodiment, the first alternating stack (32, 46) comprises a vertical repetition of multiple instances of a unit layer stack (32, 46, 38) along a vertical direction; each instance of the unit layer stack (32, 46, 38)comprises the respective one of the first insulating layers 32, the respective one of the first electrically conductive layers 46, and a respective one of the plurality of transition-metal oxide etch stop layers 38; in each instance of the unit layer stack (32, 46, 38), the respective one of the plurality of transition-metal oxide etch stop layers 38 is located entirely above and does not protrude downward below a top surface of the respective first electrically conductive layer 46; and in each instance of the unit layer stack (32, 46, 38), the respective one of the plurality of transition-metal oxide etch stop layers 38 is in contact with a surface segment of a stepped bottom surface of the first stepped dielectric material portion 65.

According to all embodiments, a method of forming a semiconductor structure, such as the memory die, comprises forming an alternating stack of insulating layers and spacer material layers, wherein the spacer material layers are formed as or are subsequently replaced with electrically conductive layers; forming stepped surfaces in the alternating stack, wherein at least one transition-metal oxide etch stop layer is located over the stepped surfaces; forming a stepped dielectric material portion over the stepped surfaces; forming a memory opening through the alternating stack; forming a memory opening fill structure in the memory opening, wherein the memory opening fill structure comprises a memory film and a vertical semiconductor channel; forming a layer contact via cavity through the at least one transition-metal oxide etch stop layer and the stepped dielectric material portion to a top surface of one of the electrically conductive layers by performing a fluorine-based anisotropic etch through the stepped dielectric material portion and by performing a chlorine-based anisotropic etch through the at least one transition-metal oxide etch stop layer; and forming an electrically conductive layer contact via structure in the layer contact via cavity in contact with the top surface of one of the electrically conductive layers.

In some embodiments, the at least one transition-metal oxide etch stop layer comprises at least one of hafnium oxide or zirconium oxide.

In the first embodiment, the stepped dielectric material portion is formed over the stepped surfaces prior to forming the least one transition-metal oxide etch stop layer; and the least one transition-metal oxide etch stop layer comprises a continuous horizontal transition-metal oxide etch stop layer that is formed over the stepped dielectric material portion and over the alternating stack, such that a portion of the continuous horizontal transition-metal oxide etch stop layer is located above the stepped surfaces. In the first embodiment, the step of performing the fluorine-based anisotropic etch through the stepped dielectric material portion occurs after the step of performing the chlorine-based anisotropic etch through the at least one transition-metal oxide etch stop layer.

In the second embodiment, the least one transition-metal oxide etch stop layer comprises a continuous stepped transition-metal oxide etch stop layer that is formed over the stepped surfaces; and the stepped dielectric material portion is formed over the continuous stepped transition-metal oxide etch stop layer. In the second embodiment, the step of performing the fluorine-based anisotropic etch through the stepped dielectric material portion occurs before the step of performing the chlorine-based anisotropic etch through the at least one transition-metal oxide etch stop layer.

In the third embodiment, the at least one metal oxide etch stop layer comprises a plurality transition-metal oxide etch stop layers; and each of the plurality transition-metal oxide etch stop layers contacts a respective horizontal portion of the stepped surfaces, and extends into the alternating stack between of a respective underlying one of the electrically conductive layers and a respective overlying one of the insulating layers. In the third embodiment, the step of performing the fluorine-based anisotropic etch through the stepped dielectric material portion occurs before the step of performing the chlorine-based anisotropic etch through the at least one transition-metal oxide etch stop layer.

The various embodiments of the present disclosure may be employed to reduce or prevent over etching through electrically conductive layers 46 during formation of the layer contact via cavities 85, and to provide reliable electrical contact between layer contact via structures 86 and electrically conductive layers 46. The dielectric metal oxide of a transition metal, such as a dielectric oxide of a Group IVB element, within the transition-metal oxide etch stop layers (160, 260, 38) can be employed as etch stop materials to eliminate or minimize, overetching of the layer contact via cavities 87 through electrically conductive layers 46.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a first alternating stack of first insulating layers and first electrically conductive layers, the first alternating stack having first stepped surfaces;
at least one first metal oxide etch stop layer overlying and contacting the first stepped surfaces;
a first stepped dielectric material portion overlying the at least one first metal oxide etch stop layer and the first stepped surfaces;
a memory opening vertically extending through the first alternating stack;
a memory opening fill structure located in the memory opening and comprising a memory film and a vertical semiconductor channel; and
an electrically conductive layer contact via structure vertically extending through the first stepped dielectric material portion and the at least one first metal oxide etch stop layer, and contacting a respective one of the first electrically conductive layers.

2. The semiconductor structure of claim 1, wherein the at least one first metal oxide etch stop layer comprises at least one first transition-metal oxide layer.

3. The semiconductor structure of claim 2, wherein the at least one first transition-metal oxide layer comprises at least one of hafnium oxide or zirconium oxide.

4. The semiconductor structure of claim 1, wherein the at least one first metal oxide etch stop layer comprises a continuous first metal oxide etch stop layer which contacts both horizontal and vertical portions of the first stepped surfaces.

5. The semiconductor structure of claim 4, further comprising:
a second alternating stack of second insulating layers and second electrically conductive layers overlying the first alternating stack, the second alternating stack having second stepped surfaces; and
a second stepped dielectric material portion overlying the second stepped surfaces.

6. The semiconductor structure of claim 5, wherein:
the first metal oxide etch stop layer further overlies the first alternating stack;
the second alternating stack overlies the first metal oxide etch stop layer;
the second stepped dielectric material portion overlies the first stepped dielectric material portion;
the memory opening vertically further extends through the second alternating stack, and through the first metal oxide etch stop layer; and
the layer contact via structure further vertically extends through the second stepped dielectric material portion.

7. The semiconductor structure of claim 6, wherein the first stepped surfaces of the first alternating stack further comprise a metal oxide blocking dielectric layer located between the first electrically conductive layers and the first metal oxide etch stop layer.

8. The semiconductor structure of claim 6, wherein the first metal oxide etch stop layer directly contacts the horizontal surfaces of the first electrically conductive layers in the first stepped surfaces.

9. The semiconductor structure of claim 6, further comprising a first insulating cap layer located between the first alternating stack and the first metal oxide etch stop layer,
wherein:
the memory opening has a first lateral extent at a horizontal plane including a bottom surface of a bottommost layer of the second alternating stack;
the memory opening has a second lateral extent at a horizontal plane including a top surface of the first insulating cap layer;
the first lateral extent is less than the second lateral extent;
the memory opening fill structure has a lateral extent at a level of the first metal oxide etch stop layer which is greater than the first lateral extent;
the memory opening fill structure has an annular horizontal surface within a horizontal plane including a top surface of the first metal oxide etch stop layer;
the annular horizontal surface is in contact with an annular segment of a bottom surface of a bottommost layer within the second alternating stack; and
the memory film is in contact with a sidewall of an opening through the first metal oxide etch stop layer.

10. The semiconductor structure of claim 5, further comprising:
a second metal oxide etch stop layer overlying the second alternating stack;
a third alternating stack of third insulating layers and third electrically conductive layers having third stepped surfaces and overlying the second metal oxide etch stop layer; and
a third stepped dielectric material portion overlying the second stepped surfaces, wherein:
the memory opening further vertically extends through the third alternating stack and through the second metal oxide etch stop layer; and
the layer contact via structure further vertically extends through the third stepped dielectric material portion and the second metal oxide etch stop layer.

11. The semiconductor structure of claim 1, wherein the at least one first metal oxide etch stop layer comprises a plurality transition-metal oxide etch stop layers.

12. The semiconductor structure of claim 11, wherein each of the plurality transition-metal oxide etch stop layers:
contacts a respective horizontal portion of the first stepped surfaces, and
extends into the first alternating stack between of a respective underlying one of the first electrically conductive layers and a respective overlying one of the first insulating layers.

13. The semiconductor structure of claim 12, wherein:
the first alternating stack comprises a vertical repetition of multiple instances of a unit layer stack along a vertical direction;
each instance of the unit layer stack comprises the respective one of the first insulating layers, the respective one of the first electrically conductive layers, and a respective one of the plurality of transition-metal oxide etch stop layers;
in each instance of the unit layer stack, the respective one of the plurality of transition-metal oxide etch stop layers is located entirely above and does not protrude downward below a top surface of the respective first electrically conductive layer; and
in each instance of the unit layer stack, the respective one of the plurality of transition-metal oxide etch stop layers is in contact with a surface segment of a stepped bottom surface of the first stepped dielectric material portion.

14. A method of forming a semiconductor structure, comprising:
forming an alternating stack of insulating layers and spacer material layers, wherein the spacer material layers are formed as or are subsequently replaced with electrically conductive layers;
forming stepped surfaces in the alternating stack, wherein at least one transition-metal oxide etch stop layer is located over the stepped surfaces;
forming a stepped dielectric material portion over the stepped surfaces;
forming a memory opening through the alternating stack;
forming a memory opening fill structure in the memory opening, wherein the memory opening fill structure comprises a memory film and a vertical semiconductor channel;
forming a layer contact via cavity through the at least one transition-metal oxide etch stop layer and the stepped dielectric material portion to a top surface of one of the electrically conductive layers by performing a fluorine-based anisotropic etch through the stepped dielectric material portion and by performing a chlorine-based anisotropic etch through the at least one transition-metal oxide etch stop layer; and
forming an electrically conductive layer contact via structure in the layer contact via cavity in contact with the top surface of one of the electrically conductive layers.

15. The method of claim 14, wherein the at least one transition-metal oxide etch stop layer comprises at least one of hafnium oxide or zirconium oxide.

16. The method of claim 14, wherein:
the stepped dielectric material portion is formed over the stepped surfaces prior to forming the least one transition-metal oxide etch stop layer; and
the least one transition-metal oxide etch stop layer comprises a continuous horizontal transition-metal oxide etch stop layer that is formed over the stepped dielectric material portion and over the alternating stack, such that a portion of the continuous horizontal transition-metal oxide etch stop layer is located above the stepped surfaces.

17. The method of claim 16, wherein the step of performing the fluorine-based anisotropic etch through the stepped dielectric material portion occurs after the step of performing the chlorine-based anisotropic etch through the at least one transition-metal oxide etch stop layer.

18. The method of claim 14, wherein:
the least one transition-metal oxide etch stop layer comprises a continuous stepped transition-metal oxide etch stop layer that is formed over the stepped surfaces; and
the stepped dielectric material portion is formed over the continuous stepped transition-metal oxide etch stop layer.

19. The method of claim 18, wherein the step of performing the fluorine-based anisotropic etch through the stepped dielectric material portion occurs before the step of performing the chlorine-based anisotropic etch through the at least one transition-metal oxide etch stop layer.

20. The method claim 14, wherein:
the at least one metal oxide etch stop layer comprises a plurality transition-metal oxide etch stop layers;
each of the plurality transition-metal oxide etch stop layers contacts a respective horizontal portion of the stepped surfaces, and extends into the alternating stack between of a respective underlying one of the electrically conductive layers and a respective overlying one of the insulating layers; and
the step of performing the fluorine-based anisotropic etch through the stepped dielectric material portion occurs before the step of performing the chlorine-based anisotropic etch through the at least one transition-metal oxide etch stop layer.
